(19) United States
(12) Patent Application Publication
(10) Pub. No.: US 2014/0357866 A1
(43) Pub. Date: Dec. 4, 2014

(54) NOVEL ORGANIC ELECTROLUMINESCENT COMPOUNDS AND ORGANIC ELECTROLUMINESCENT DEVICE USING THE SAME

(71) Applicant: Rohm and Haas Electronic Materials Korea Ltd., Chungcheongnam-do (KR)

(72) Inventors: Chi-Sik Kim, Gyeonggi-do (KR); Soo-Yong Lee, Chungcheongnam-do (KR); Soo-Jin Yang, Gyeonggi-do (KR); Seung-Ae Kim, Gyeonggi-do (KR); Kyoung-Jin Park, Gyeonggi-do (KR); Hyuck-Joo Kwon, Seoul (KR); Kyung-Joo Lee, Seoul (KR); Bong-Ok Kim, Seoul (KR)

(21) Appl. No.: 14/362,126

(22) PCT Filed: Nov. 30, 2012
(86) PCT No.: PCT/KR2012/010313

§ 371 Date: Jun. 1, 2014

(30) Foreign Application Priority Data
Dec. 1, 2011 (KR) 10-2011-0127640

(51) Int. Cl. H01L 51/00

(52) U.S. Cl. CPC H01L 51/0067; H01L 51/0071
USPC 544/333

(57) ABSTRACT

The present invention relates to a novel organic electroluminescent compound and an organic electroluminescent device containing the same. Using the organic electroluminescent compounds of the present invention, it is possible to manufacture an OLED device with a long operating lifespan and high luminous efficiency. In addition, the compounds can improve the power efficiency of the device to reduce overall power consumption.

### TECHNICAL FIELD

The present invention relates to novel organic electroluminescent compounds and organic electroluminescent device using the same.

### BACKGROUND ART

An electroluminescent (EL) device is a self-light-emitting device which has advantages over other types of display devices in that it provides a wider viewing angle, a greater contrast ratio, and a faster response time. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. Until now, fluorescent materials have been widely used as a light-emitting material. However, in view of electroluminescent mechanisms, since phosphorescent materials theoretically enhance luminous efficiency by four (4) times compared to fluorescent materials, development of phosphorescent light-emitting materials are widely being researched. Indium(III) complexes have been widely known as phosphorescent materials, including bis(2-(2′-benzothienyl)-pyridinato-N,C3′)iridium(acetylacetonate) ((acac)Ir(btp)₂), tris(2-phenylpyridine)indium (Ir(ppy)₃) and bis(4,6-difluorophenylpyridinato-N,C2)picolinate iridium (Firpic) as red, green and blue materials, respectively.

Until now, 4,4′-N,N′-dicarbazol-biphenyl (CBP) was the most widely known host material for phosphorescent substances in conventional technologies. Further, an organic EL device using bathocuproine (BCP) and aluminum(III)bis(2-methyl-8-quinolinate)(4-phenylphenolate) (BAIq) for a hole blocking layer is also known, and Pioneer (Japan) et al. developed a high performance organic EL device employing a derivative of BAIq as a host material.

Though these materials provide good light-emitting characteristics, they have the following disadvantages: (1) Due to their low glass transition temperature and poor thermal stability, degradation may occur during a high-temperature deposition process in a vacuum. (2) The power efficiency of an organic EL device is given by [(π/voltage)×current efficiency], and power efficiency is inversely proportional to voltage. An organic EL device comprising phosphorescent host materials provides a higher current efficiency (cd/A) than one comprising fluorescent materials. However, it has a higher driving voltage, and thus, there is less advantages in terms of power efficiency (lm/W). (3) Further, the operating lifespan of the organic EL device is short, and luminous efficiency still needs improvement.

International Patent Publication No. WO 2011/099374 discloses fused pentacyclic compounds based on a carbazole structure, substituted with a monocyclic heteroaryl group comprising a nitrogen atom. However, the compounds require high driving voltages, and so are not suitable for commercialization.

### DISCLOSURE OF INVENTION

### Technical Problem

The objective of the present invention is to provide an organic electroluminescent compound imparting high luminous efficiency and a long operating lifespan to a device, and having suitable color coordinate; and an organic electroluminescent device having high efficiency and a long lifespan, using said compound as a light-emitting material.

### Solution to Problem

The present inventors found that the objective above is achievable by an organic electroluminescent compound represented by the following formula 1:

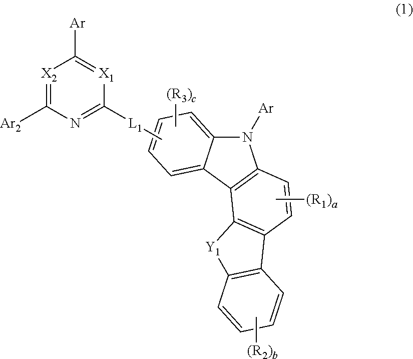

wherein

L₁ represents a single bond, a substituted or unsubstituted 3- to 30-membered heteroarylene group, or a substituted or unsubstituted (C6-C30)arylene group;

X₁ and X₂ each independently represent CR′ or N;

Y₁ represents —O—, —S—, —CR₁₁R₁₂—, —SiR₁₃R₁₄— or —NR₁₅—, provided that when Y₁ is —NR₁₅—, L₁ is not a single bond;

Ar represents hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, or a substituted or unsubstituted 5- to 7-membered heterocycloalkyl group,

Ar₁, Ar₂, R′, R₁ to R₃, and R₁₁ to R₁₅ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, an amino group, a substituted or unsubstituted (C6-C30)arylamino group, a substituted or unsubstituted tri(C1-C30)alkylsilyl group, a substituted or unsubstituted tri(C6-C30)arylsilyl group, a cyano group, a nitro group, or a hydroxyl group;

a represents an integer of 1 or 2, b represents an integer of 1 to 4, c represents an integer of 1 to 3; where a to c are integers of 2 or more, each of R₁ to R₃ is the same or different; and

the heterocycloalkyl group, the heteroarylene group and the heteroaryl group contain at least one hetero atom selected from B, N, O, S, P(═O), Si and P.

### Advantageous Effects of Invention

The organic electroluminescent compounds according to the present invention have high luminous efficiency and good lifespan characteristics, and thus could provide an organic electroluminescent device having long operating lifespan.

In addition, the present invention makes it possible to manufacture a device free from crystallization since the organic electroluminescent compounds used in the present invention are highly efficient in transporting electrons. Further, the compounds have good layer formability and improve the current characteristics of the device. Therefore, it is possible to produce an organic electroluminescent device having lowered driving voltages and enhanced power efficiency.

### MODE FOR THE INVENTION

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, The organic electroluminescent compound represented by the above formula 1 will be described in detail.

Herein, “alkyl” includes methyl, ethyl, n-propyl, isopropyl, n-butyl, isobutyl, tert-butyl, etc.; “alkenyl” includes vinyl, 1-propenyl, 2-propenyl, 1-butenyl, 2-butenyl, 3-butenyl, 2-methylbut-2-enyl, etc.; “alkynyl” includes ethynyl, 1-propynyl, 2-propynyl, 1-butynyl, 2-butynyl, 3-butynyl, 1-methylpent-2-ynyl, etc.; “cycloalkyl” includes cyclopropyl, cyclobutyl, cyclopentyl, cyclohexyl, etc.; “5- to 7-membered heterocycloalkyl” is a cycloalkyl having at least one heteroatom selected from B, N, O, S, P(═O), Si and P, preferably O, S and N, and 5 to 7 ring backbone atoms, and includes tetrahydrofuran, pyrrolidine, thiolan, tetrahydropyran, etc.; “aryl(ene)” is a monocyclic or fused ring derived from an aromatic hydrocarbon, and includes phenyl, biphenyl, terphenyl, naphthyl, binaphthyl, phenyl naphthyl, naphthyl phenyl, fluorenyl, phenyl fluorenyl, benzofluorenyl, dibenzofluorenyl, phenanthrenyl, phenyl phenanthrenyl, anthracenyl, indanyl, indenyl, isoindenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “Halogen” includes F, C1, Br and I.

Herein, “substituted” in the expression “substituted or unsubstituted” means that a hydrogen atom in a certain functional group is replaced with another atom or group, i.e., a substituent.

The aryl(ene), heteroaryl(ene), alkyl, cycloalkyl, heterocycloalkyl, arylamino, trialkylsilyl and triarylsilyl groups in L₁, Ar, Ar₁, Ar₂, R′, R₁ to R₃, and R₁₁ to R₁₅ of formula 1, can be further substituted with at least one selected from the group consisting of: deuterium; a halogen; a (C1-C30)alkyl group substituted or unsubstituted with a halogen; a (C6-C30)aryl group; a 3- to 30-membered heteroaryl group substituted or unsubstituted with a (C1-C30)alkyl or a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group; preferably are at least one selected from the group consisting of deuterium, a (C1-C10)alkyl group, a (C6-C20)aryl group and a 5- to 20-membered heteroaryl group; more preferably are at least one selected from the group consisting of deuterium, a (C1-C6)alkyl group, a (C6-C12)aryl group and a 5- to 12-membered heteroaryl group.

In formula 1, above, L₁ represents a single bond, a substituted or unsubstituted 3- to 30-membered heteroarylene group, or a substituted or unsubstituted (C6-C30)arylene group; preferably a single bond or a substituted or unsubstituted (C6-C20)arylene group; more preferably a single bond; or a (C6-C15)arylene group unsubstituted or substituted with a (C1-C6)alkyl group or a 5- to 12-membered heteroaryl group.

X₁ and X₂ each independently represent CR′ or N.

Y₁ represents —O—, —S—, —CR₁₁R₁₂—, —SiR₁₃R₁₄— or —NR₁₅—, provided that when Y₁ is —NR₁₅—, L₁ is not a single bond;

Ar represents hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, or a substituted or unsubstituted 5- to 7-membered heterocycloalkyl group; preferably hydrogen, a substituted or unsubstituted (C6-C20)aryl group, or a substituted or unsubstituted 5- to 20-membered heteroaryl group; more preferably hydrogen; a (C6-C18)aryl group unsubstituted or substituted with a 5- to 12-membered heteroaryl group; or a 5- to 12-membered heteroaryl group unsubstituted or substituted with a (C6-C12)aryl group.

Ar₁, Ar₂, R′, R₁ to R₃, and R₁₁ to R₁₅ each independently represent: hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, an amino group, a substituted or unsubstituted (C6-C30)arylamino group, a substituted or unsubstituted tri(C1-C30)alkylsilyl group, a substituted or unsubstituted tri(C6-C30)arylsilyl group, a cyano group, a nitro group, or a hydroxyl group; preferably hydrogen, a substituted or unsubstituted (C1-C10)alkyl group, a substituted or unsubstituted (C6-C20)aryl group, a substituted or unsubstituted 5- to 20-membered heteroaryl group, a substituted or unsubstituted tri(C1-C10)alkylsilyl group, or a substituted or unsubstituted tri(C6-C20)arylsilyl group; more preferably hydrogen; a (C1-C6)alkyl group unsubstituted or substituted with a halogen; a (C6-C18)aryl group unsubstituted or substituted with deuterium or a 5- to 12-membered heteroaryl group; an unsubstituted 5- to 15-membered heteroaryl group; an unsubstituted tri(C1-C6)alkylsilyl group; or an unsubstituted tri(C6-C12)arylsilyl group.

According to one embodiment of the present invention, in formula 1, above, L₁ represents a single bond or a substituted or unsubstituted (C6-C20)arylene group; X₁ and X₂ each independently represent CR′ or N; Y₁ represents —O—, —S—, —CR₁₁R₁₂—, —SiR₁₃R₁₄— or —NR₁₅—, provided that when Y₁ is —NR₁₅—, L₁ is not a single bond; Ar represents hydrogen, a substituted or unsubstituted (C6-C20)aryl group, or a substituted or unsubstituted 5- to 20-membered heteroaryl group; and Ar₁, Ar₂, R′, R₁ to R₃, and R₁₁ to R₁₅ each independently represent: hydrogen, a substituted or unsubstituted (C1-C10)alkyl group, a substituted or unsubstituted (C6-C20)aryl group, a substituted or unsubstituted 5- to 20-membered heteroaryl group, a substituted or unsubstituted tri(C1-C10)alkylsilyl group, or a substituted or unsubstituted tri(C6-C20)arylsilyl group.

According to another embodiment of the present invention, in formula 1, above, L₁ represents a single bond; or a (C6-C15)arylene group unsubstituted or substituted with a (C1-C6)alkyl group or a 5- to 12-membered heteroaryl group; X₁ and X₂ each independently represent CR′ or N; Y₁ represents —O—, —S—, —CR₁₁R₁₂—, —SiR₁₃R₁₄— or —NR₁₅—, provided that when Y₁ is —NR₁₅—, L₁ is not a single bond; Ar represents hydrogen; a (C6-C18)aryl group unsubstituted or substituted with a 5- to 12-membered heteroaryl group; or a 5- to 12-membered heteroaryl group unsubstituted or substituted with a (C6-C12)aryl group; and Ar₁, Ar₂, R′, R₁ to R₃, and R₁₁ to R₁₅ each independently represent: hydrogen; a (C1-C6)alkyl group unsubstituted or substituted with a halogen; a (C6-C18)aryl group unsubstituted or substituted with deuterium or a 5- to 12-membered heteroaryl group; an unsubstituted 5- to 15-membered heteroaryl group; an unsubstituted tri(C1-C6)alkylsilyl group; or an unsubstituted tri(C6-C12)arylsilyl group.

L₁ can represent a single bond, a 3- to 30-membered heteroarylene group, or a (C6-C30)arylene group; X₁ and X₂ each independently represent CR′ or N; Y₁ represents —O—, —S—, —CR₁₁R₁₂—, —SiR₁₃R₁₄— or —NR₁₅—, provided that when Y₁ is —NR₁₅—, L₁ is not a single bond; Ar represents hydrogen, a (C6-C30)aryl group, or a 3- to 30-membered heteroaryl group; Ar₁, Ar₂, R′, R₁, R₂, R₃, and R₁₁ to R₁₅ each independently represent hydrogen, a (C1-C30)alkyl group, a (C6-C30)aryl group, a 3- to 30-membered heteroaryl group, a (C1-C30)alkylsilyl group, or a (C6-C30)arylsilyl group; a represents an integer of 1 or 2; where a is an integer of 2, each of R₁ is the same or different; b represents an integer of 1 to 4; where b is an integer of 2 or more, each of R₂ is the same or different; c represents an integer of 1 to 3; where c is an integer of 2 or more, each of R₃ is the same or different; and the heteroarylene and arylene groups in L₁, and the alkyl, aryl and heteroaryl groups in Ar, Ar₁, Ar₂, R′, R₁ to R₃, and R₁₁ to R₁₅ can be further substituted with at least one selected from the group consisting of deuterium, a halogen, a (C1-C30)alkyl group, a (C6-C30)aryl group, a 3- to 30-membered heteroaryl group, a (C3-C30)cycloalkyl group, and a (C6-C30)aryl(C1-C30)alkyl group.

Specifically, L₁ can represent a single bond, a phenylene, a biphenylene, a terphenylene, an indenylene, a fluorenylene, a triphenylenylene, a pyrenylene, a perylenylene, a fluoranthenylene, a thiophenylene, a pyrrolylene, a pyrazolylene, a thiazolylene, an oxazolylene, an oxadiazolylene, a triazinylene, a tetrazinylene, a triazolylene, a tetrazolylene, a furazanylene, a pyridylene, a pyrimidylene, a benzofuranylene, a benzothiophenylene, an indolene, a benzoimidazolylene, a benzothiazolylene, a benzoisothiazolylene, a benzoisoxazolylene, a benzoxazolylene, a benzothiadiazolylene, a dibenzofuranylene or a dibenzothiophenylene; Ar, Ar₁, Ar₂, R′, R₁, R₂, R₃, and R₁₁ to R₁₅ each independently represent: hydrogen, a fluoryl, a methyl, an ethyl, an n-propyl, an i-propyl, an n-butyl, an i-butyl, a t-butyl, an n-pentyl, an i-pentyl, an n-hexyl, an n-heptyl, an n-octyl, a 2-ethylhexyl, an n-nonyl, a decyl, a dodecyl, a hexadecyl, a trifluoromethyl, a perfluoroethyl, a trifluoroethyl, a perfluoropropyl, a perfluorobutyl, a cyclopropyl, a cyclobutyl, a cyclopentyl, a phenyl, a biphenyl, a fluorenyl, a fluoranthenyl, a terphenyl, a pyrenyl, a perylenyl, a pyridyl, a pyrimidyl, a pyrrolyl, a furanyl, a thiophenyl, an imidazolyl, a benzoimidazolyl, a quinolyl, a triazinyl, a benzofuranyl, a dibenzofuranyl, a benzothiophenyl, a dibenzothiophenyl, a pyrazolyl, an indolyl, an indenyl, a carbazolyl, a thiazolyl, an oxazolyl, a benzothiazolyl, a benzoxazolyl, a quinoxalinyl, an N-carbazolyl, a pyrrolyl, a triphenylsilyl, or a trimethylsilyl; and the substituents in L₁, Ar, Ar₁, Ar₂, R′, R₁, R₂, R₃ and R₁₁ to R₁₅ can be further substituted with at least one selected from the group consisting of: deuterium, a chlorine, a fluorine, a methyl, an ethyl, an n-propyl, an i-propyl, an n-butyl, an i-butyl, a t-butyl, an n-pentyl, an i-pentyl, an n-hexyl, an n-heptyl, an n-octyl, a 2-ethylhexyl, an n-nonyl, a decyl, a dodecyl, a hexadecyl, a trifluoromethyl, a perfluoroethyl, a trifluoroethyl, a perfluoropropyl, a perfluorobutyl, a cyclopropyl, a cyclobutyl, a cyclopentyl, a cyclohexyl, a cycloheptyl, a phenyl, a biphenyl, a terphenyl, a fluorenyl, a fluoranthenyl, a triphenylenyl, a thiophenyl, a benzothiophenyl, a benzofuranyl, a pyridyl, an indenyl, an imidazolyl, a quinolyl, an isoquinolyl, a trimethylsilyl, a triethylsilyl, a tripropylsilyl, a tri(t-butyl)silyl, a t-butyldimethylsilyl, a dimethylphenylsilyl and a triphenylsilyl.

The representative organic electroluminescent compounds of the present invention include the following compounds, but not limited thereto:

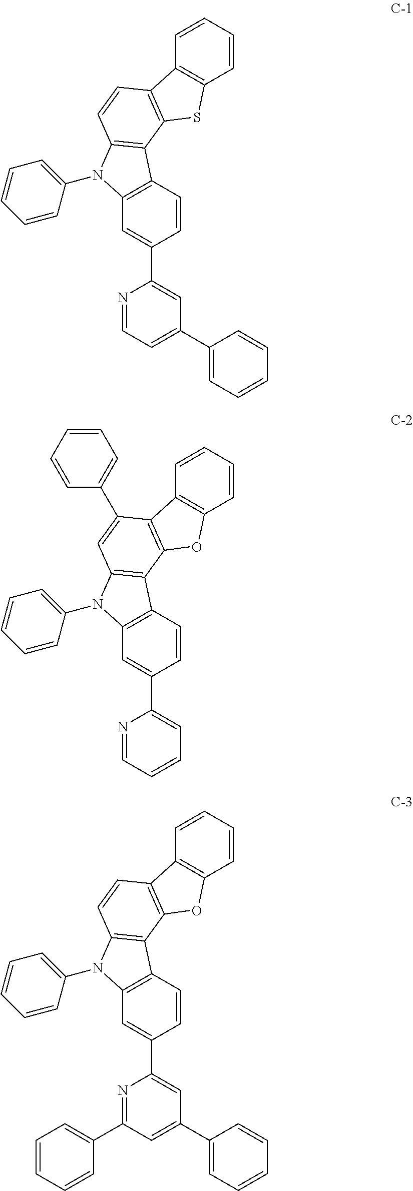 [SMILES: c1ccc(-c2ccnc(-c3ccc4c5c6sc7ccccc7c6ccc5n(-c5ccccc5)c4c3)c2)cc1 ; c1ccc(-c2cc3c(c4ccc(-c5ccccn5)cc4n3-c3ccccc3)c3oc4ccccc4c23)cc1 ; c1ccc(-c2cc(-c3ccccc3)nc(-c3ccc4c5c6oc7ccccc7c6ccc5n(-c5ccccc5)c4c3)c2)cc1]

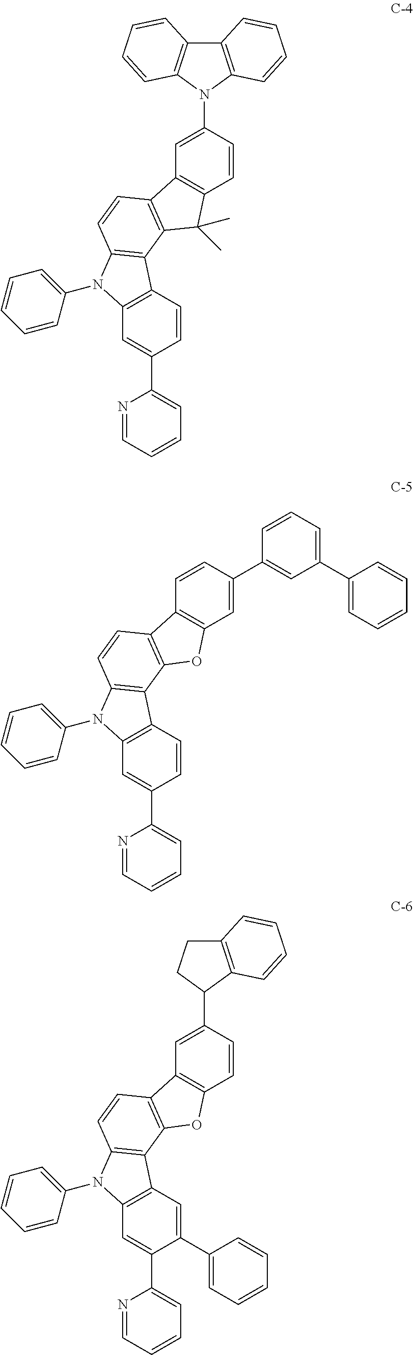 [SMILES: CC1(C)c2ccc(-n3c4ccccc4c4ccccc43)cc2-c2ccc3c(c21)c1ccc(-c2ccccn2)cc1n3-c1ccccc1 ; c1ccc(-c2cccc(-c3ccc4c(c3)oc3c4ccc4c3c3ccc(-c5ccccn5)cc3n4-c3ccccc3)c2)cc1 ; c1ccc(-c2cc3c4c5oc6ccc(C7CCc8ccccc87)cc6c5ccc4n(-c4ccccc4)c3cc2-c2ccccn2)cc1]

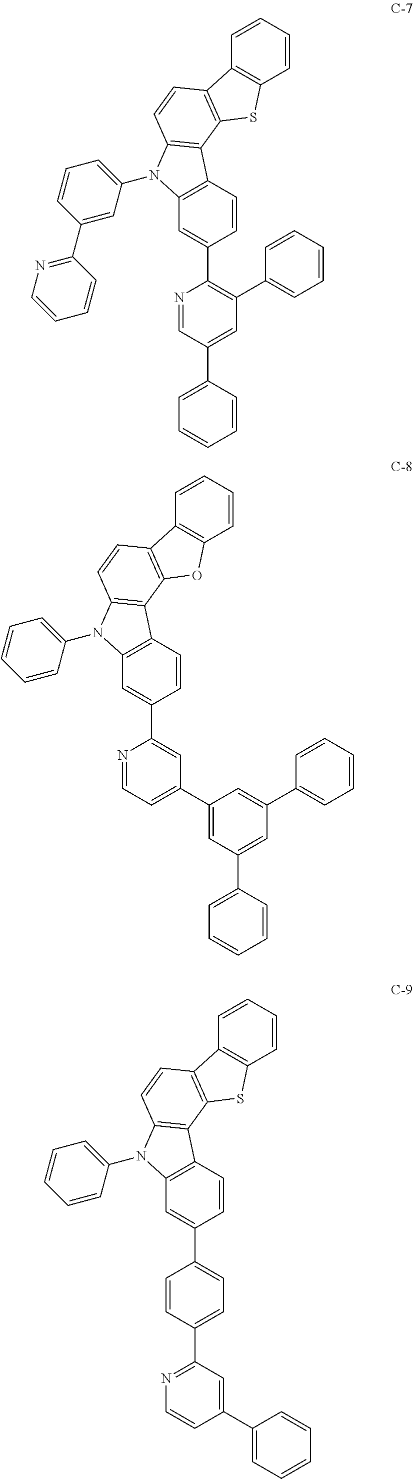

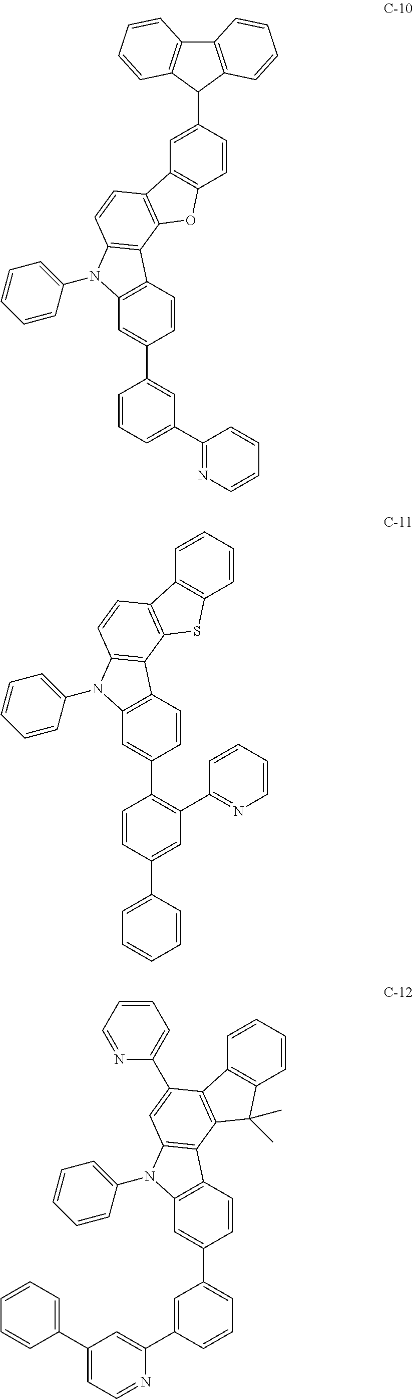

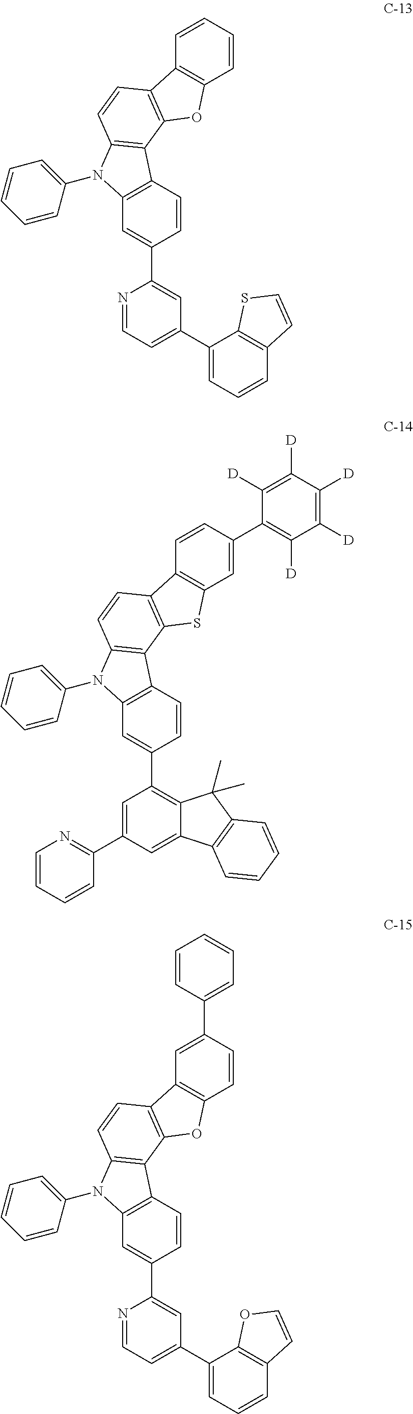 [SMILES: c1ccc(-n2c3cc(-c4cc(-c5cccc6ccsc56)ccn4)ccc3c3c4oc5ccccc5c4ccc32)cc1 ; [2H]c1c([2H])c([2H])c(-c2ccc3c(c2)sc2c3ccc3c2c2ccc(-c4cc(-c5ccccn5)cc5c4C(C)(C)c4ccccc4-5)cc2n3-c2ccccc2)c([2H])c1[2H] ; c1ccc(-c2ccc3oc4c(ccc5c4c4ccc(-c6cc(-c7cccc8ccoc78)ccn6)cc4n5-c4ccccc4)c3c2)cc1]

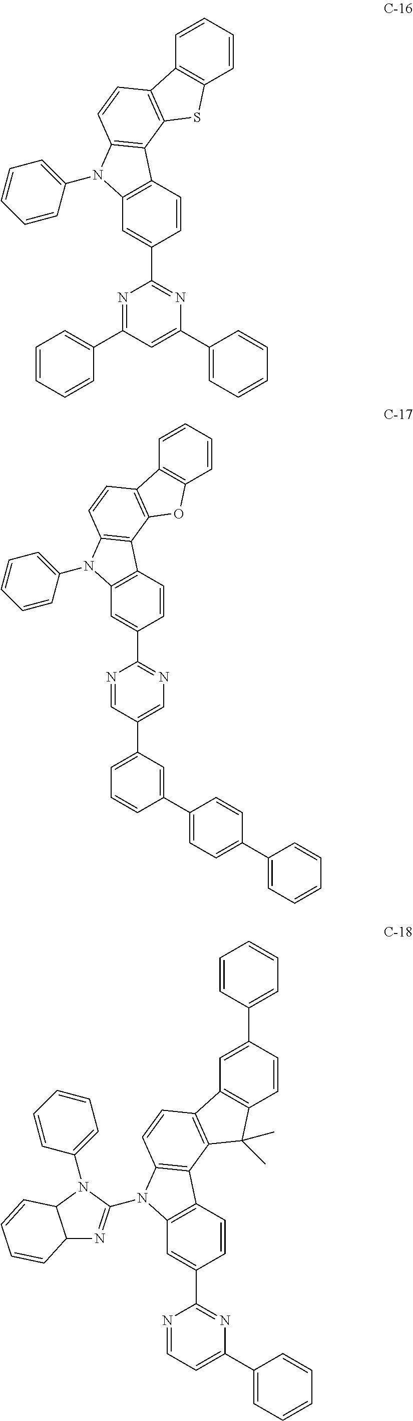 [SMILES: c1ccc(-c2cc(-c3ccccc3)nc(-c3ccc4c5c6sc7ccccc7c6ccc5n(-c5ccccc5)c4c3)n2)cc1 ; c1ccc(-c2ccc(-c3cccc(-c4cnc(-c5ccc6c7c8oc9ccccc9c8ccc7n(-c7ccccc7)c6c5)nc4)c3)cc2)cc1 ; CC1(C)c2ccc(-c3ccccc3)cc2-c2ccc3c(c21)c1ccc(-c2nccc(-c4ccccc4)n2)cc1n3C1=NC2C=CC=CC2N1c1ccccc1]

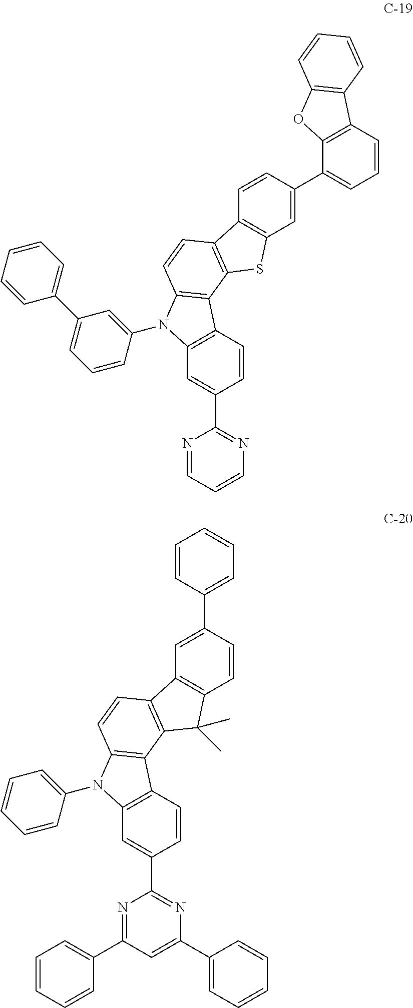

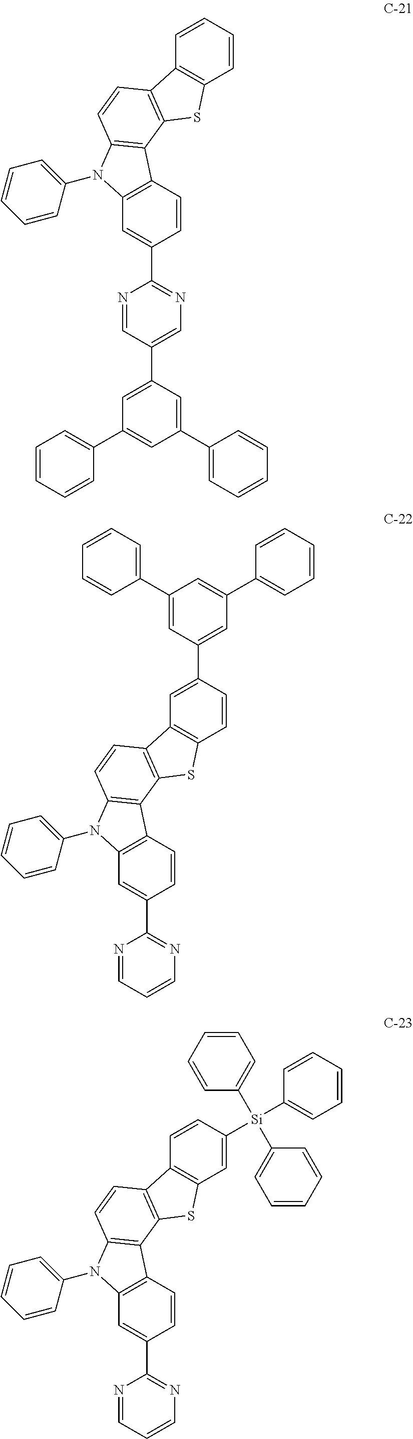 [SMILES: c1ccc(-c2cc(-c3ccccc3)cc(-c3cnc(-c4ccc5c6c7sc8ccccc8c7ccc6n(-c6ccccc6)c5c4)nc3)c2)cc1 ; c1ccc(-c2cc(-c3ccccc3)cc(-c3ccc4sc5c(ccc6c5c5ccc(-c7ncccn7)cc5n6-c5ccccc5)c4c3)c2)cc1 ; c1ccc(-n2c3cc(-c4ncccn4)ccc3c3c4sc5cc([Si](c6ccccc6)(c6ccccc6)c6ccccc6)ccc5c4ccc32)cc1]

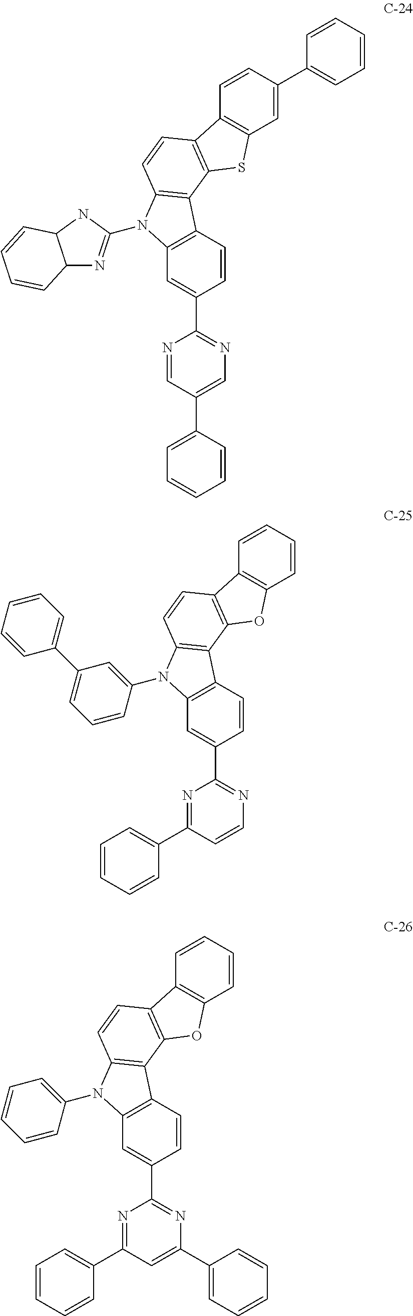 [SMILES: C1=CC2N=C(n3c4cc(-c5ncc(-c6ccccc6)cn5)ccc4c4c5sc6cc(-c7ccccc7)ccc6c5ccc43)NC2C=C1 ; c1ccc(-c2cccc(-n3c4cc(-c5nccc(-c6ccccc6)n5)ccc4c4c5oc6ccccc6c5ccc43)c2)cc1 ; c1ccc(-c2cc(-c3ccccc3)nc(-c3ccc4c5c6oc7ccccc7c6ccc5n(-c5ccccc5)c4c3)n2)cc1]

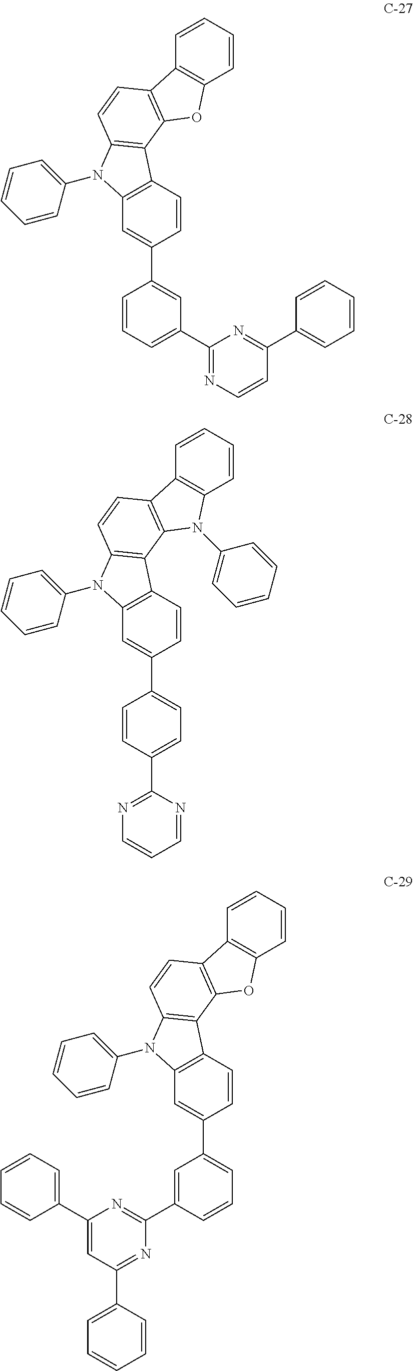

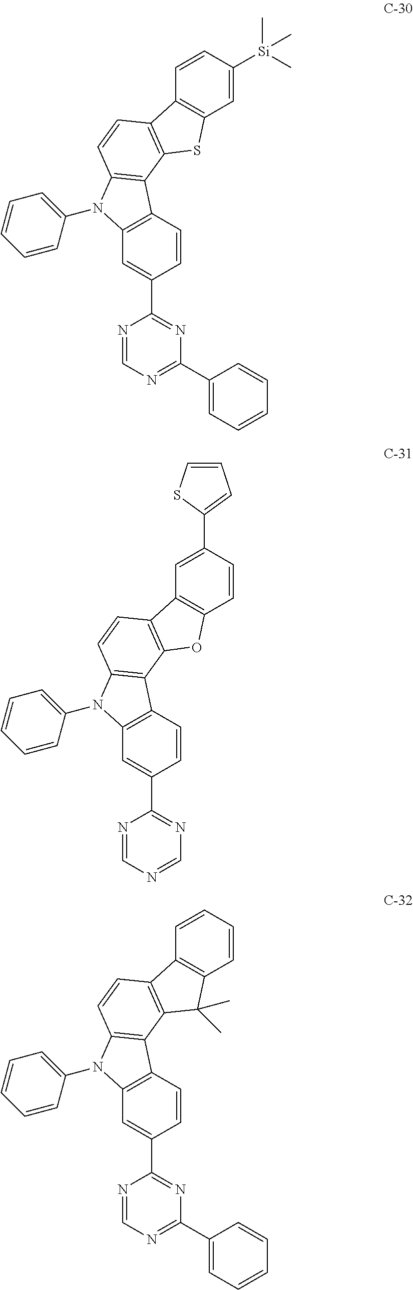

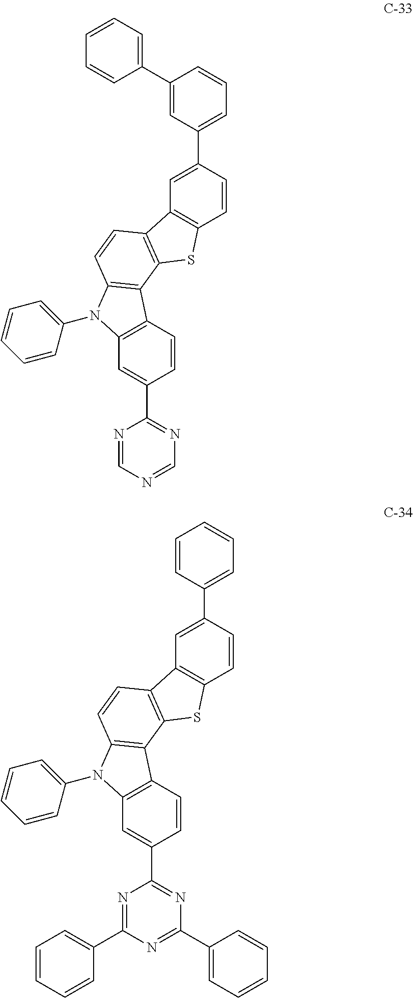 [SMILES: c1ccc(-c2cccc(-c3ccc4sc5c(ccc6c5c5ccc(-c7ncncn7)cc5n6-c5ccccc5)c4c3)c2)cc1 ; c1ccc(-c2ccc3sc4c(ccc5c4c4ccc(-c6nc(-c7ccccc7)nc(-c7ccccc7)n6)cc4n5-c4ccccc4)c3c2)cc1]

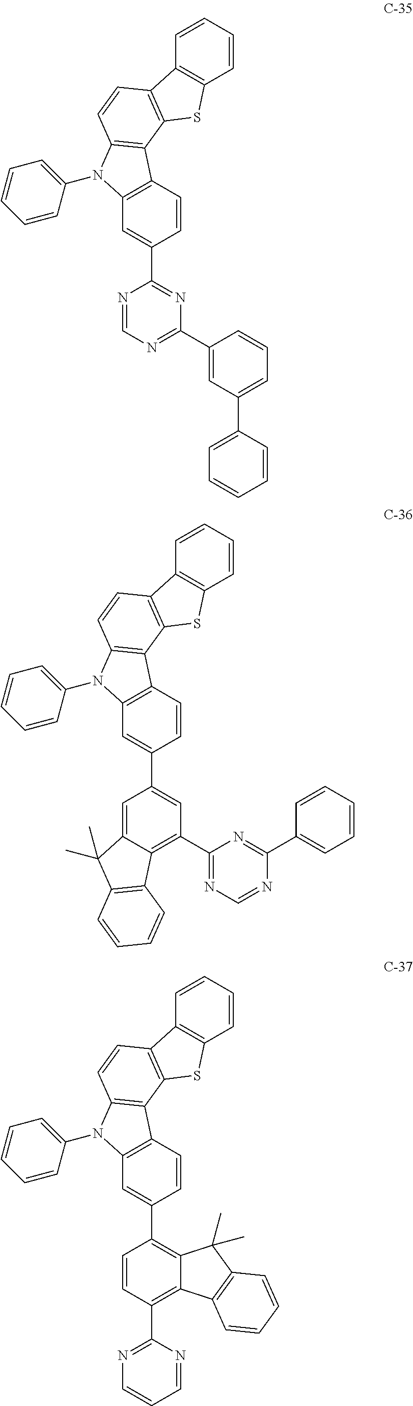

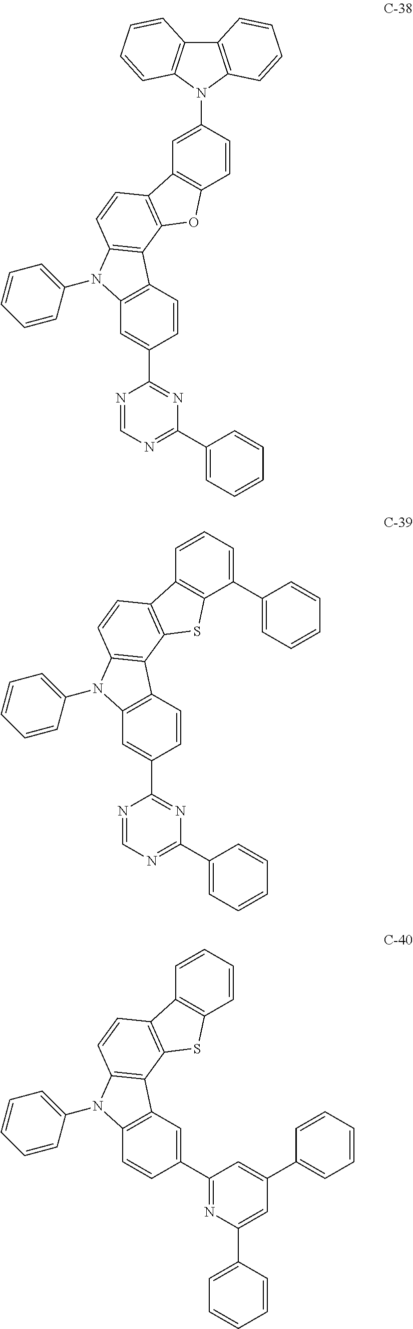

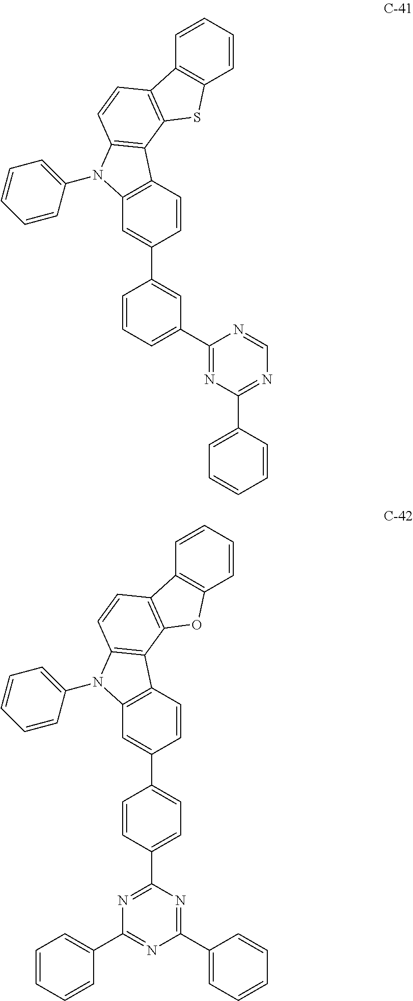

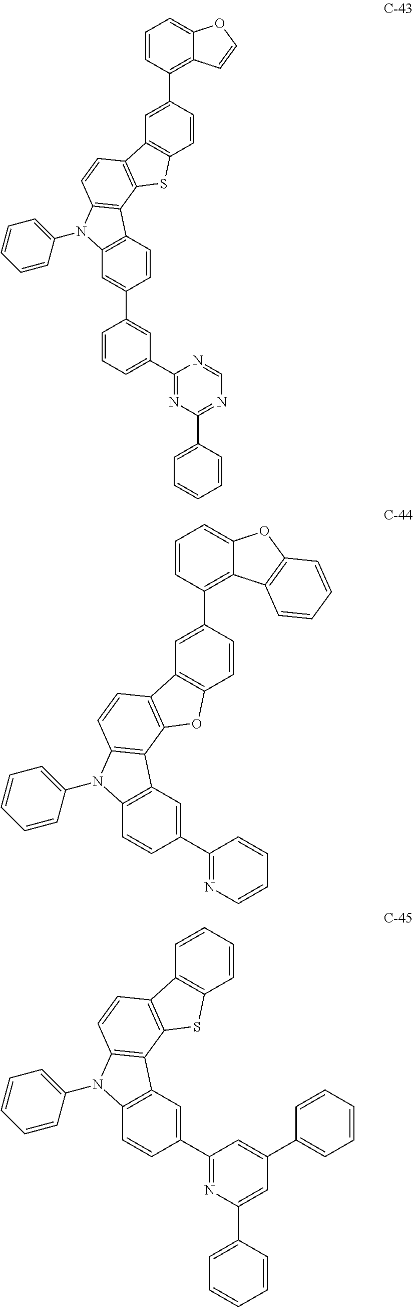

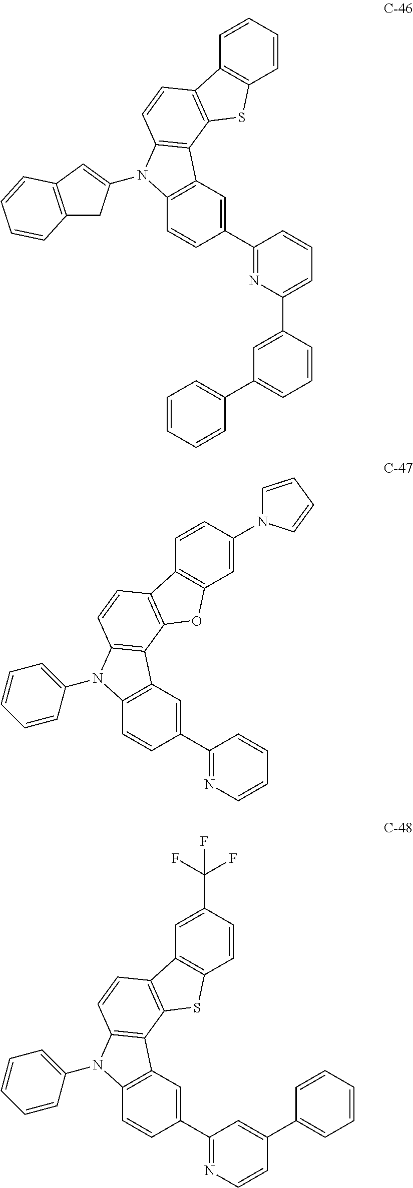 [SMILES: C1=C(n2c3ccc(-c4cccc(-c5cccc(-c6ccccc6)c5)n4)cc3c3c4sc5ccccc5c4ccc32)Cc2ccccc21 ; c1ccc(-n2c3ccc(-c4ccccn4)cc3c3c4oc5cc(-n6cccc6)ccc5c4ccc32)cc1 ; FC(F)(F)c1ccc2sc3c(ccc4c3c3cc(-c5cc(-c6ccccc6)ccn5)ccc3n4-c3ccccc3)c2c1]

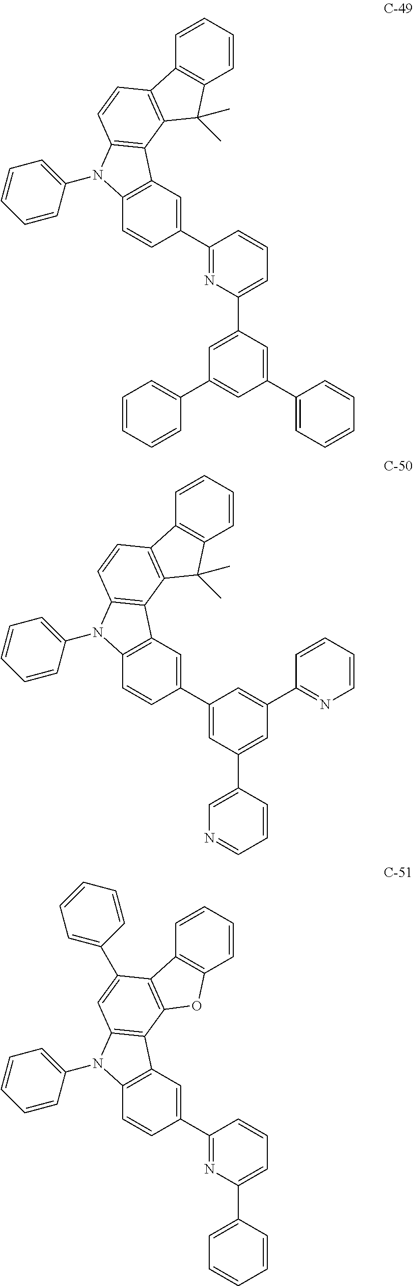 [SMILES: CC1(C)c2ccccc2-c2ccc3c(c21)c1cc(-c2cccc(-c4cc(-c5ccccc5)cc(-c5ccccc5)c4)n2)ccc1n3-c1ccccc1 ; CC1(C)c2ccccc2-c2ccc3c(c21)c1cc(-c2cc(-c4cccnc4)cc(-c4ccccn4)c2)ccc1n3-c1ccccc1 ; c1ccc(-c2cccc(-c3ccc4c(c3)c3c5oc6ccccc6c5c(-c5ccccc5)cc3n4-c3ccccc3)n2)cc1]

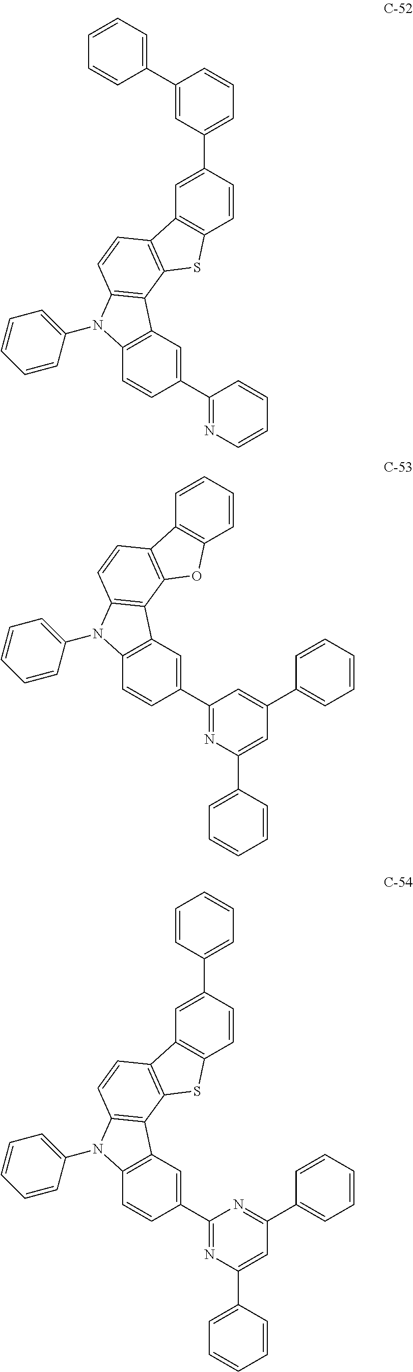

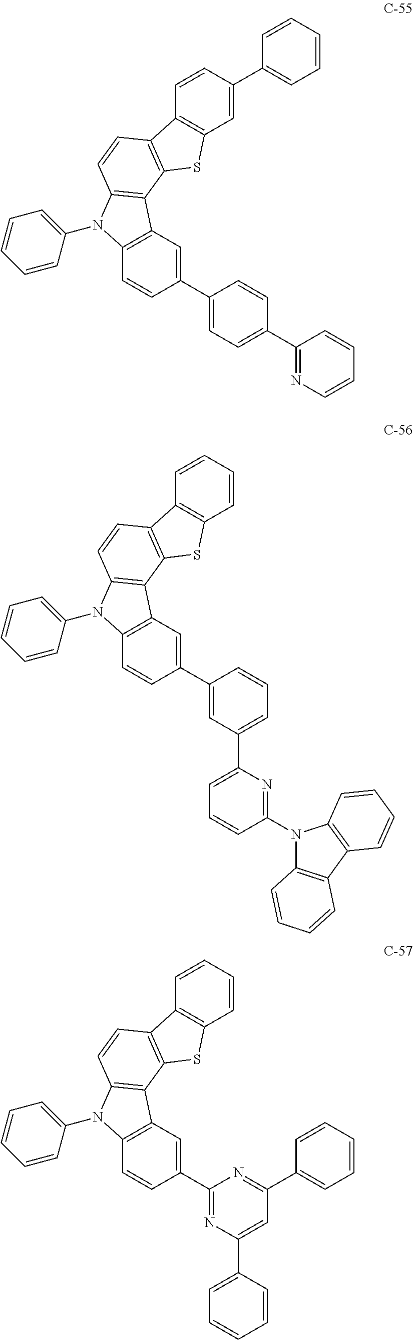 [SMILES: c1ccc(-c2ccc3c(c2)sc2c3ccc3c2c2cc(-c4ccc(-c5ccccn5)cc4)ccc2n3-c2ccccc2)cc1 ; c1ccc(-n2c3ccc(-c4cccc(-c5cccc(-n6c7ccccc7c7ccccc76)n5)c4)cc3c3c4sc5ccccc5c4ccc32)cc1 ; c1ccc(-c2cc(-c3ccccc3)nc(-c3ccc4c(c3)c3c5sc6ccccc6c5ccc3n4-c3ccccc3)n2)cc1]

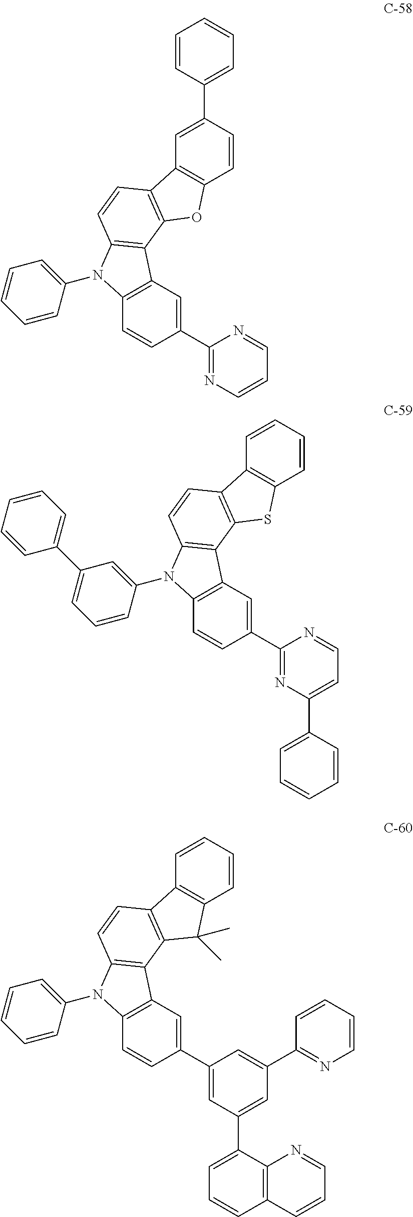

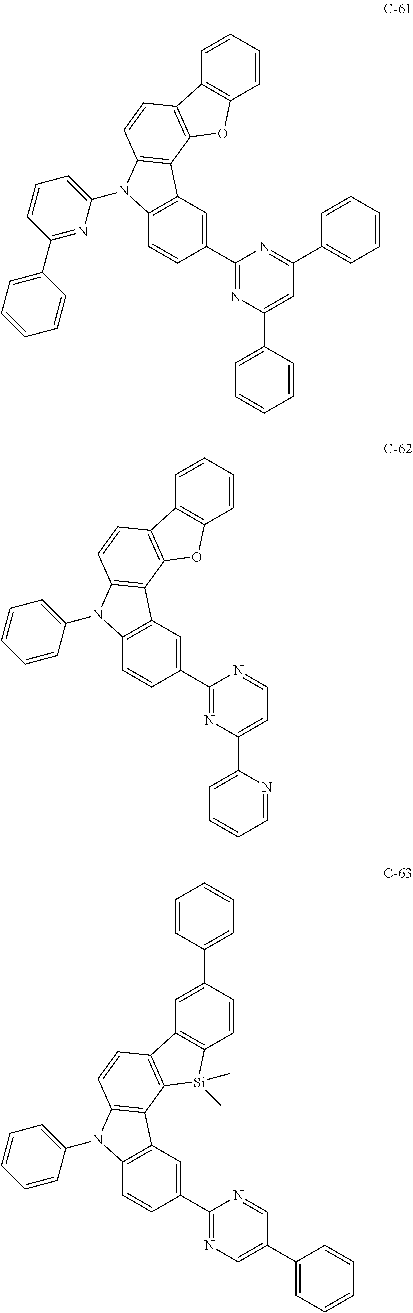 [SMILES: c1ccc(-c2cccc(-n3c4ccc(-c5nc(-c6ccccc6)cc(-c6ccccc6)n5)cc4c4c5oc6ccccc6c5ccc43)n2)cc1 ; c1ccc(-n2c3ccc(-c4nccc(-c5ccccn5)n4)cc3c3c4oc5ccccc5c4ccc32)cc1 ; C[Si]1(C)c2ccc(-c3ccccc3)cc2-c2ccc3c(c21)c1cc(-c2ncc(-c4ccccc4)cn2)ccc1n3-c1ccccc1]

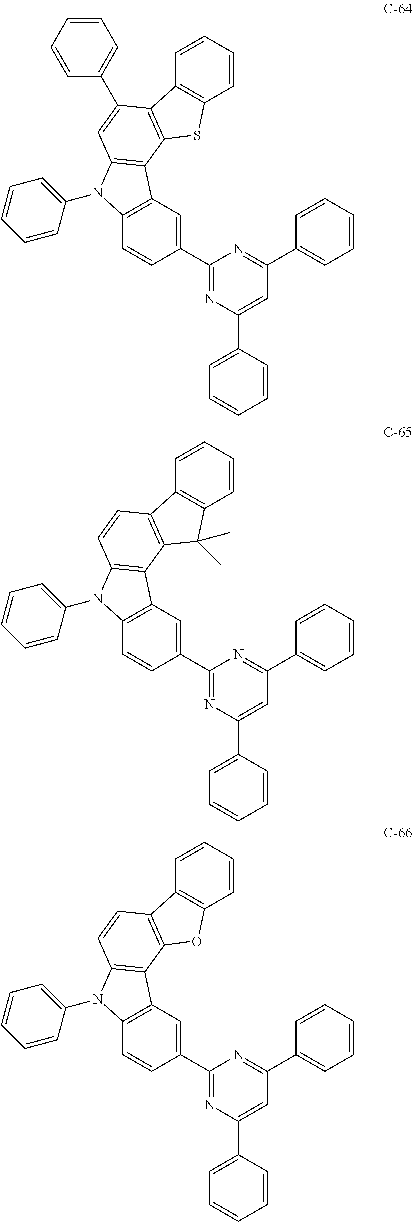

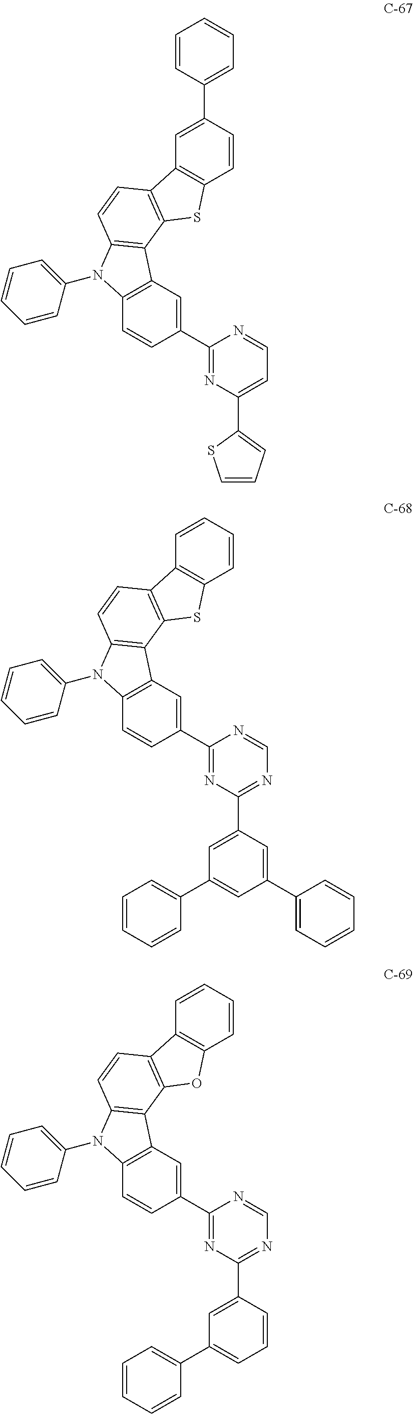

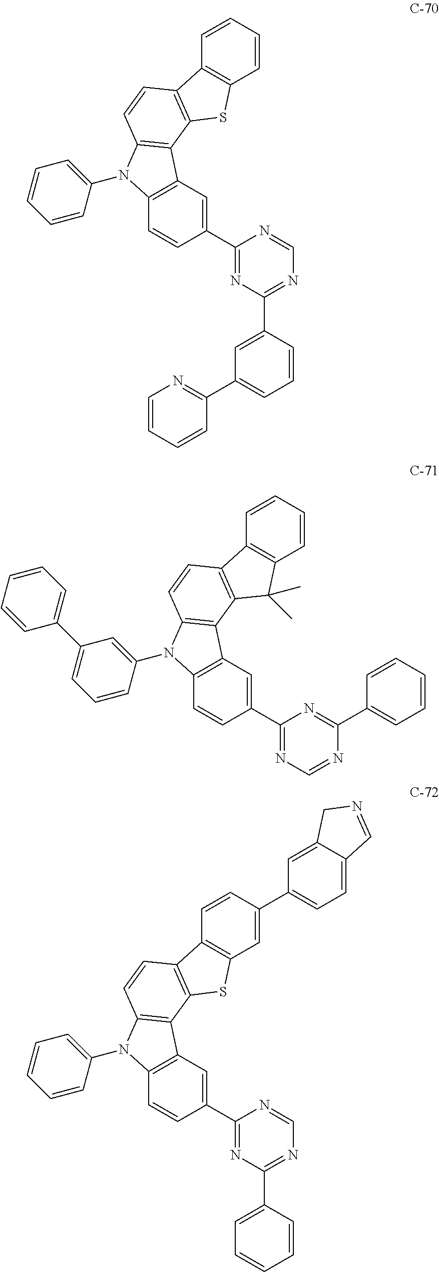

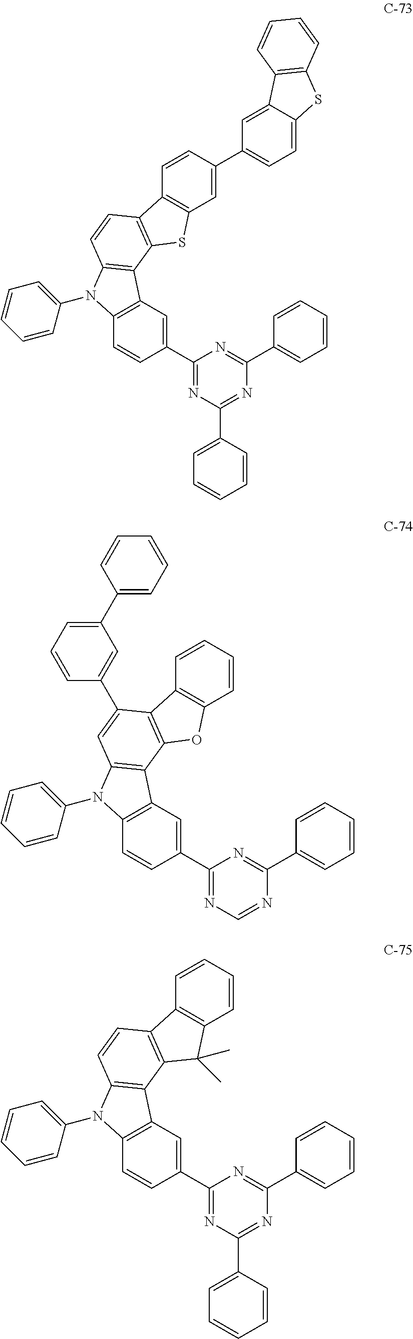 [SMILES: c1ccc(-c2nc(-c3ccccc3)nc(-c3ccc4c(c3)c3c5sc6cc(-c7ccc8sc9ccccc9c8c7)ccc6c5ccc3n4-c3ccccc3)n2)cc1 ; c1ccc(-c2cccc(-c3cc4c(c5cc(-c6ncnc(-c7ccccc7)n6)ccc5n4-c4ccccc4)c4oc5ccccc5c34)c2)cc1 ; CC1(C)c2ccccc2-c2ccc3c(c21)c1cc(-c2nc(-c4ccccc4)nc(-c4ccccc4)n2)ccc1n3-c1ccccc1]

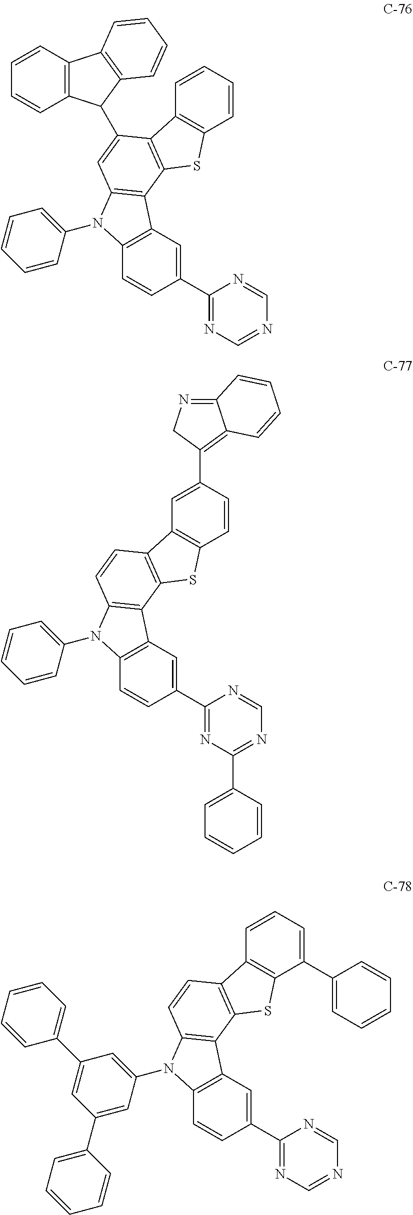

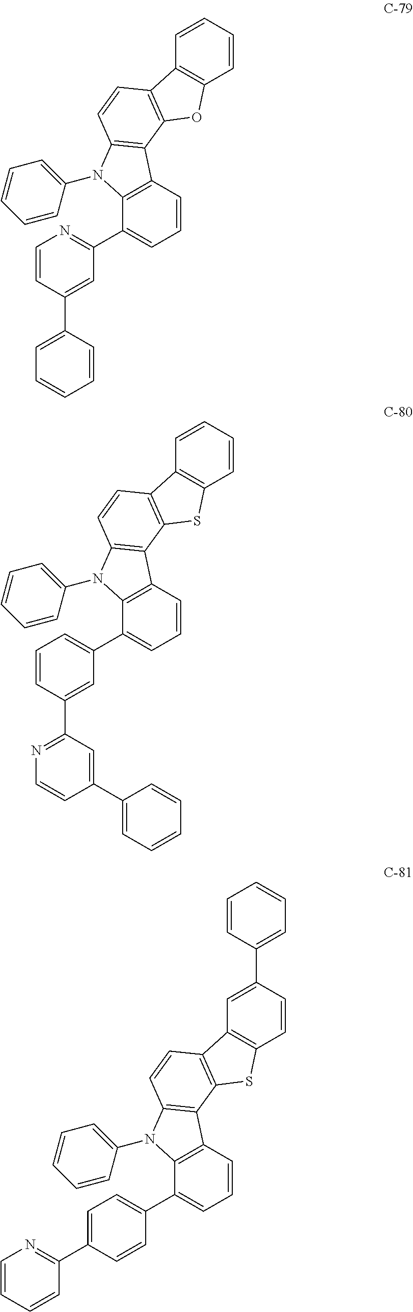 [SMILES: c1ccc(-c2ccnc(-c3cccc4c5c6oc7ccccc7c6ccc5n(-c5ccccc5)c34)c2)cc1 ; c1ccc(-c2ccnc(-c3cccc(-c4cccc5c6c7sc8ccccc8c7ccc6n(-c6ccccc6)c45)c3)c2)cc1 ; c1ccc(-c2ccc3sc4c(ccc5c4c4cccc(-c6ccc(-c7ccccn7)cc6)c4n5-c4ccccc4)c3c2)cc1]

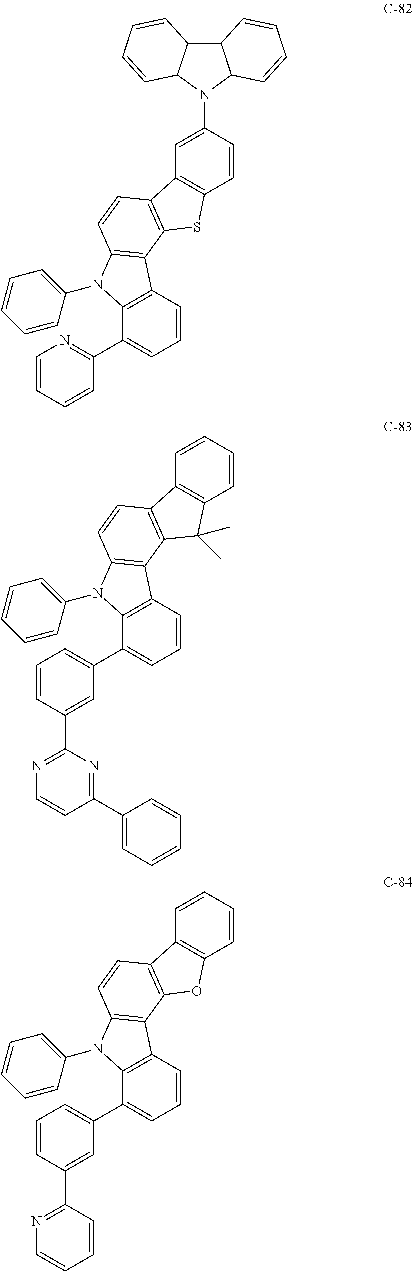 [SMILES: C1=CC2C3C=CC=CC3N(c3ccc4sc5c(ccc6c5c5cccc(-c7ccccn7)c5n6-c5ccccc5)c4c3)C2C=C1 ; CC1(C)c2ccccc2-c2ccc3c(c21)c1cccc(-c2cccc(-c4nccc(-c5ccccc5)n4)c2)c1n3-c1ccccc1 ; c1ccc(-n2c3ccc4c5ccccc5oc4c3c3cccc(-c4cccc(-c5ccccn5)c4)c32)cc1]

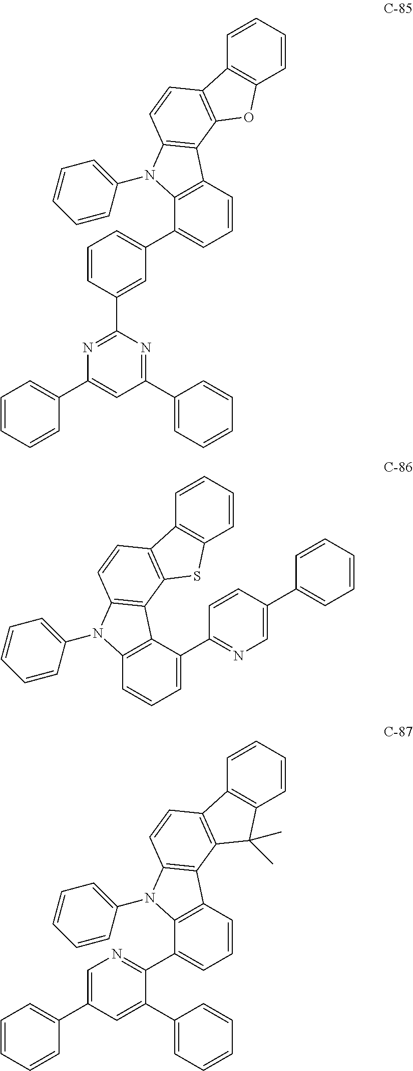

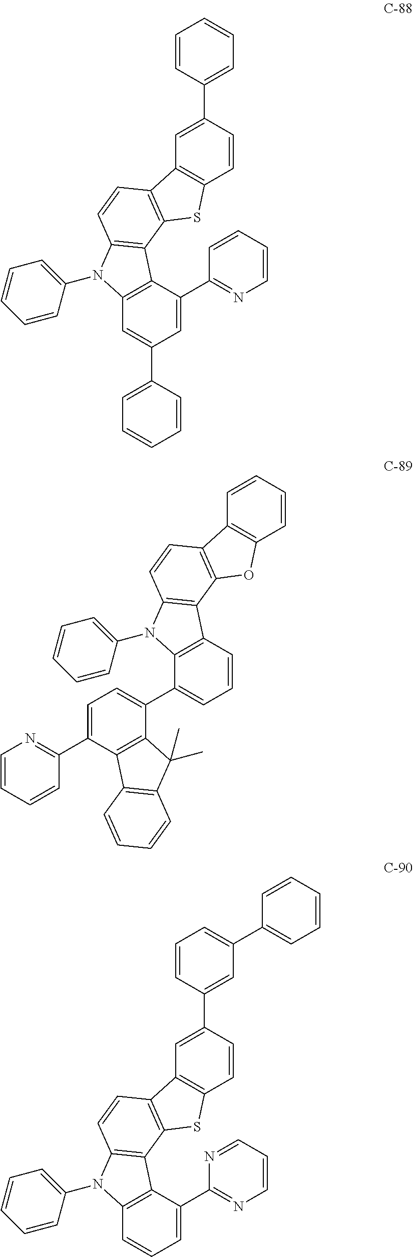 [SMILES: c1ccc(-c2ccc3sc4c(ccc5c4c4c(-c6ccccn6)cc(-c6ccccc6)cc4n5-c4ccccc4)c3c2)cc1 ; CC1(C)c2ccccc2-c2c(-c3ccccn3)ccc(-c3cccc4c5c6oc7ccccc7c6ccc5n(-c5ccccc5)c34)c21 ; c1ccc(-c2cccc(-c3ccc4sc5c(ccc6c5c5c(-c7ncccn7)cccc5n6-c5ccccc5)c4c3)c2)cc1]

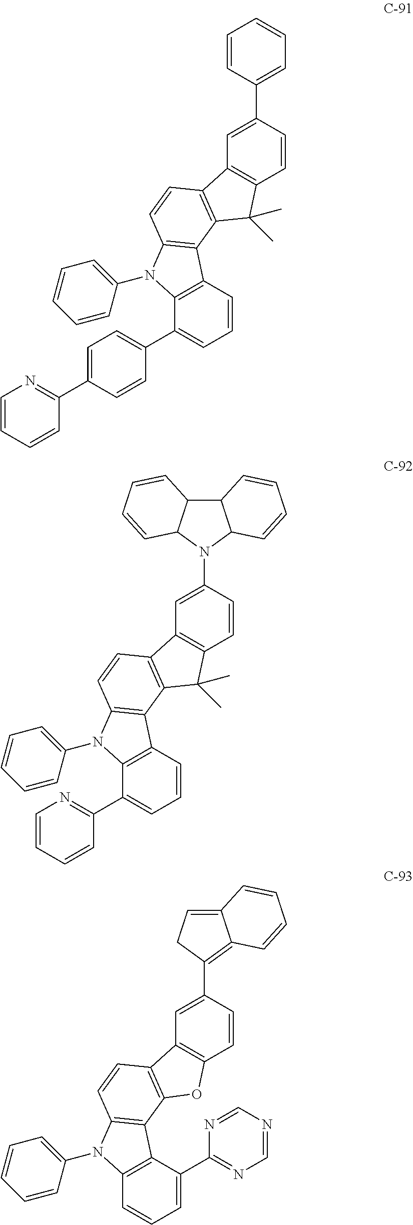 [SMILES: CC1(C)c2ccc(-c3ccccc3)cc2-c2ccc3c(c21)c1cccc(-c2ccc(-c4ccccn4)cc2)c1n3-c1ccccc1 ; CC1(C)c2ccc(N3C4C=CC=CC4C4C=CC=CC43)cc2-c2ccc3c(c21)c1cccc(-c2ccccn2)c1n3-c1ccccc1 ; C1=c2ccccc2=C(c2ccc3oc4c(ccc5c4c4c(-c6ncncn6)cccc4n5-c4ccccc4)c3c2)C1]

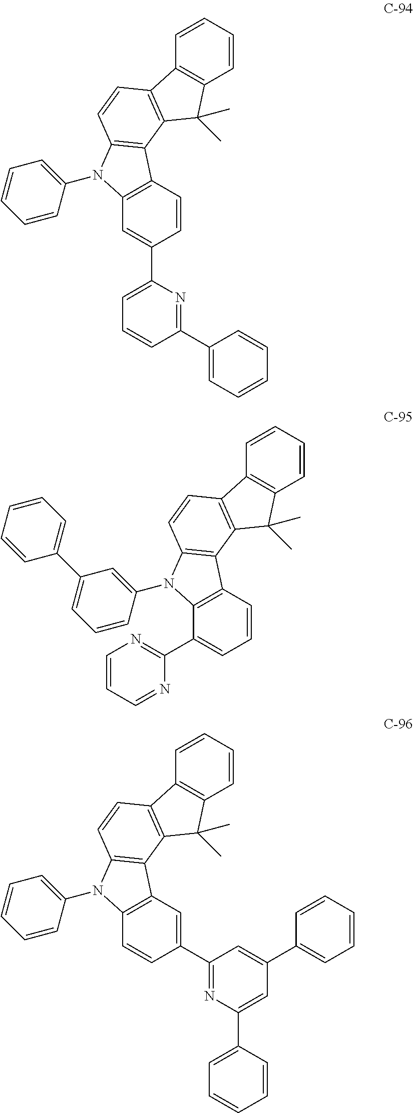

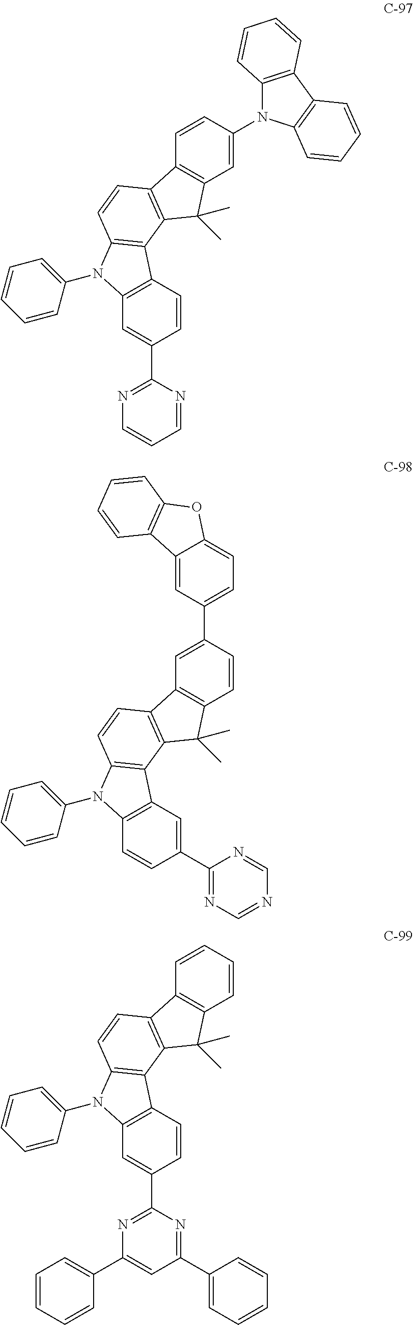

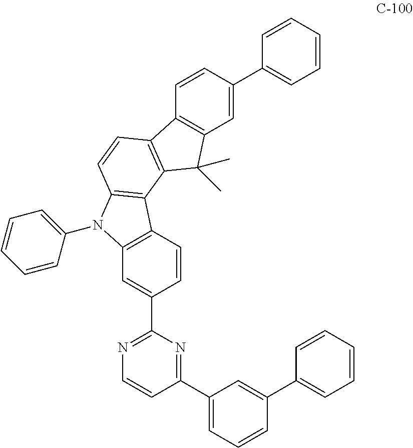 [SMILES: CC1(C)c2cc(-c3ccccc3)ccc2-c2ccc3c(c21)c1ccc(-c2nccc(-c4cccc(-c5ccccc5)c4)n2)cc1n3-c1ccccc1]

The organic electroluminescent compounds of the present invention can be prepared according to the following reaction scheme.

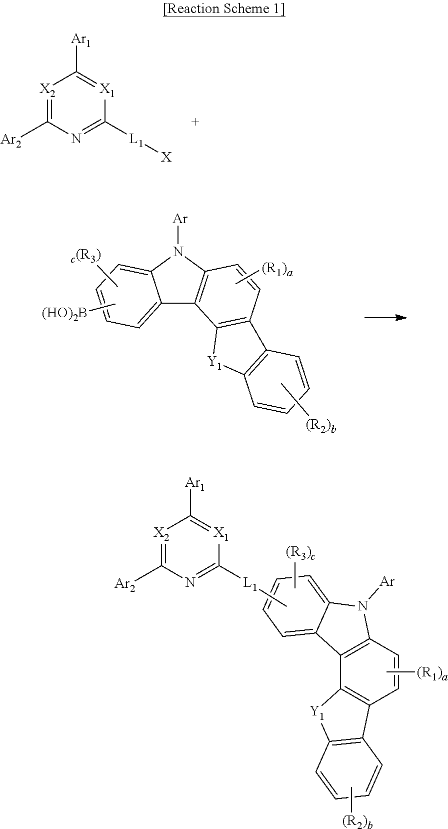

wherein Ar, Ar₁, Ar₂, R₁ to R₃, Y₁, L₁, X₁, X₂, a, b and c are as defined in formula 1 above, and Hal represents a halogen.

In addition, the present invention provides an organic electroluminescent material comprising the organic electroluminescent compound of formula 1, and an organic electroluminescent device comprising the material.

The above material can be comprised of the organic electroluminescent compound according to the present invention alone, or can further include conventional materials generally used in organic electroluminescent materials.

Said organic electroluminescent device comprises a first electrode, a second electrode, and at least one organic layer between said first and second electrodes. Said organic layer may comprise at least one organic electroluminescent compound of formula 1 according to the present invention, or an organic electroluminescent material comprising the compound.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, a hole blocking layer and an electron blocking layer.

The organic electroluminescent compound according to the present invention can be comprised of in the light-emitting layer. Where used in the light-emitting layer, the organic electroluminescent compound according to the present invention can be comprised as a host material.

The light-emitting layer can further comprise at least one dopant and, if needed, another compound as a second host material in addition to the organic electroluminescent compound according to the present invention, wherein the ratio of the organic electroluminescent compound according to the present invention (a first host material) to the second host material can be in the range of 1:99 to 99:1.

The second host material can be from any of the known phosphorescent dopants. Specifically, the phosphorescent dopant selected from the group consisting of the compounds of formula 2 to 6 below is preferable in view of luminous efficiency.

H-(Cz-L₄)ₕ-M (2)

H-(Cz)ᵢ-L₄-M (3)

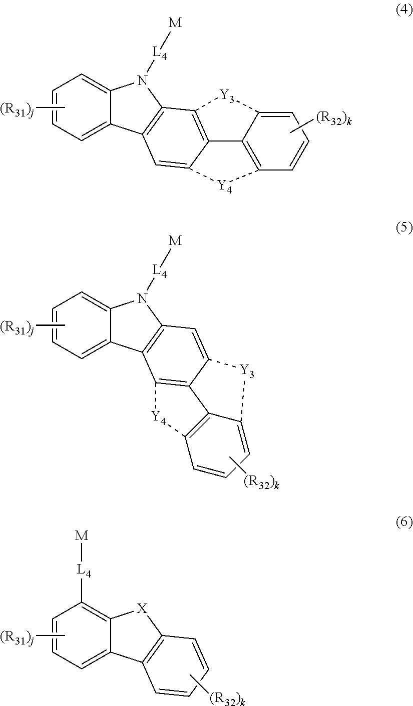

wherein Cz represents the following structure;

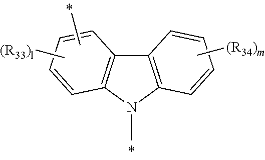

X represents O or S;

R₃₁ to R₃₄ each independently represent hydrogen, deuterium, a halogen, a substituted or unsubstituted (C1-C30)alkyl group, a substituted of unsubstituted (C6-C30)aryl group, a substituted or unsubstituted 3- to 30-membered heteroaryl group, or R₃₅R₃₆R₃₇Si—; R₃₅ to R₃₇ each independently represent a substituted or unsubstituted (C1-C30)alkyl group, or a substituted or unsubstituted (C6-C30)aryl group; L₄ represents a single bond, a substituted or unsubstituted (C6-C30)arylene group, or a substituted or unsubstituted 3- to 30-membered heteroarylene group; M represents a substituted or unsubstituted (C6-C30)aryl group, or a substituted or unsubstituted 3- to 30-membered heteroaryl group; Y₃ and Y₄ represent —O—, —S—, —N(R₄₁)— or —C(R₄₂)(R₄₃)—, provided that Y₃ and Y₄ do not simultaneously exist; R₄₁ to R₄₃ each independently represent a substituted or unsubstituted (C1-C30)alkyl group, a substituted or unsubstituted (C6-C30)aryl group, or a substituted or unsubstituted 3- to 30-membered heteroaryl group, and R₄₂ and R₄₃ are the same or different; h and i each independently represent an integer of 1 to 3; j, k, l and m each independently represent an integer of 0 to 4; and where h, i, j, k, l or m is an integer of 2 or more, each of (Cz-L₄), each of (Cz), each of R₃₁, each of R₃₂, each of R₃₃ or each of R₃₄ is the same or different.

Specifically, preferable examples of the second host material are as follows:

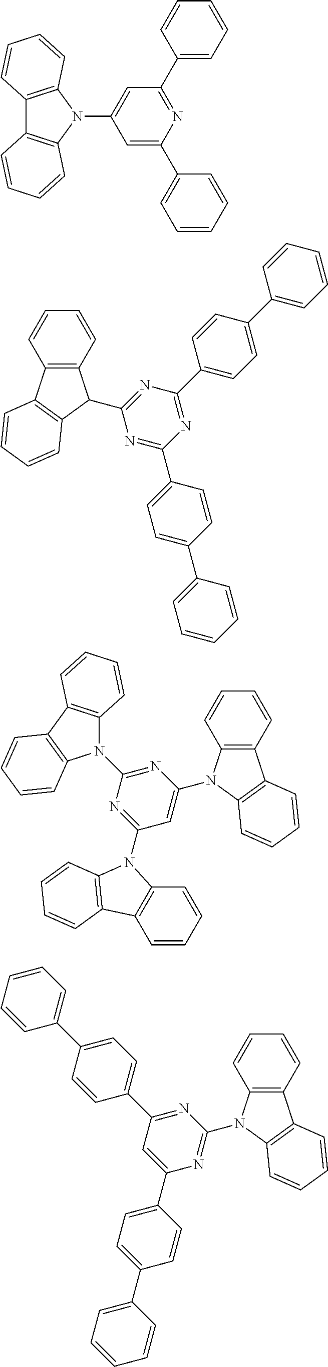 [SMILES: c1ccc(-c2cc(-n3c4ccccc4c4ccccc43)cc(-c3ccccc3)n2)cc1 ; c1ccc(-c2ccc(-c3nc(-c4ccc(-c5ccccc5)cc4)nc(C4c5ccccc5-c5ccccc54)n3)cc2)cc1 ; c1ccc2c(c1)c1ccccc1n2-c1cc(-n2c3ccccc3c3ccccc32)nc(-n2c3ccccc3c3ccccc32)n1 ; c1ccc(-c2ccc(-c3cc(-c4ccc(-c5ccccc5)cc4)nc(-n4c5ccccc5c5ccccc54)n3)cc2)cc1]

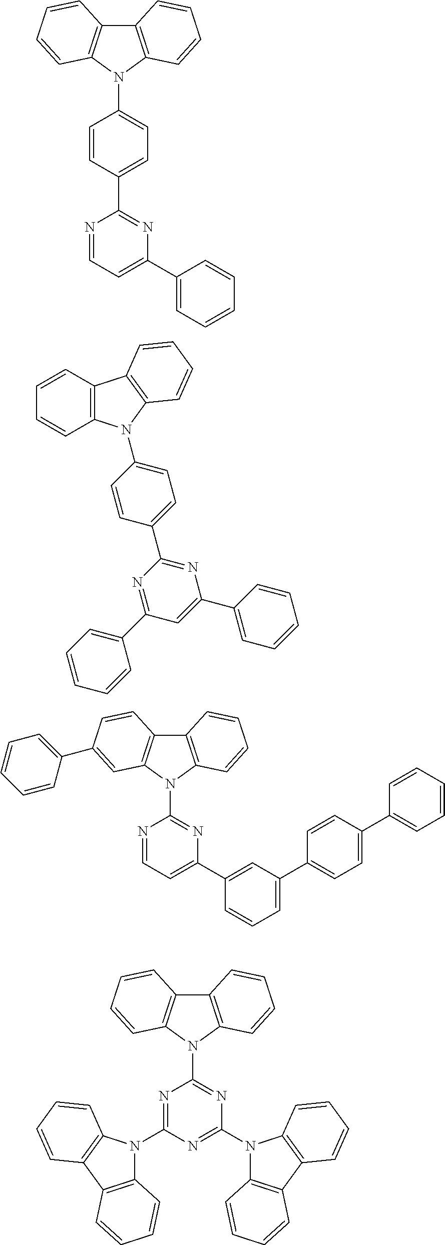

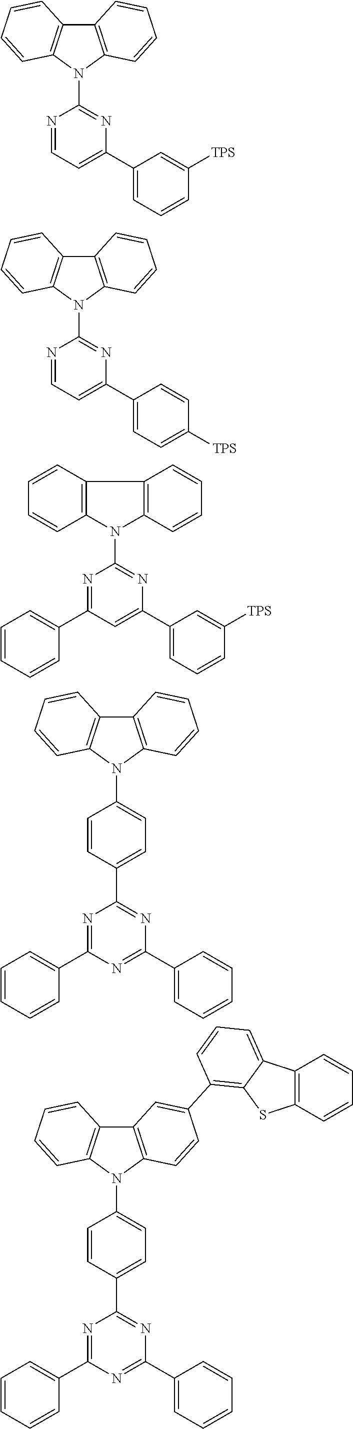

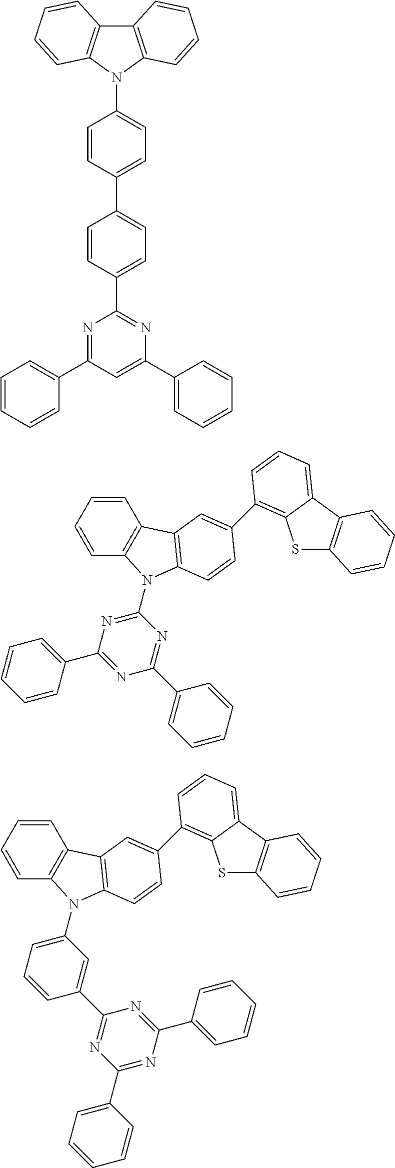

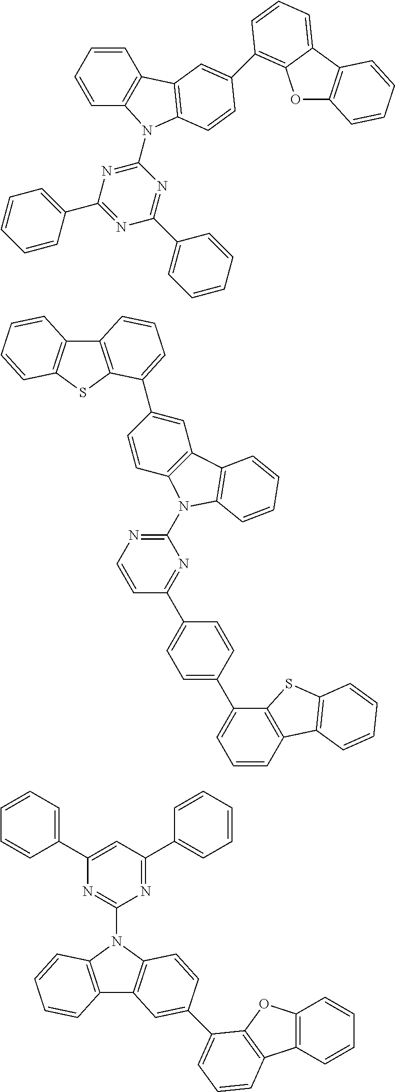

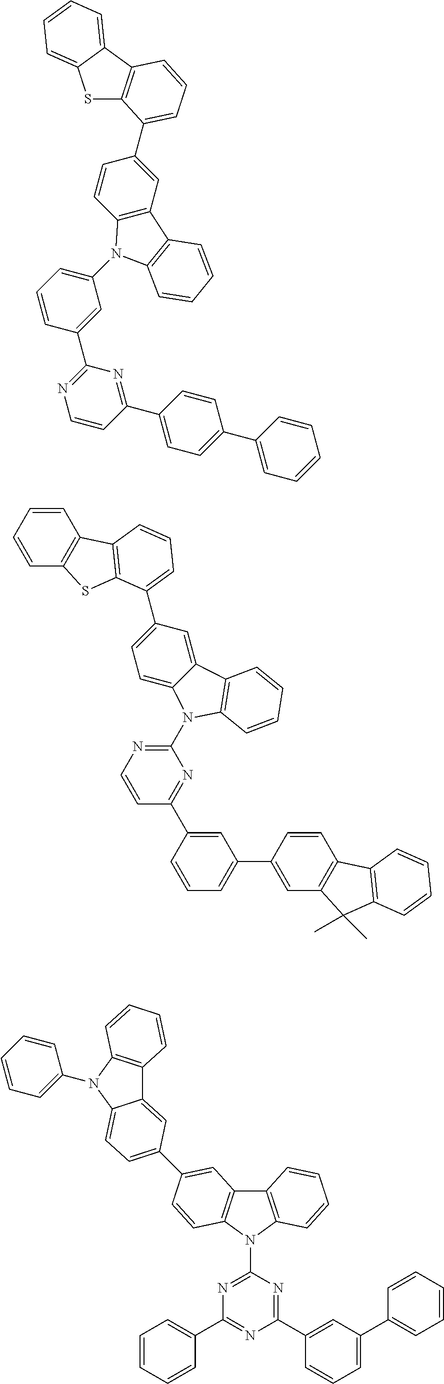 [SMILES: c1ccc(-c2ccc(-c3ccnc(-c4cccc(-n5c6ccccc6c6cc(-c7cccc8c7sc7ccccc78)ccc65)c4)n3)cc2)cc1 ; CC1(C)c2ccccc2-c2ccc(-c3cccc(-c4ccnc(-n5c6ccccc6c6cc(-c7cccc8c7sc7ccccc78)ccc65)n4)c3)cc21 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1]

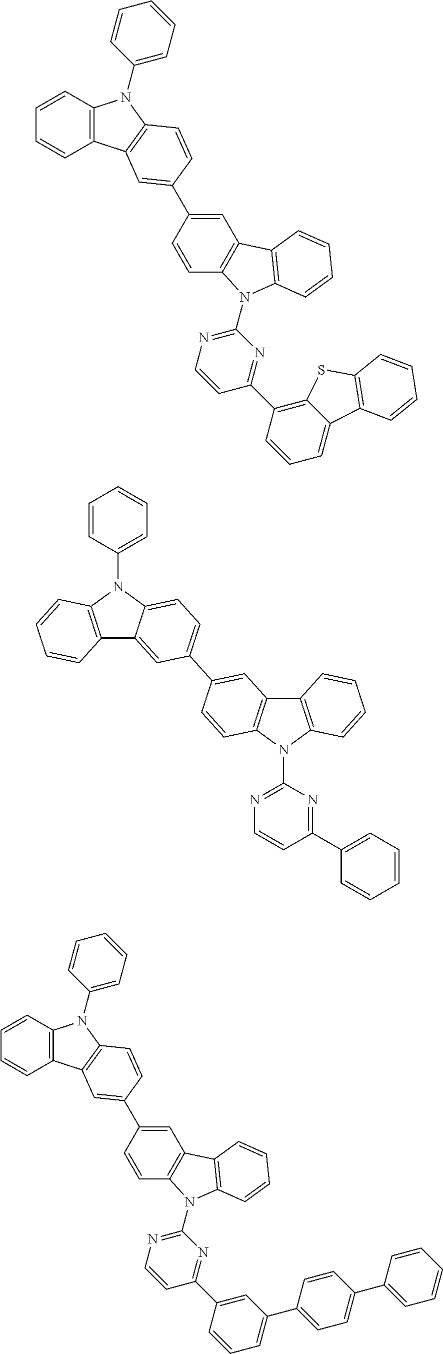 [SMILES: c1ccc(-n2c3ccccc3c3cc(-c4ccc5c(c4)c4ccccc4n5-c4nccc(-c5cccc6c5sc5ccccc56)n4)ccc32)cc1 ; c1ccc(-c2ccnc(-n3c4ccccc4c4cc(-c5ccc6c(c5)c5ccccc5n6-c5ccccc5)ccc43)n2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

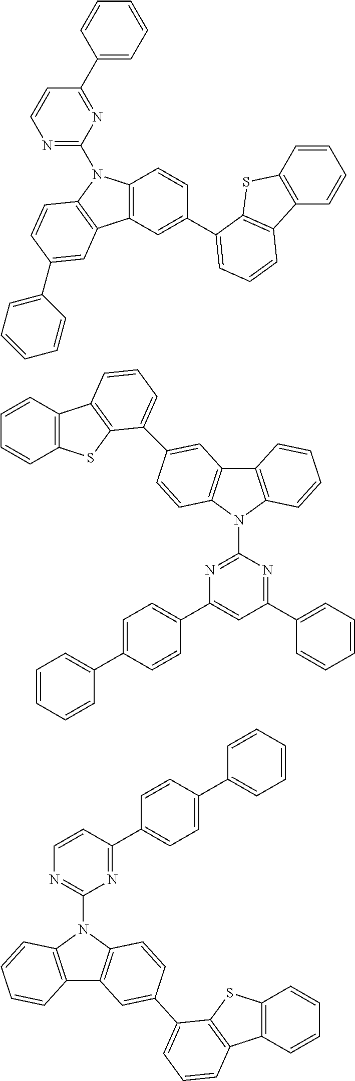

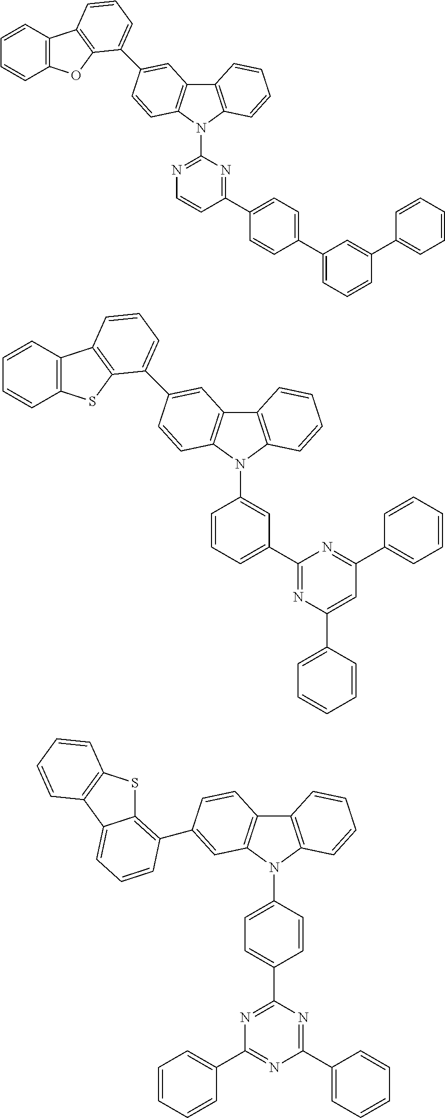 [SMILES: c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1]

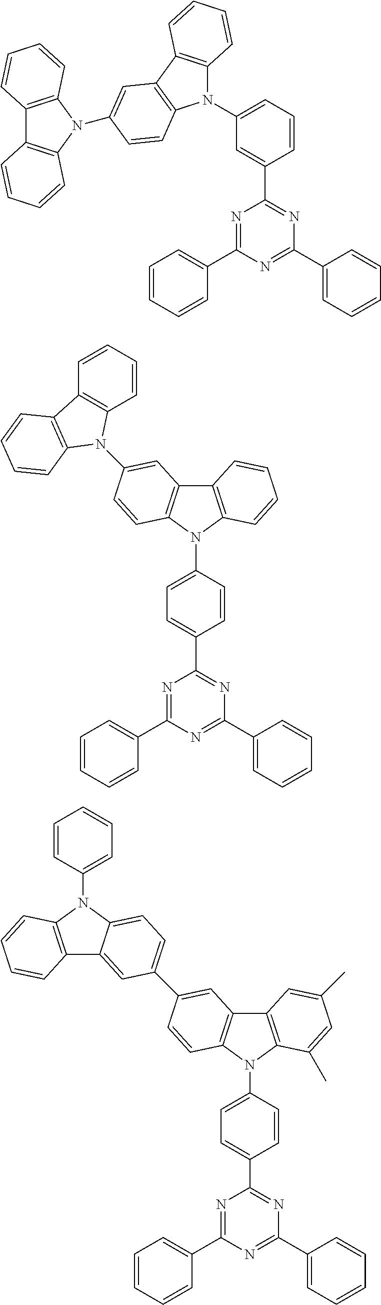

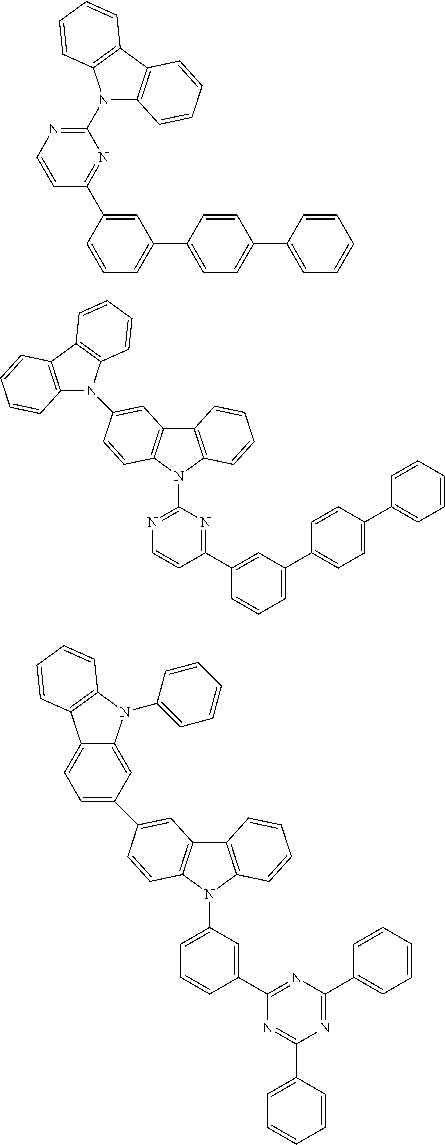

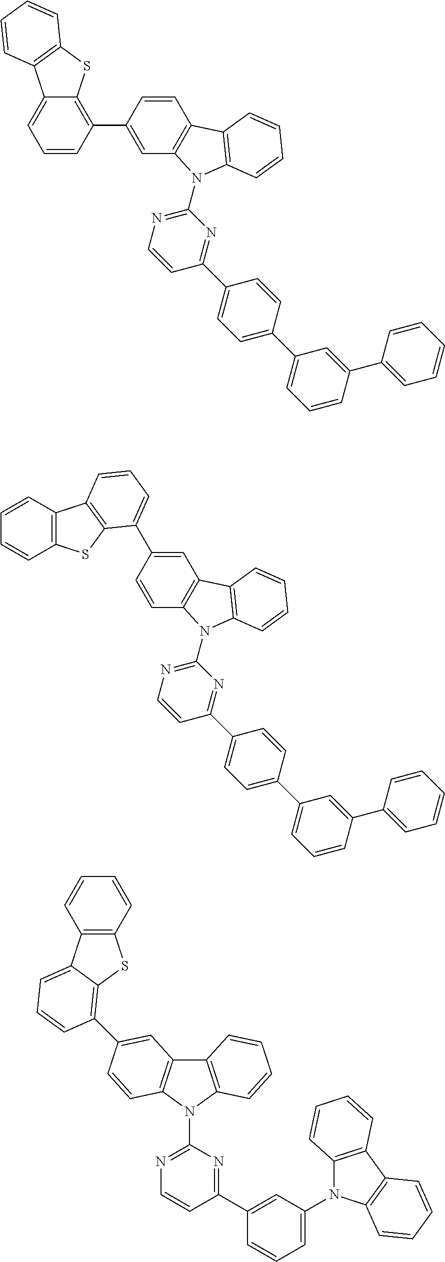 [SMILES: c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccc(-c4ccnc(-n5c6ccccc6c6cc(-c7cccc8c7sc7ccccc78)ccc65)n4)cc3)c2)cc1 ; c1cc(-c2ccnc(-n3c4ccccc4c4cc(-c5cccc6c5sc5ccccc56)ccc43)n2)cc(-n2c3ccccc3c3ccccc32)c1]

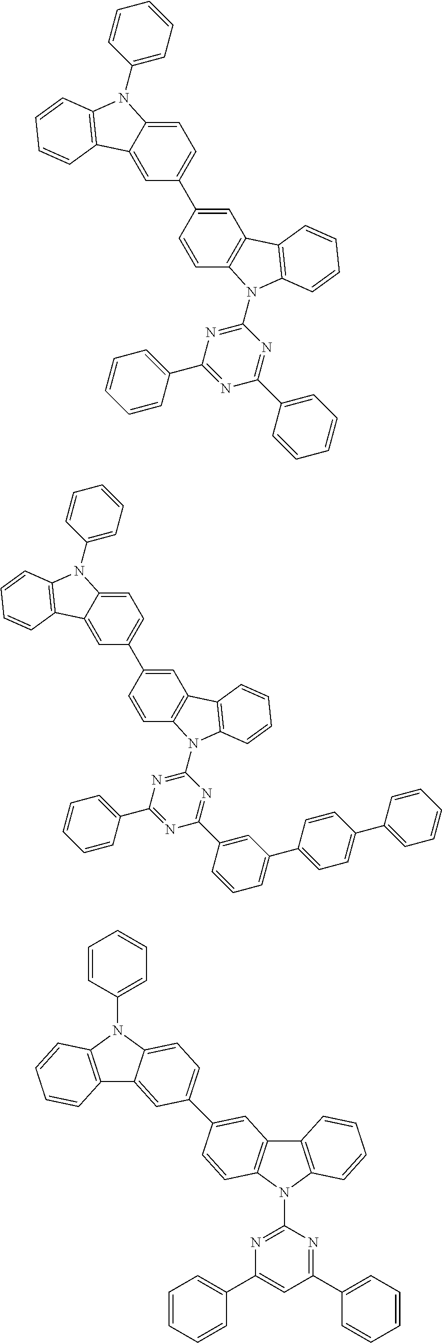 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1 ; c1ccc(-c2cc(-c3ccccc3)nc(-n3c4ccccc4c4cc(-c5ccc6c(c5)c5ccccc5n6-c5ccccc5)ccc43)n2)cc1]

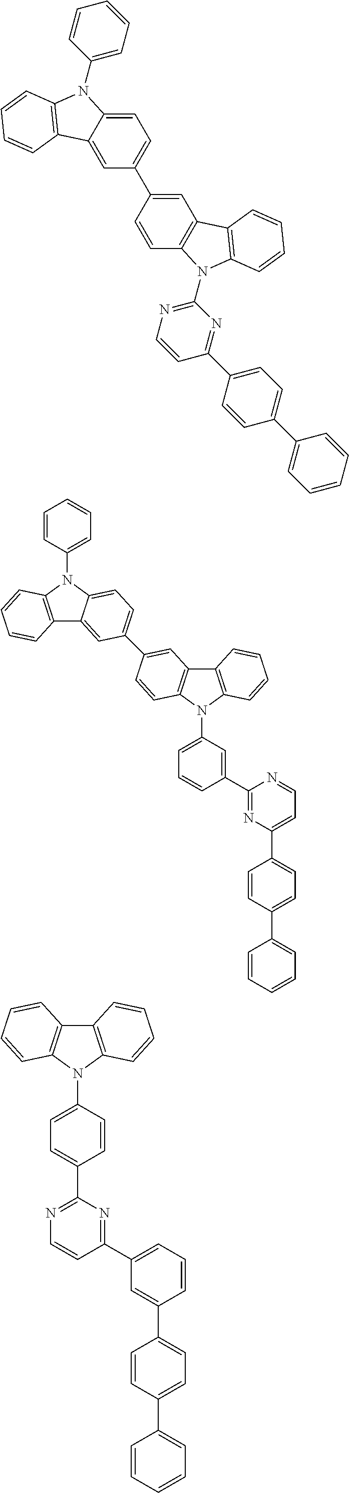 [SMILES: c1ccc(-c2ccc(-c3ccnc(-n4c5ccccc5c5cc(-c6ccc7c(c6)c6ccccc6n7-c6ccccc6)ccc54)n3)cc2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1 ; c1ccc(-c2ccc(-c3cccc(-c4ccnc(-c5ccc(-n6c7ccccc7c7ccccc76)cc5)n4)c3)cc2)cc1]

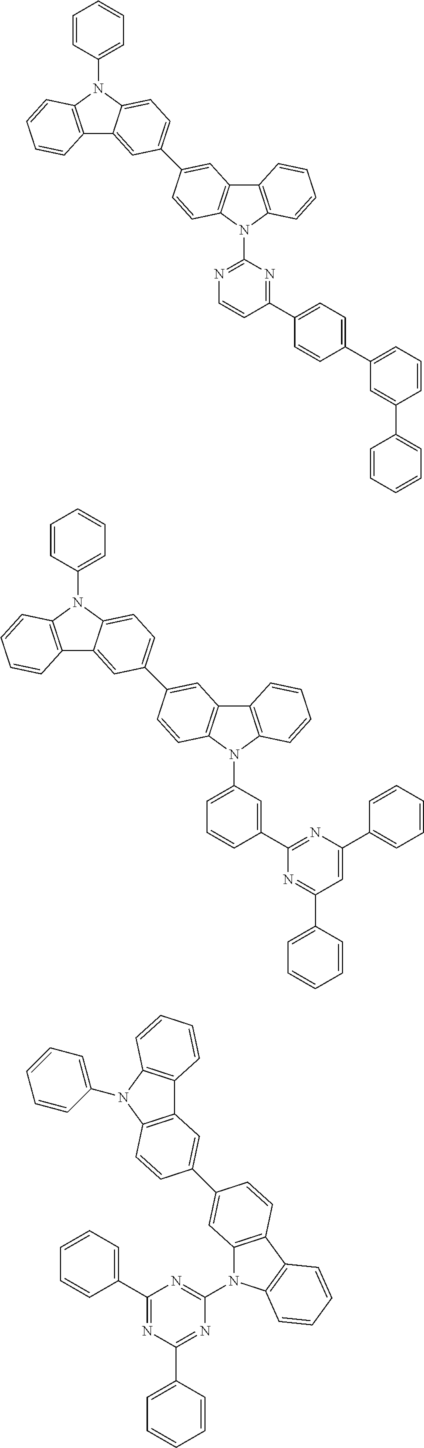 [SMILES: c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1 ; c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

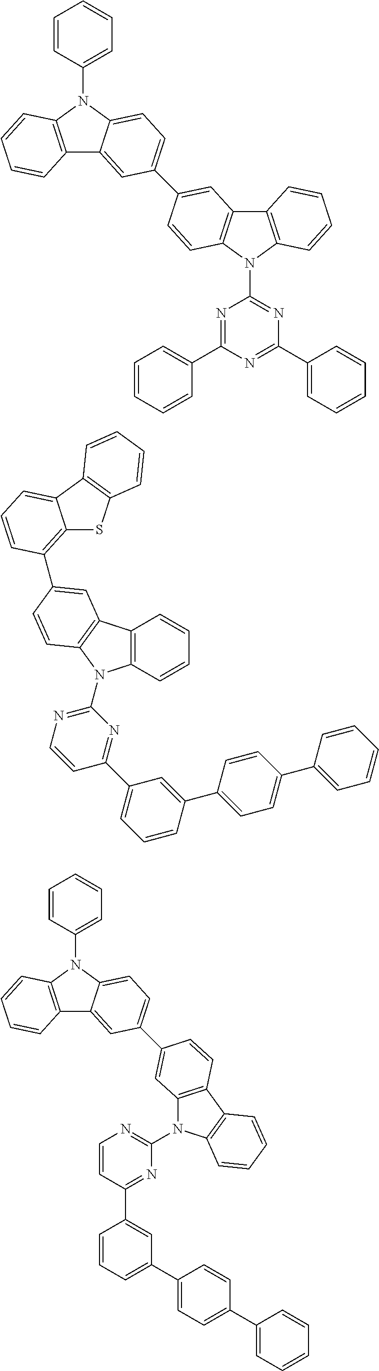

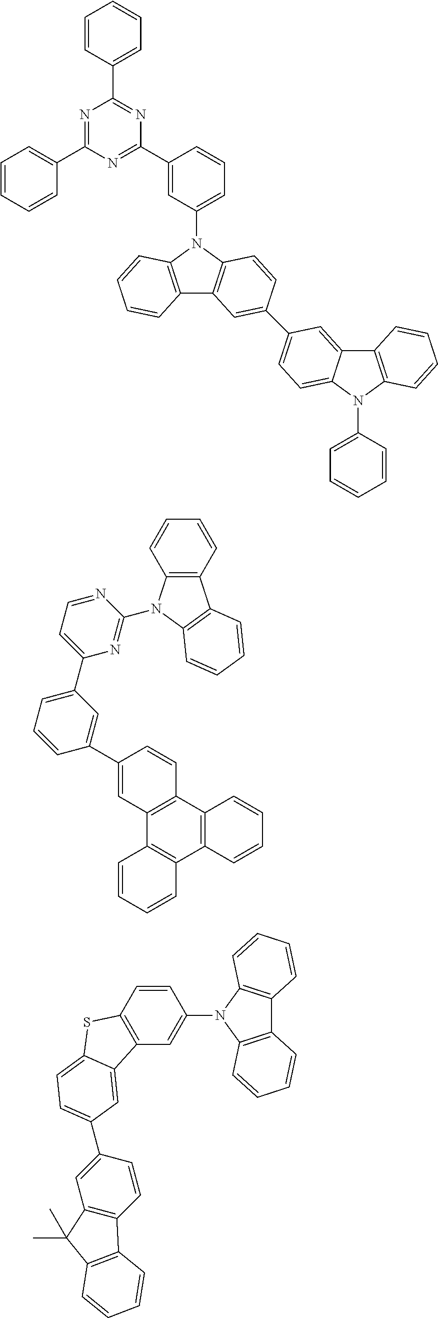 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21]

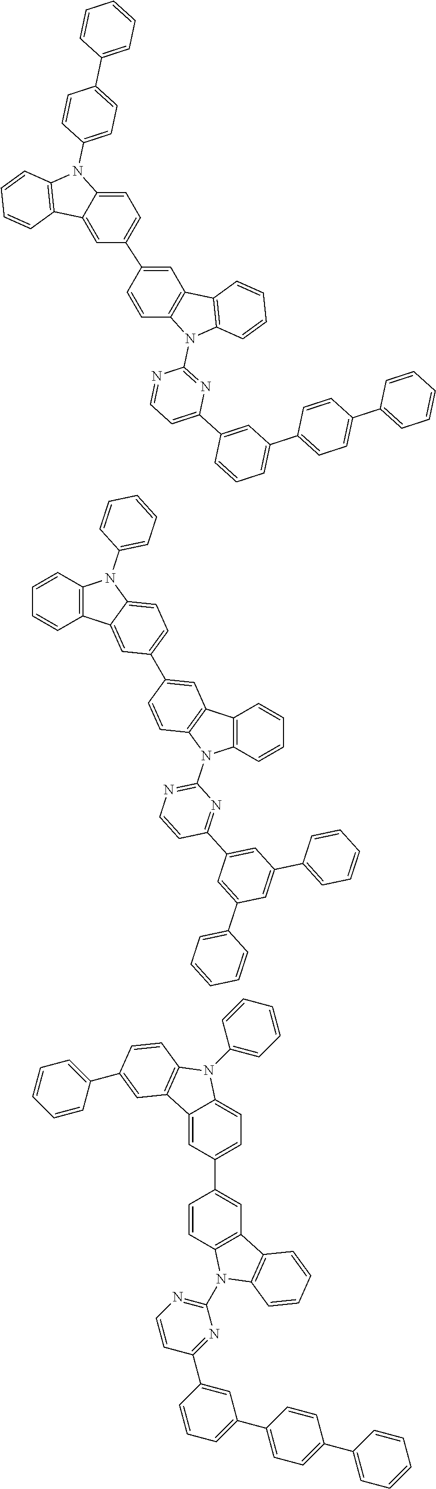

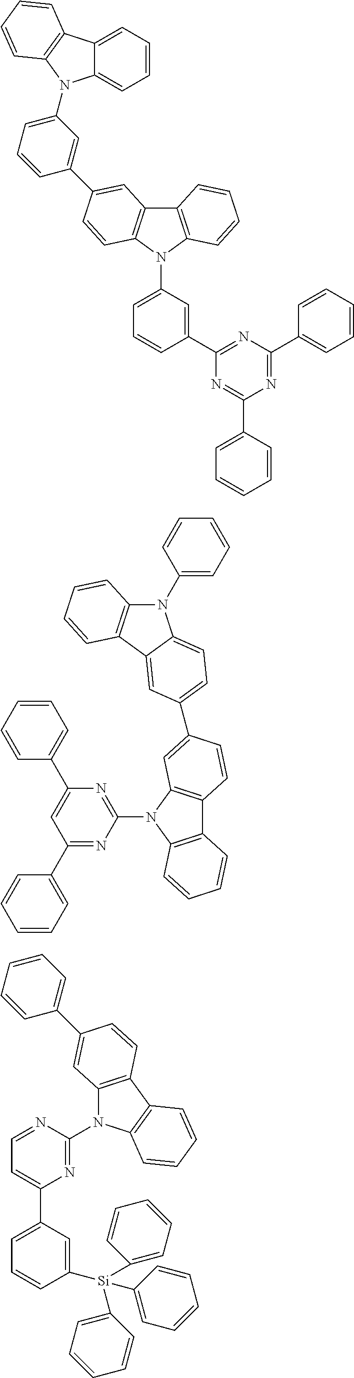

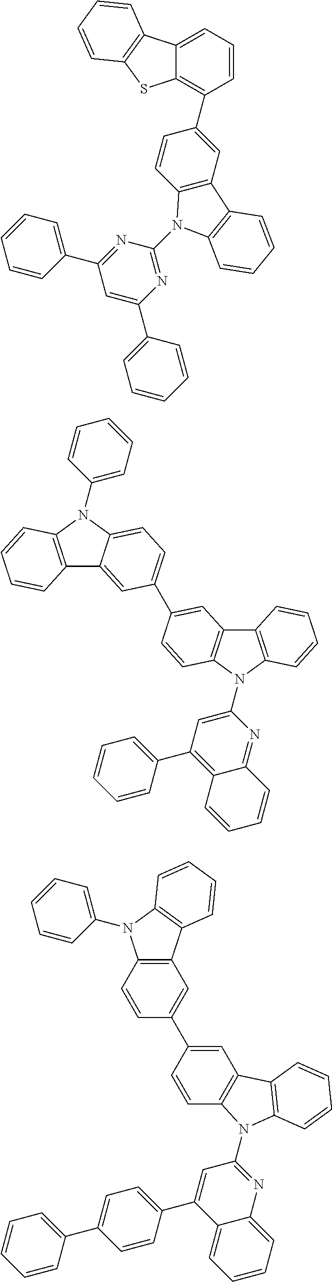

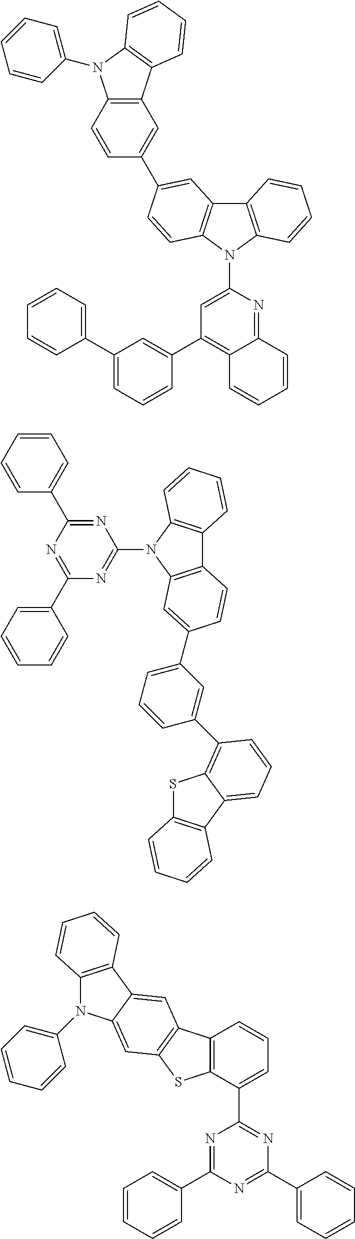 [SMILES: c1ccc(-c2cccc(-c3cc(-n4c5ccccc5c5cc(-c6ccc7c(c6)c6ccccc6n7-c6ccccc6)ccc54)nc4ccccc34)c2)cc1 ; c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3cccc4c3sc3cc5c(cc34)c3ccccc3n5-c3ccccc3)n2)cc1]

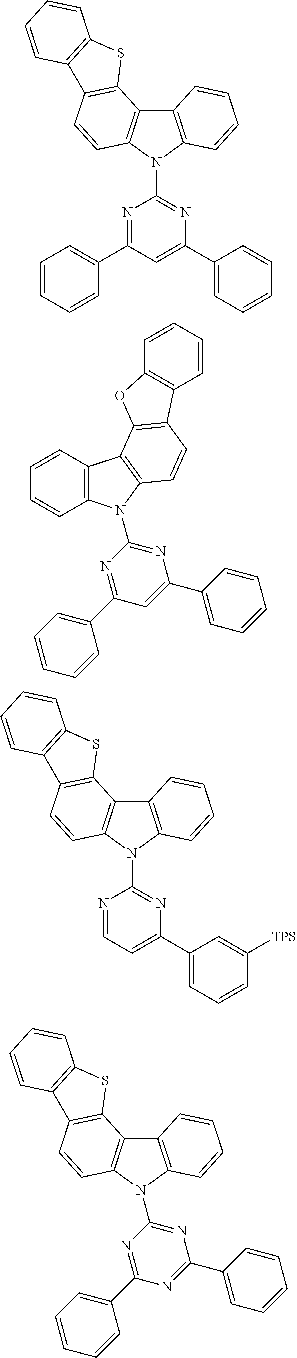

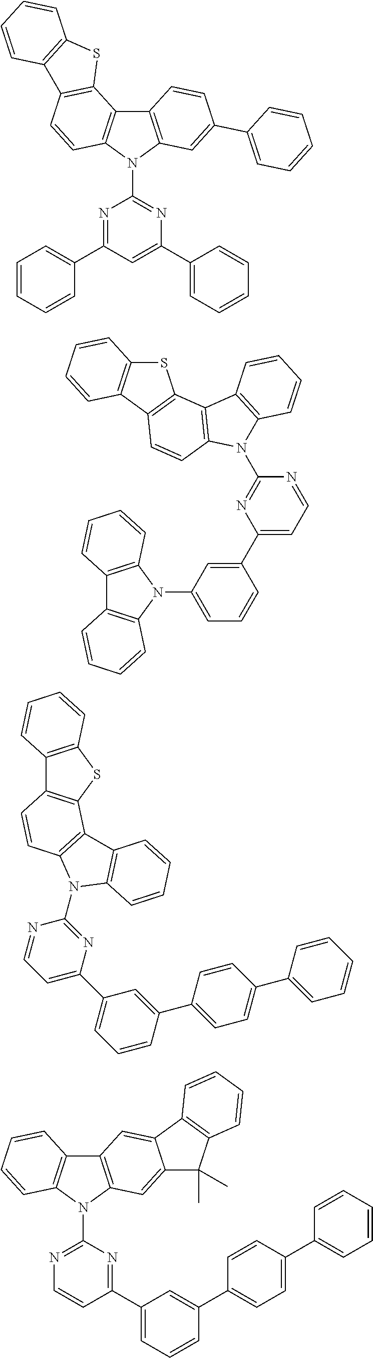

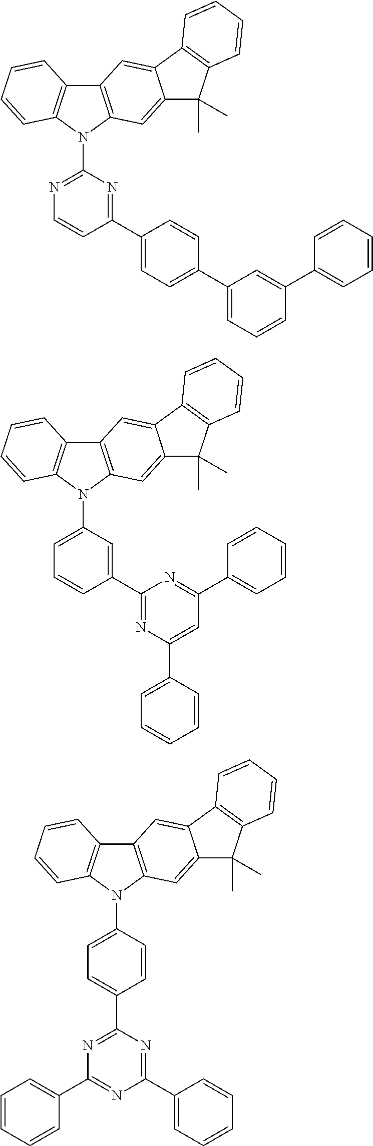

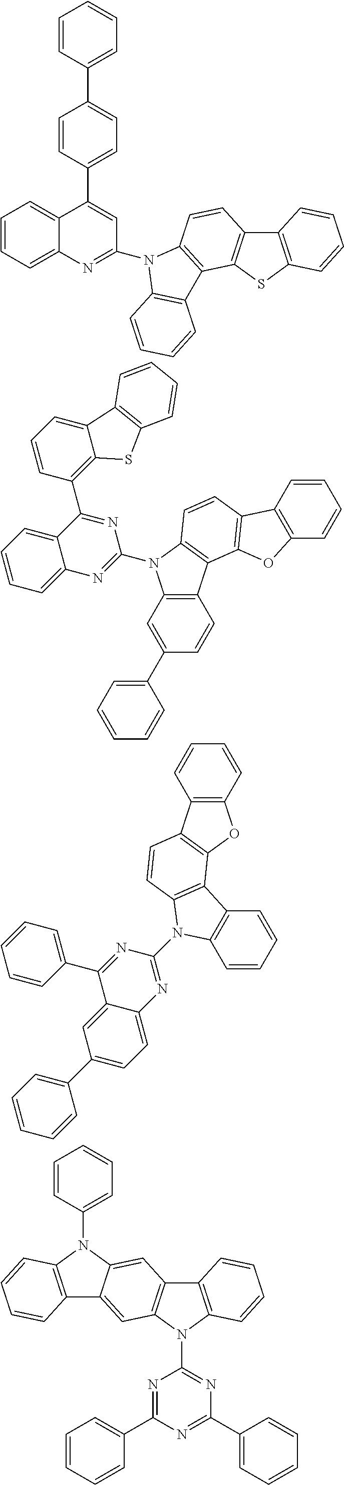

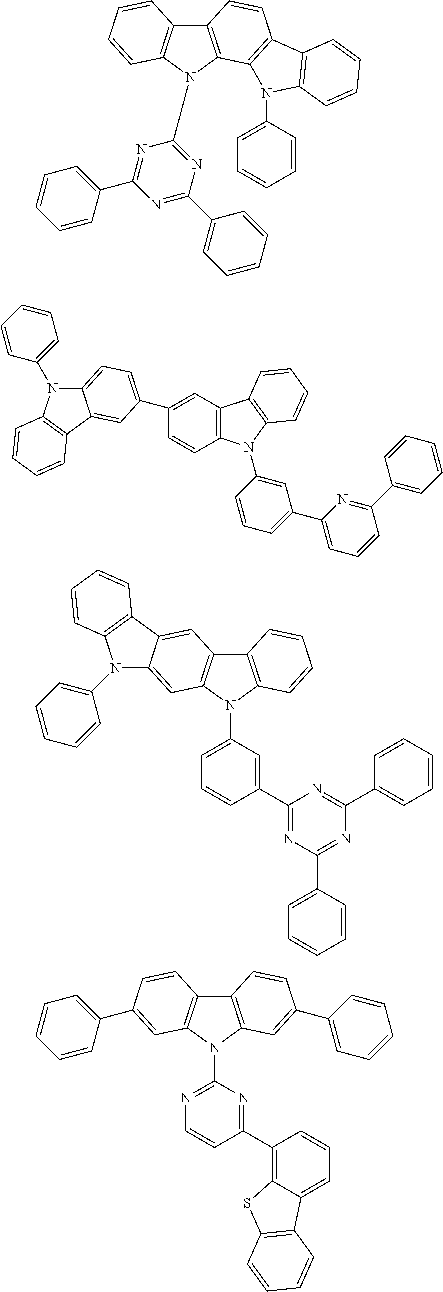

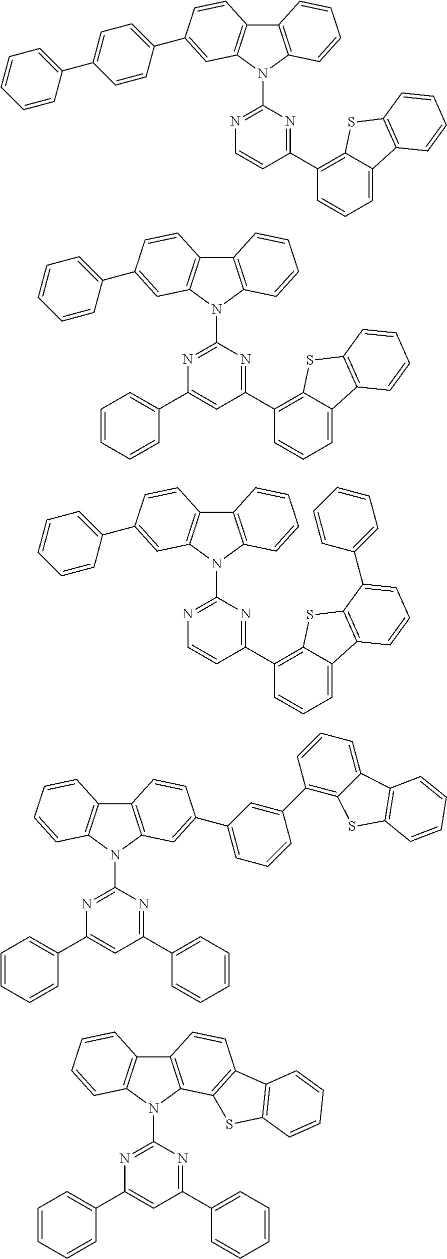

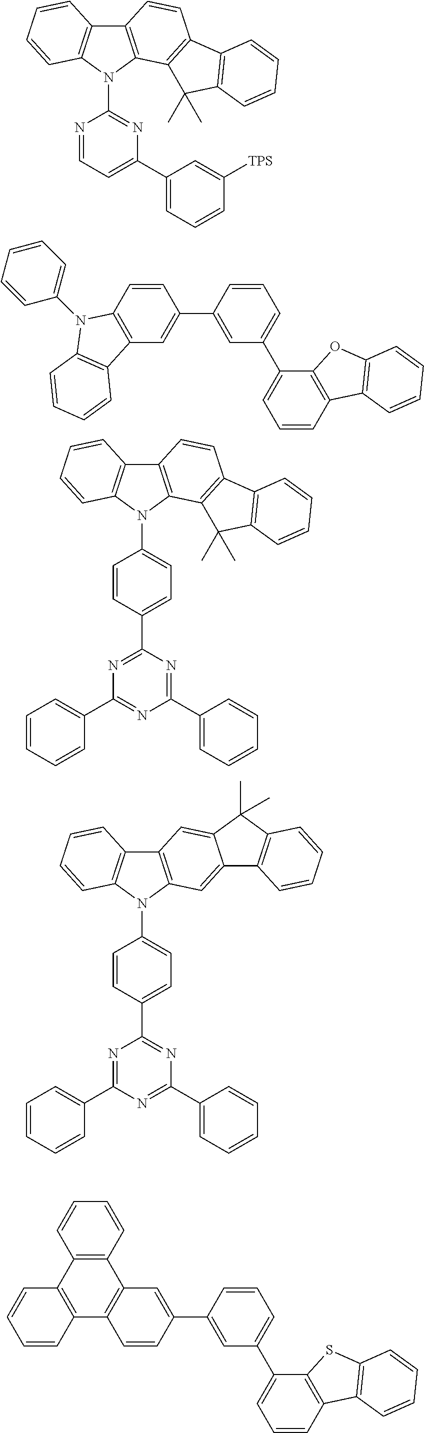

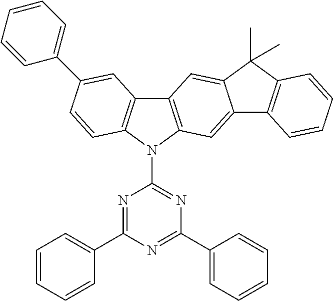 [SMILES: CC1(C)c2ccccc2-c2cc3c(cc21)c1cc(-c2ccccc2)ccc1n3-c1nc(-c2ccccc2)nc(-c2ccccc2)n1]

According to the present invention, the dopant used in the manufacture of the organic electroluminescent device is preferably one or more phosphorescent dopants. The phosphorescent dopant material applied to the electroluminescent device according to the present invention is not limited, but preferably may be selected from complex compounds of iridium, osmium, copper and platinum; more preferably ortho-metallated complex compounds of iridium, osmium, copper and platinum; and even more preferably ortho-metallated iridium complex compounds.

According to the present invention, the dopant comprised in the organic electroluminescent device may be selected from compounds represented by the following formulas 7 to 9.

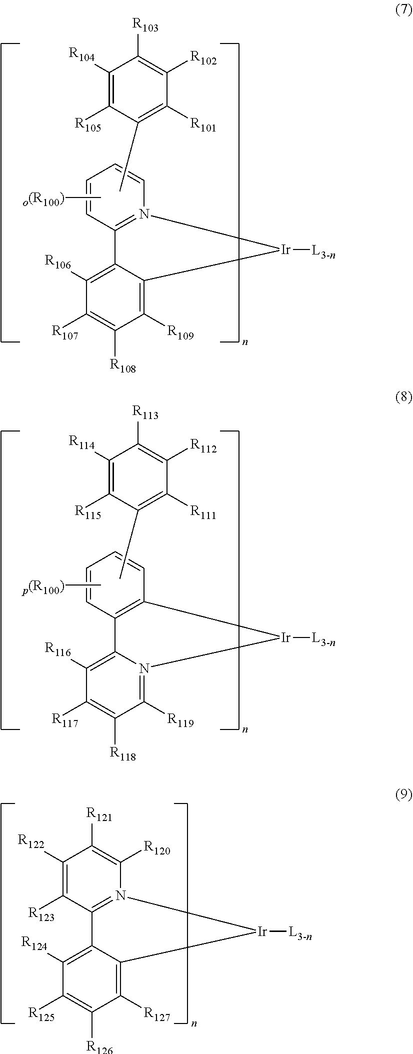

wherein L is selected from the following structures:

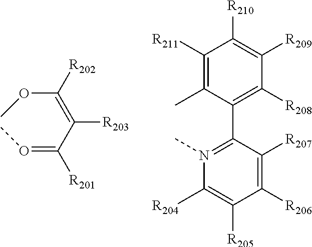

R₁₀₀ represents hydrogen, a substituted or unsubstituted (C1-C30)alkyl group, or a substituted or unsubstituted (C3-C30)cycloalkyl group; R₁₀₁ to R₁₀₉, and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; R₁₂₀ to R₁₂₃ are linked to an adjacent substituent to form a fused ring, e.g. quinoline; R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene; R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group; o and p each independently represent an integer of 1 to 3; where o or p is an integer of 2 or more, each of R₁₀₀ is the same or different; and n is an integer of 1 to 3.

The phosphorescent dopant materials include the following:

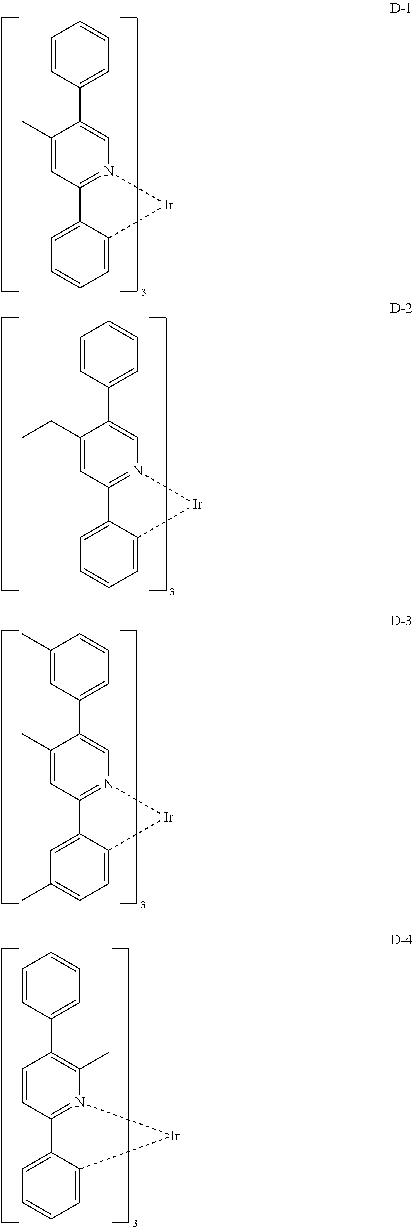

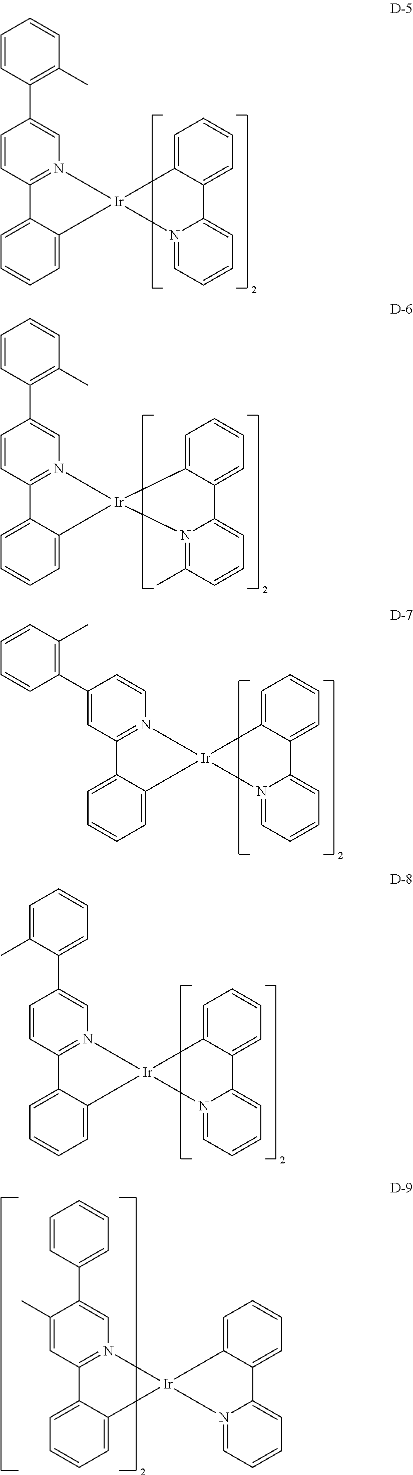

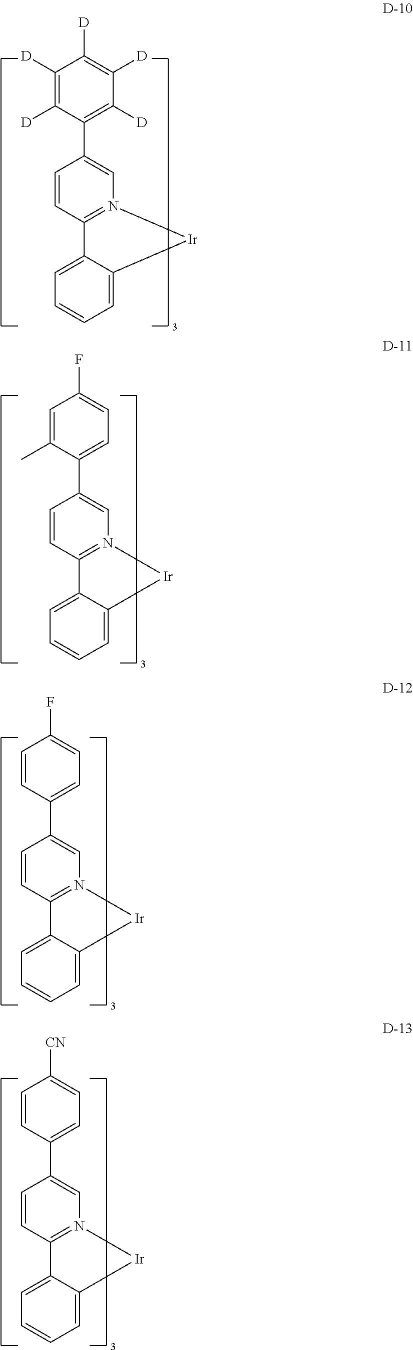

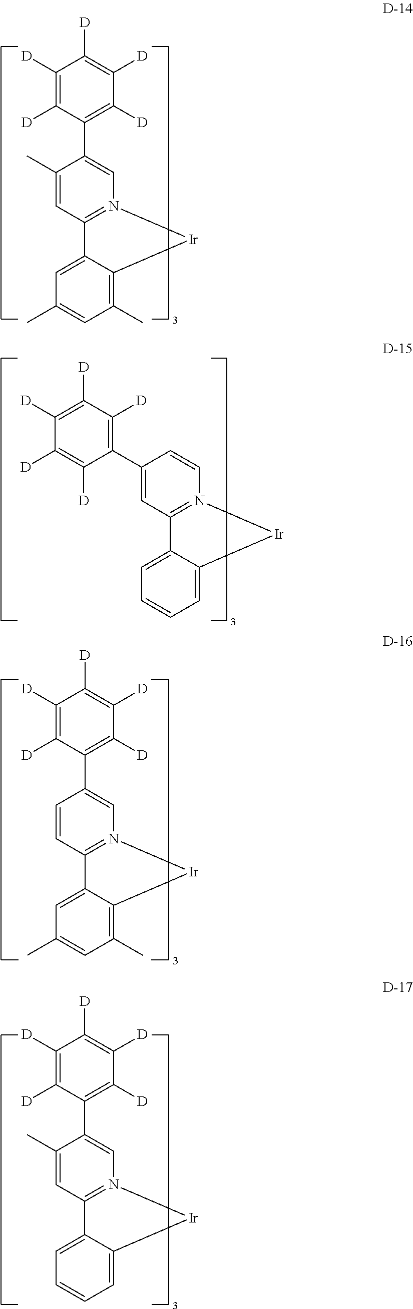

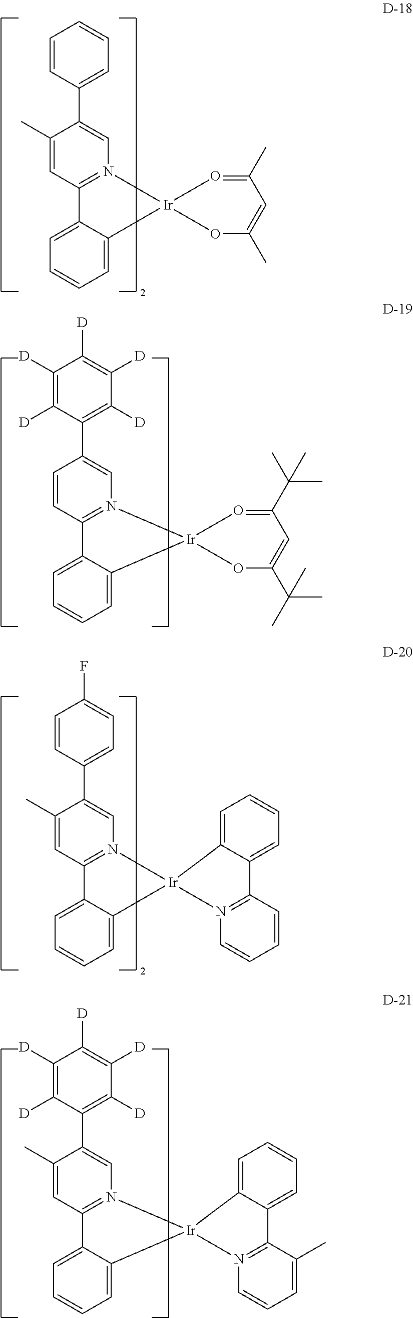

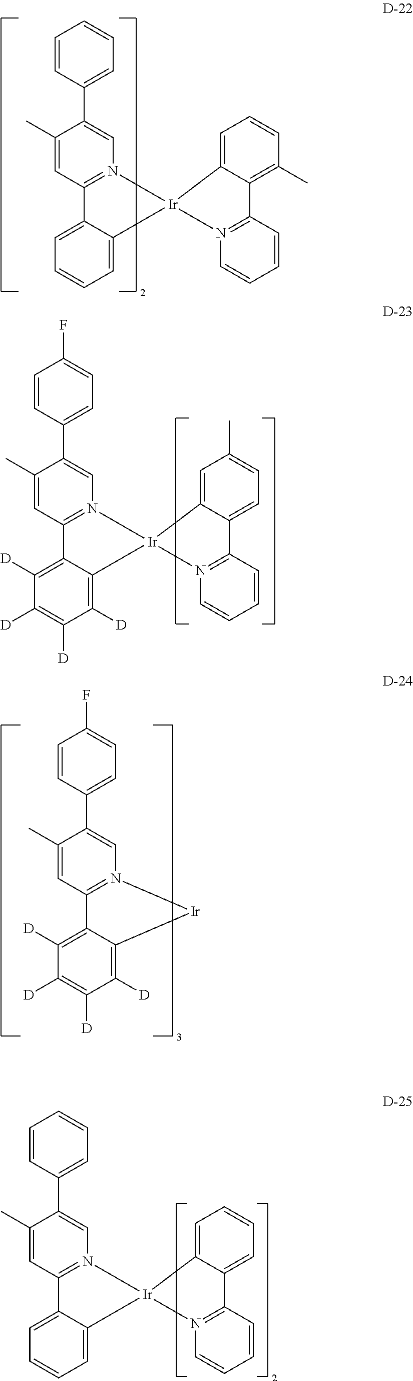

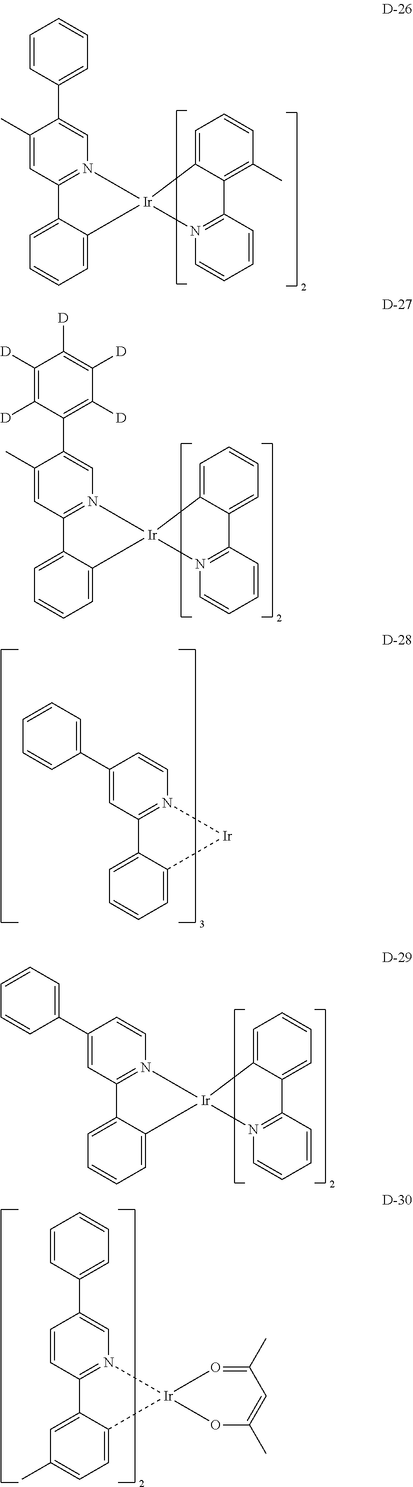

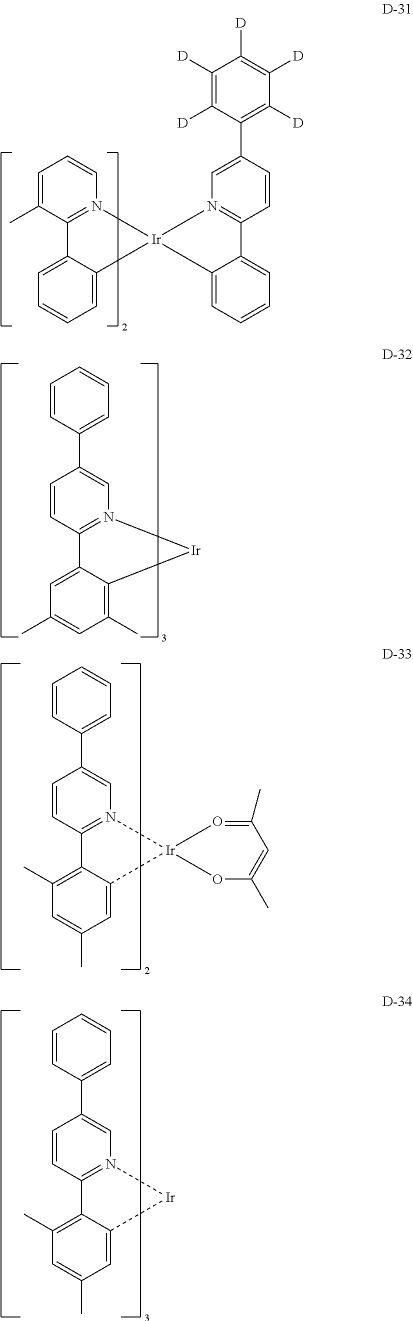

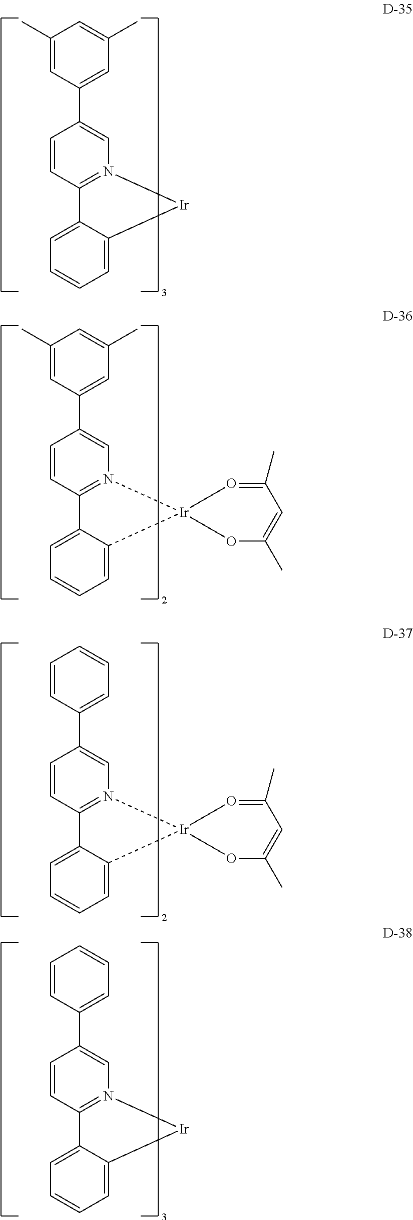

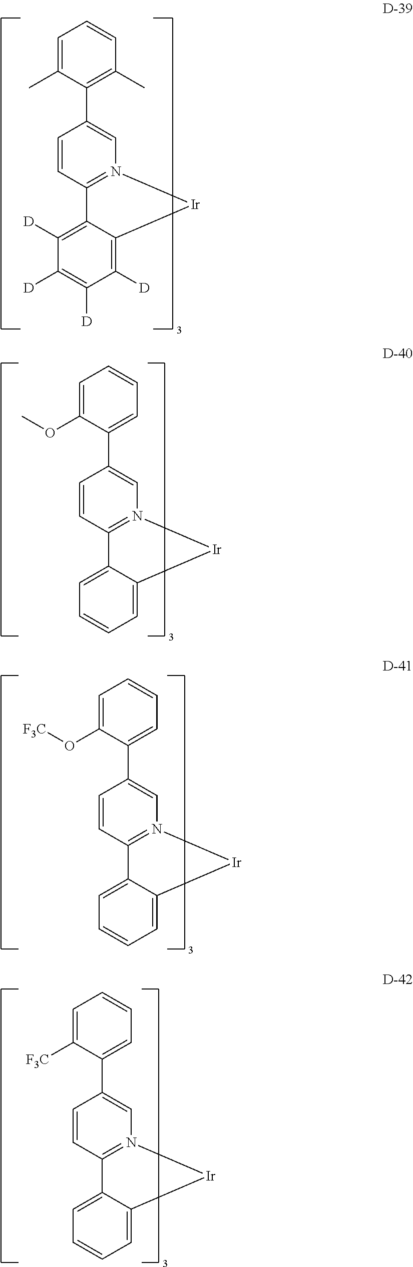

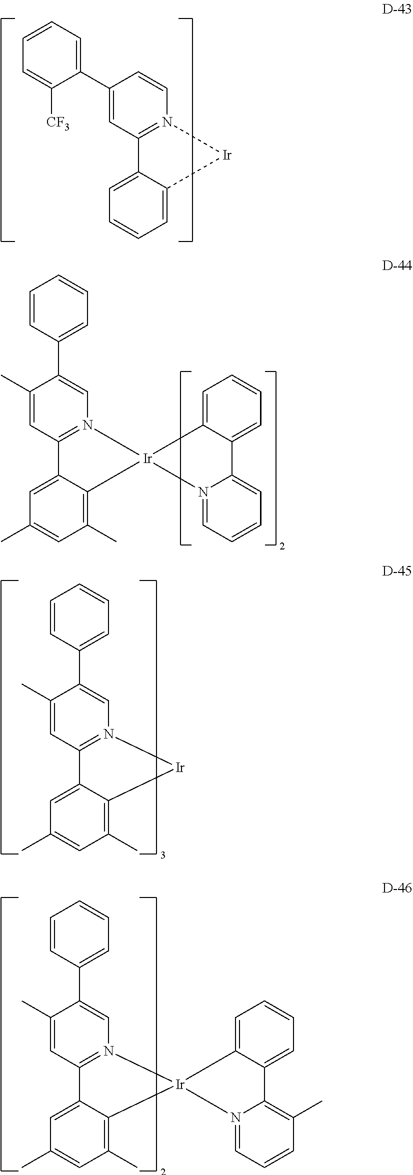

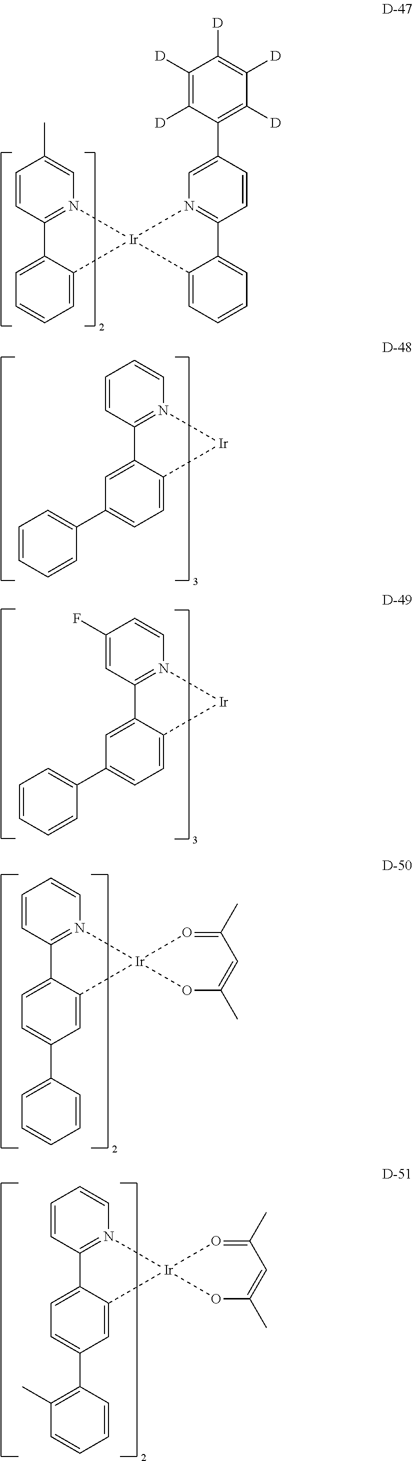

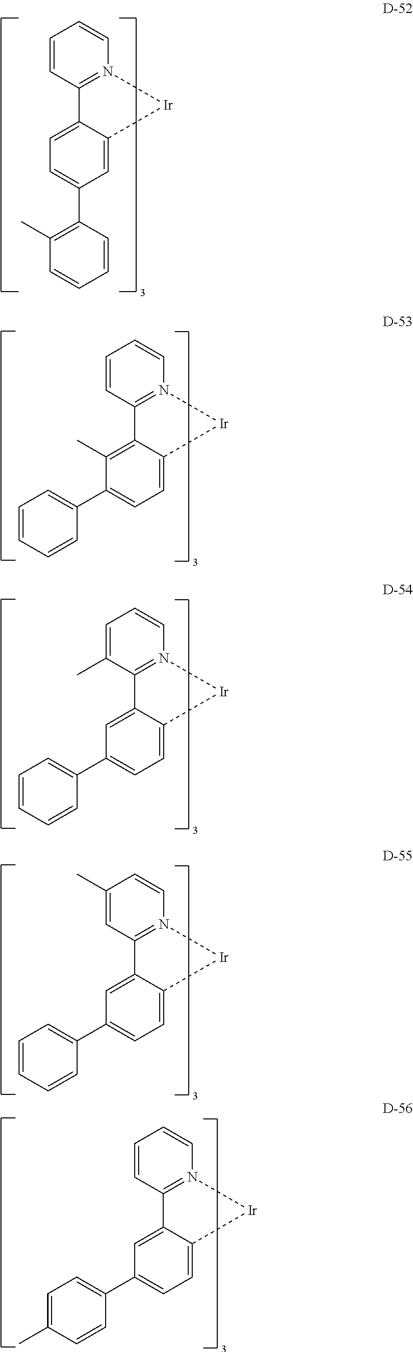

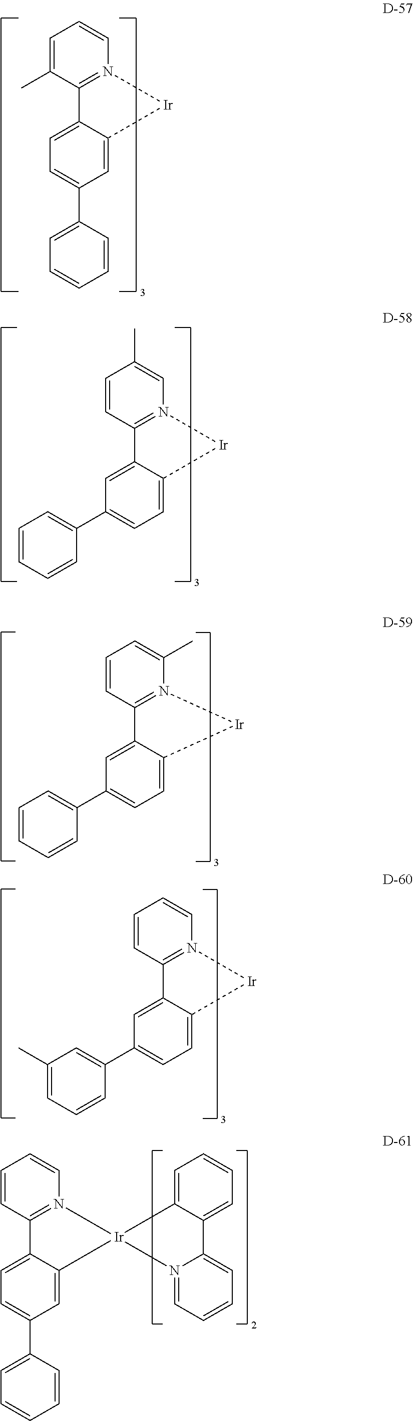

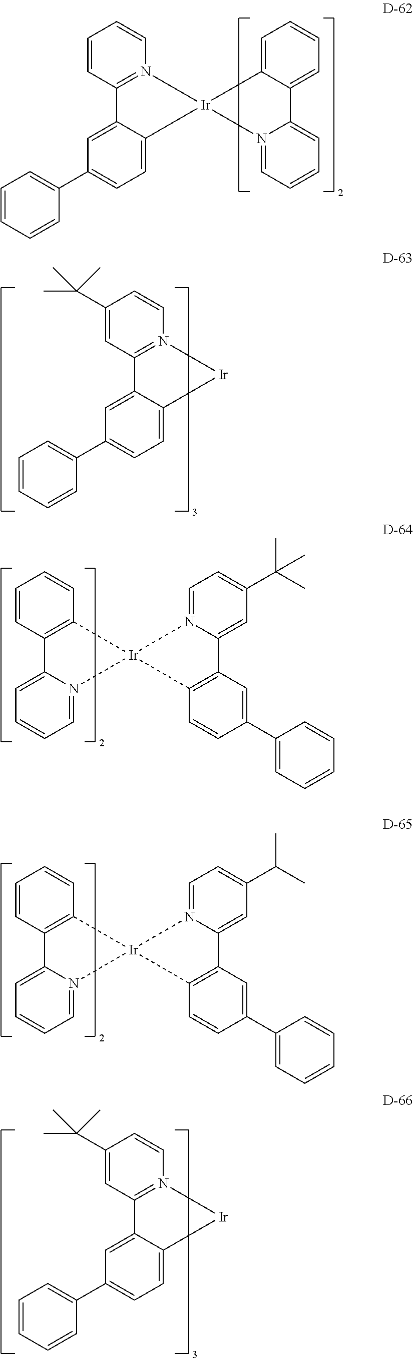

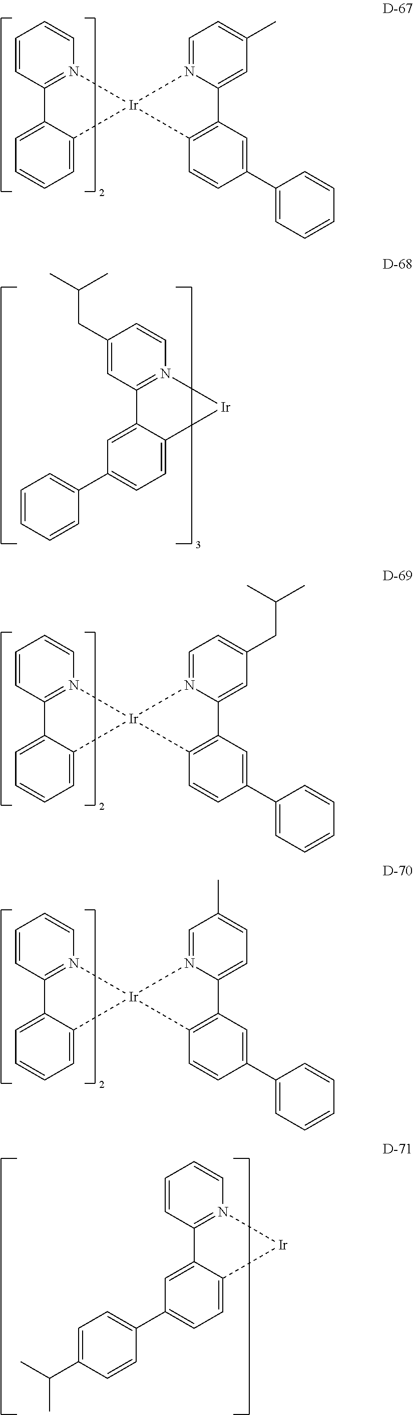

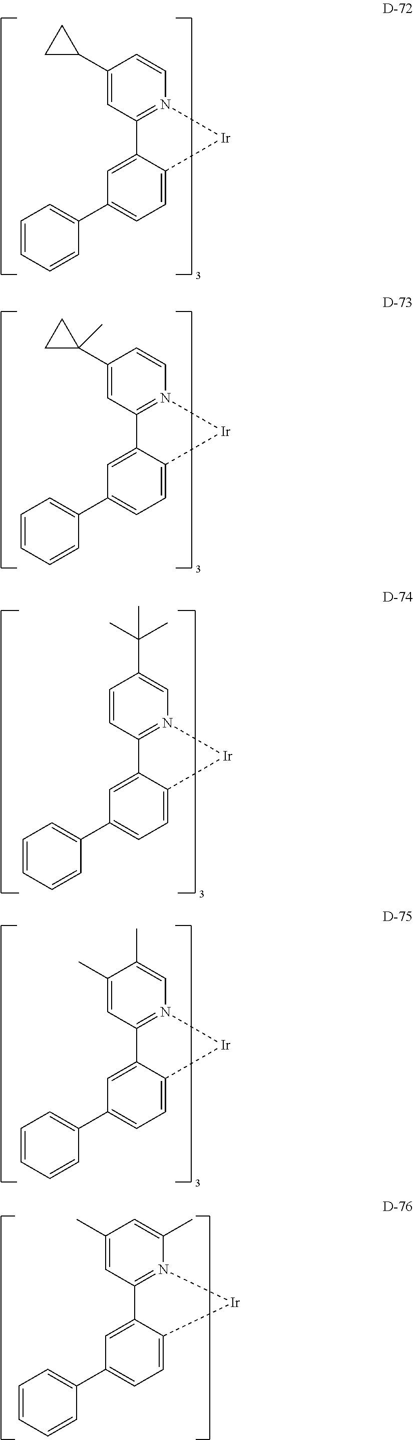

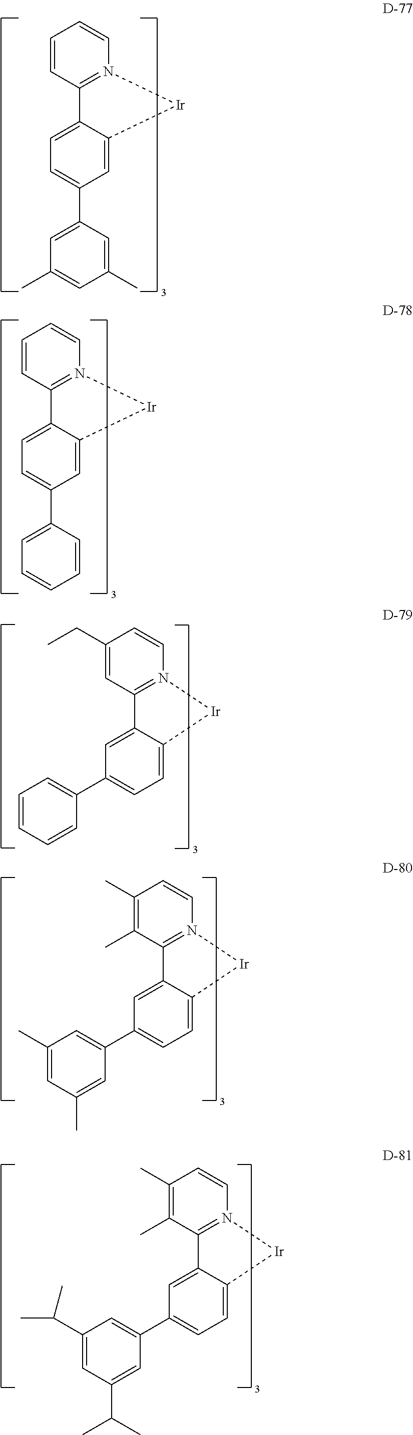

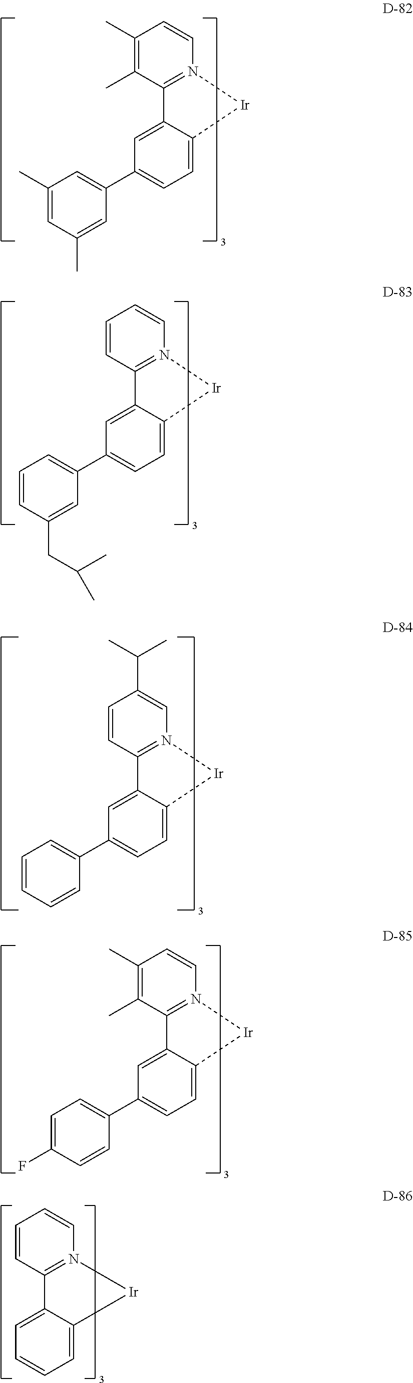

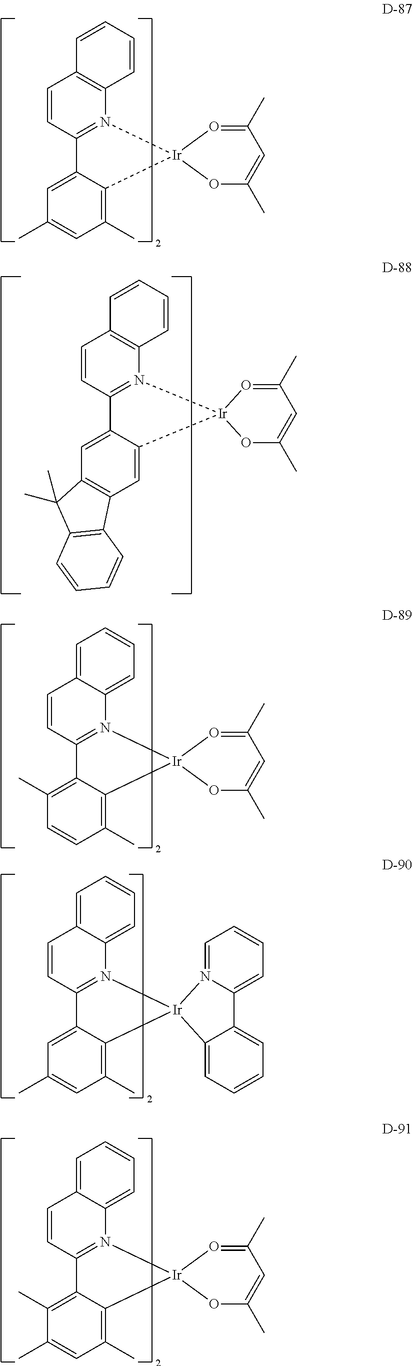

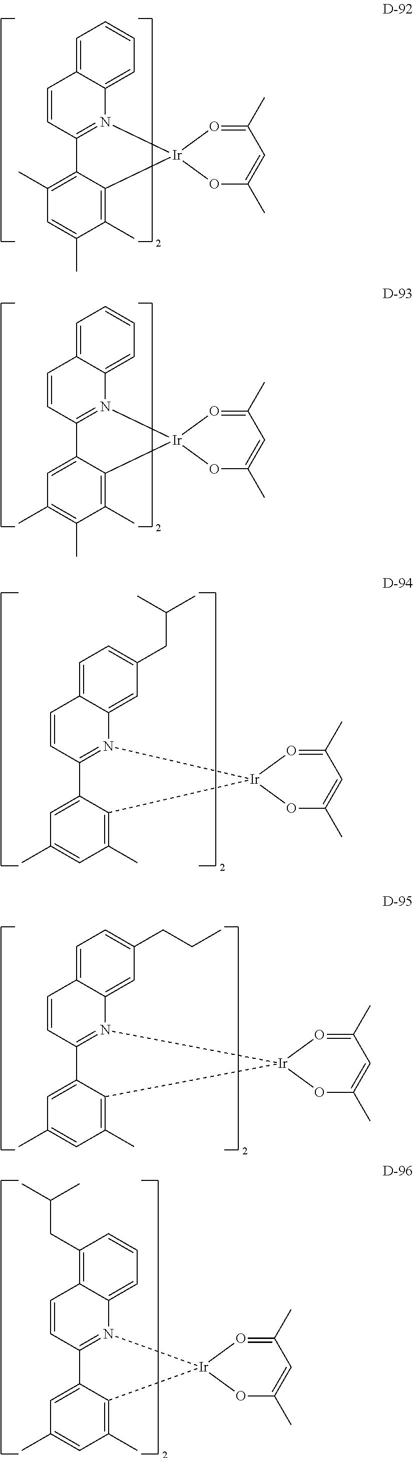

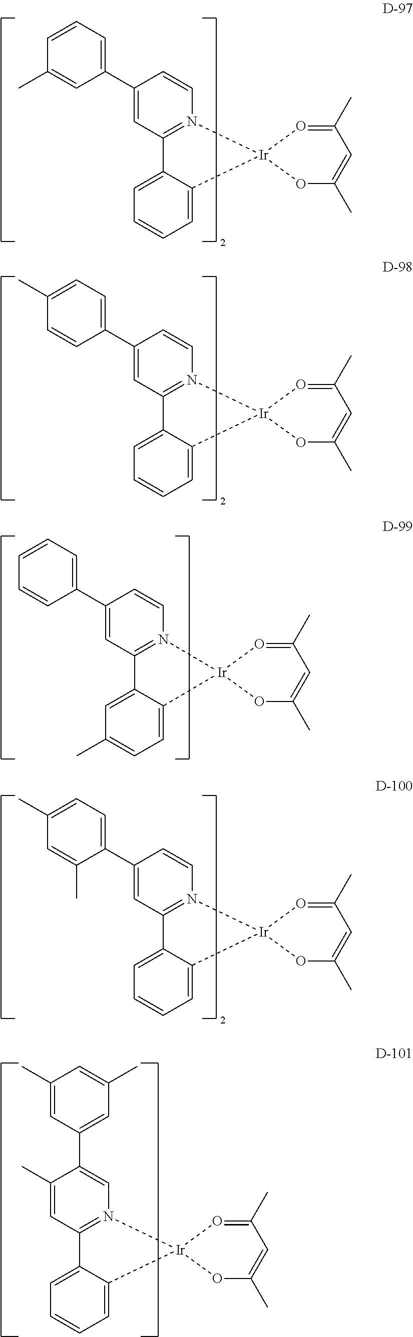

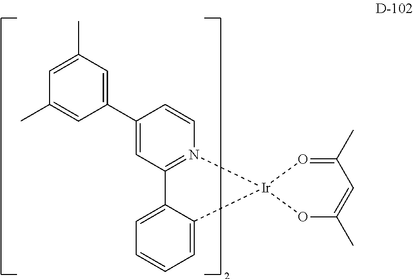

The organic layer of the organic electroluminescent device according to the present invention may further comprise, in addition to the organic electroluminescent compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may comprise a light-emitting layer and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. Also, if needed, a yellow or orange light-emitting layer can be comprised in the device.

According to the present invention, at least one layer (hereinafter, “a surface layer”) of the organic electroluminescent device preferably selected from a chalcogenide layer, a metal halide layer and a metal oxide layer; may be placed on an inner surface(s) of one or both electrode(s). Specifically, a chalcogenide (includes oxides) layer of silicon or aluminum is preferably placed on an anode surface of an electroluminescent medium layer, and a metal halide layer or a metal oxide layer is placed on a cathode surface of an electroluminescent medium layer. Such a surface layer provides operation stability for the organic electroluminescent device. Preferably, said chalcogenide includes SiOₓ (1≦X≦2), AlOₓ (1≦X≦0.5), SiON, SiAlON, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

As for the formation of the layers of the organic electroluminescent device according to the present invention, dry film-forming methods such as vacuum evaporation, sputtering, plasma and ion plating methods, or wet film-forming methods such as spin coating, dipping, flow coating methods can be used.

When applying a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused.

Hereinafter, the organic electroluminescent compound, the preparation method of the compound, and the luminescent properties of the device comprising the compound of the present invention will be explained in detail with reference to the following examples:

### Example 1

### Preparation of Compound C-16

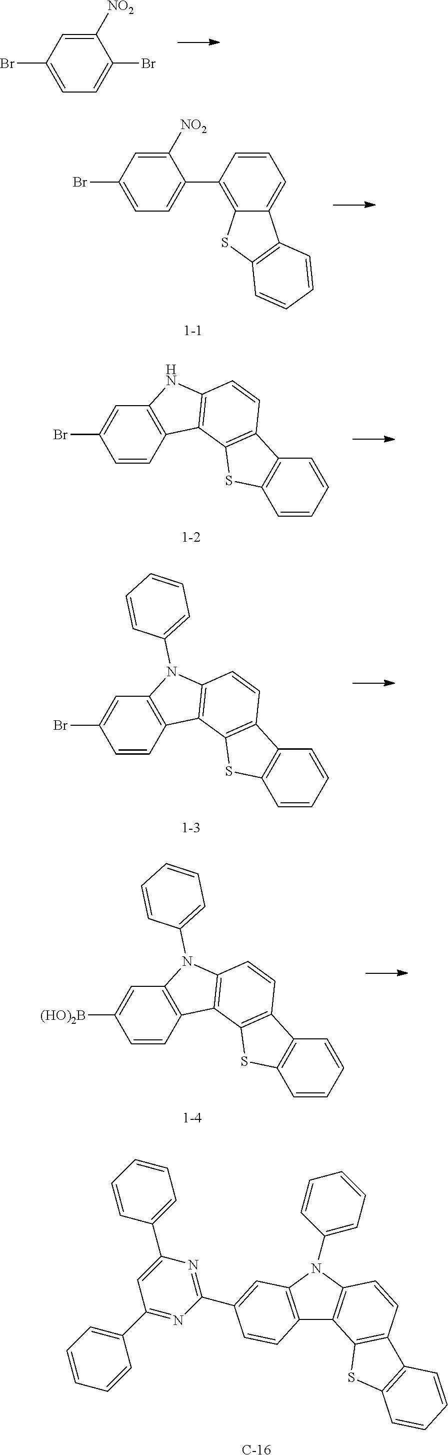

Preparation of Compound 1-1

After putting 2,5-dibromonitrobenzene (30 g, 106.8 mmol), dibenzothiophen-4-yl boronic acid (20.3 g, 88.9 mmol), Pd(PPh₃)₄ (5.1 g, 4.45 mmol) and Na₂CO₃ (27.9 g, 267 mmol) in a flask, a mixture of toluene 600 mL and ethanol 100 mL was added for dissolution. Then, the mixture was stirred for 3 hours at 90° C. After completing the reaction, distilled water was added, and then the organic layer was extracted with ethyl acetate (EA). Then, the organic layer was dried with MgSO₄ to remove the remaining moisture, and then was separated through a column to obtain compound 1-1 (24 g, 62 mmol, 59%).

Preparation of Compound 1-2

After putting compound 1-1 (40 g, 39.3 mmol) in a flask, triethylphosphite 150 mL was added, and the mixture was stirred for 24 hours at 150° C. After completing the reaction, the solvent was distillated under reduced pressure, and then the remaining product was separated through a column to obtain compound 1-2 (15 g, 42.58 mmol, 40.94%).

Preparation of Compound 1-3

After mixing compound 1-2 (15 g, 42.58 mmol), iodobenzene (9.5 mL, 85.16 mmol), CuI (6.4 mL, 34.06 mmol), ethylene diamine (4.3 mL, 63.87 mmol), K₃PO₄ (27.1 g, 127.75 mmol) and toluene, the mixture was stirred under reflux. After 6 hours, the mixture was cooled to room temperature, and then filtered under reduced pressure to remove CuI and K₃PO₄. The remaining solution was washed with distilled water, and then extracted with EA. The remaining product was dried with MgSO₄ to remove the remaining moisture, then distillated under reduced pressure, and then separated through a column to obtain compound 1-3 (13 g, 30.34 mmol, 71.25%).

Preparation of Compound 1-4

After dissolving compound 1-3 (13 g, 30.34 mmol) in tetrahydrofuran (THF) 250 mL, n-buLi (14.56 mL, 36.41 mmol, 2.5 M in hexane) was added to the mixture at −78° C. After 1 hour, triisopropylborate (10.5 mL, 45.52 mmol) was added. After stirring the mixture for 12 hours, distilled water was added, and then the mixture was extracted with EA. The remaining product was dried with MgSO₄ to remove the remaining moisture, and then recrystallized with EA and hexane to obtain compound 1-4 (9 g, 22.88 mmol, 75.42%).

Preparation of Compound C-16

After mixing compound 1-4 (7.8 g, 22.49 mmol), 4,6-diphenyl-2-chloropyrimidine (5 g, 18.74 mmol), X-phos(2-dicyclohexylphosphino-2′,4′,6′-triisopropyl biphenyl) (0.8 g, 1.68 mmol), 2 M Na₂CO₃ 28 mL, toluene 200 mL and THF 200 mL, the mixture was stirred for 12 hours at 100° C. Then, methanol was added, and lien the obtained solid was filtered under reduced pressure. The remaining product was recrystallized with EA and methylene chloride (MC) to obtain compound C-16 (2.1 g, 3.62 mmol, 19.33%).

MS/EIMS found 579.7; calculated 579.18

### Example 2

### Preparation of Compound C-32

A compound was synthesized in the same manner as in Example 1, except for using 3-bromo-5H-benzofuro[3,2-c]carbazole in place of compound 1-2 to obtain compound C-32 (9 g, 57%).

MS/EIMS found 563.6; calculated 563.2

### Example 3

### Preparation of Compound C-57

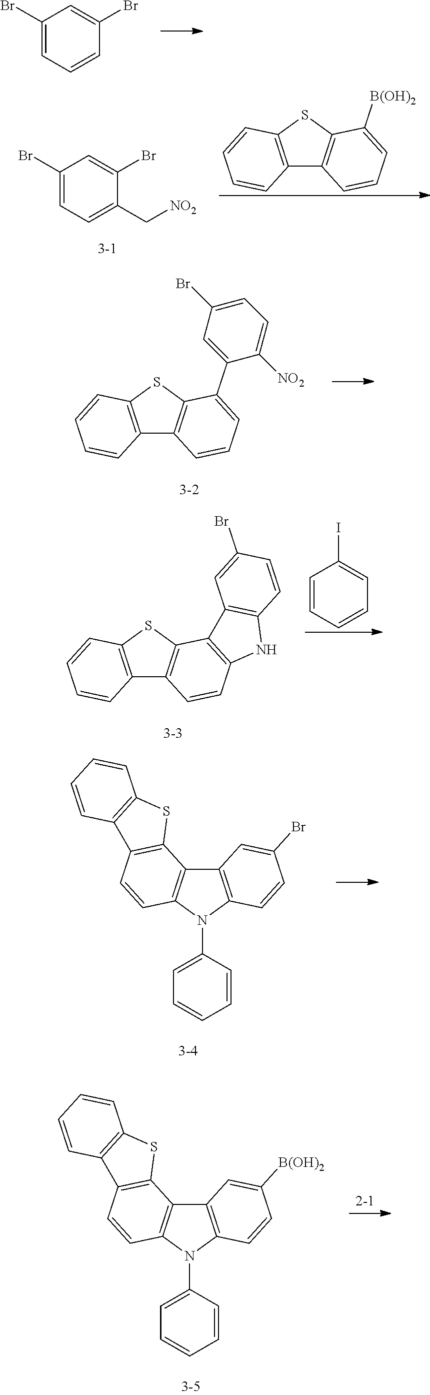

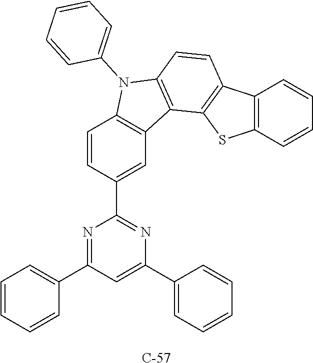

Preparation of Compound 3-1

After putting HNO₃ (95 mL, 1.5 mol) and H₂SO₄ (167 mL, 1.7 M) in a 1000 mL round bottom flask, the mixture was cooled to 0° C. After adding 1,3-dibromobenzene (50 g, 0.18 mol) slowly, the mixture was stirred for 1 hour. After completing the reaction, the mixture was slowly added to iced water of 0° C. Then, the mixture was filtered, and then separated through a column to obtain a yellow solid: compound 3-1 (75 g, 63%).

Preparation of Compound 3-2

After putting compound 3-1 (50 g, 0.18 mol), dibenzo[b,d]thiophen-4-yl boronic acid (34 g, 0.15 mol), Pd(PPh₃)₄ (6.9 g, 0.006 mol), K₂CO₃ (47 g, 0.4 mol), toluene 1800 mL, ethanol 150 mL and distilled water 220 mL in a 3000 mL round bottom flask, the mixture was stirred for 12 hours at 60° C. After completing the reaction, the mixture was extracted with EA. The remaining organic layer was dried with MgSO₄, then filtered, then distillated under reduced pressure, and then separated through a column to obtain compound 3-2 (30 g, 53%).

Preparation of Compounds 3-3, 3-4 and 3-5

The same synthesis methods as in preparing compounds 1-2, 1-3, and 1-4 each were handled to obtain a yellow solid: compound 3-3 (22 g, 80%), a white solid: compound 3-4 (2 g, 8%), and compound 3-5 (1.3 g, 83%), respectively.

Preparation of Compound C-57

After putting compound 3-5 (1.68 g, 6.30 mmol), 2-chloro-4,6-diphenyl-1,3,5-triazine (3.22 g, 8.18 mmol), PdCl₂(PPh₃)₂ (0.66 g, 0.9 mmol), Ca₂CO₃ (8.2 g, 25 mmol), toluene 70 mL, ethanol 35 mL, and distilled water 9 mL in a 500 mL round bottom flask, the mixture was stirred for 12 hours at 100° C. After completing the reaction, the mixture was extracted with EA, the remaining organic layer was dried with MgSO₄, then filtered, then distillated under reduced pressure, and then separated through a column to obtain compound C-57 (2 g, 54%).

MS/EIMS found 579.7; calculated 579.18

### Device Example 1

### Production of an OLED Device Using the Compound According to the Present Invention

An OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. N¹,N^{1′}-([1,1′-biphenyl]-4,4′-diyl)bis(N¹-(naphthalen-1-yl)-N⁴,N⁴-diphenylbenzene-1,4-diamine) was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 60 nm on the ITO substrate. Then, N,N′-di(4-biphenyl)-N,N′-di(4-biphenyl)-4,4′-diaminobiphenyl was introduced into another cell of said vacuum vapor depositing apparatus, and was evaporated by applying an electric current to the cell, thereby forming a hole transport layer having a thickness of 20 nm on the hole injection layer. Thereafter, compound C-16 was introduced into one cell of the vacuum vapor depositing apparatus, as a host material, and compound D-25 was introduced into another cell as a dopant. The two materials were evaporated at different rates and deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into one cell and lithium quinolate was introduced into another cell. The two materials were evaporated at the same rate and deposited in a doping amount of 50 wt %, respectively to form an electron transport layer having a thickness of 30 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 1030 cd/m² and a current density of 2.52 mA/cm² at a driving voltage of 3.6 V.

### Device Example 2

### Production of an OLED Device Using the Compound According to the Present Invention

An OLED device was produced in the same manner as in Device Example 1, except for using compound C-26 as a host material, and compound D-2 as a dopant.

The produced OLED device showed a green emission having a luminance of 1010 cd/m² and a current density of 2.54 mA/cm² at a driving voltage of 3.5 V.

### Device Example 3

### Production of an OLED Device Using the Compound According to the Present Invention

An OLED device was produced in the same manner as in Device Example 1, except for using compound C-57 as a host material, and compound D-2 as a dopant.

The produced OLED device showed a green emission having a luminance of 1090 cd/m² and a current density of 2.82 mA/cm² at a driving voltage of 3.4 V.

### Comparative Example 1

### Production of an OLED Device Using Conventional Electroluminescent Compounds

An OLED device was produced in the same manner as in Device Example 1, except that 4,4′-N,N′-dicarbazole-biphenyl was used as a host material, and compound D-5 was used as a dopant to deposit a light-emitting layer having a thickness of 30 nm on the hole transport layer; and a hole blocking layer having a thickness of 10 nm was deposited by using aluminum(III)bis(2-methyl-8-quinolinato)4-phenylphenolate.

The produced OLED device showed a green emission having a luminance of 1000 cd/m² and a current density of 2.86 mA/cm² at a driving voltage of 4.9 V.

It is verified that the organic electroluminescent devices using the compounds according to the present invention as a green light-emitting host material have superior luminous efficiency and power efficiency over devices using conventional materials.

1. An organic electroluminescent compound represented by the following formula 1: 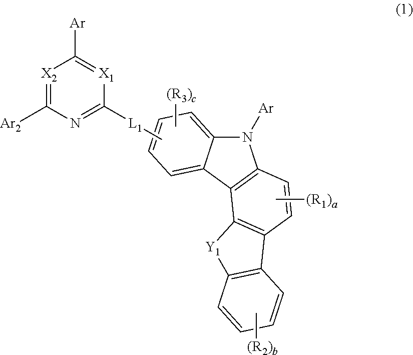
wherein
L₁ represents a single bond, a substituted or unsubstituted 3- to 30-membered heteroarylene group, or a substituted or unsubstituted (C6-C30)arylene group;
X₁ and X₂ each independently represent CR′ or N;
Y₁ represents —O—, —S—, —CR₁₁R₁₂—, —SiR₁₃R₁₄— or —NR₁₅—, provided that when Y₁ is —NR₁₅—, L₁ is not a single bond;
Ar represents hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, or a substituted or unsubstituted 5- to 7-membered heterocycloalkyl group;
Ar₁, Ar₂, R′, R₁ to R₃, and R₁₁ to R₁₅ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, an amino group, a substituted or unsubstituted (C6-C30)arylamino group, a substituted or unsubstituted tri(C1-C30)alkylsilyl group, a substituted or unsubstituted tri(C6-C30)arylsilyl group, a cyano group, a nitro group, or a hydroxyl group;
a represents an integer of 1 or 2, b represents an integer of 1 to 4, c represents an integer of 1 to 3; where a to c are integers of 2 or more, each of R₁ to R₃ is the same or different; and
the heterocycloalkyl group, the heteroarylene group and the heteroaryl group contain at least one hetero atom selected from B, N, O, S, P(═O), Si and P.

2. The organic electroluminescent compound according to claim 1, wherein the aryl(ene), heteroaryl(ene), alkyl, cycloalkyl, heterocycloalkyl, arylamino, trialkylsilyl and triarylsilyl groups in L₁, Ar, Ar₁, Ar₂, R′, R₁ to R₃, and R₁₁ to R₁₅ can be further substituted with at least one selected from the group consisting of deuterium; a halogen; a (C1-C30)alkyl group substituted or unsubstituted with a halogen; a (C6-C30)aryl group; a 3- to 30-membered heteroaryl group substituted or unsubstituted with a (C1-C30)alkyl or a (C6-C30)aryl; a (C3-C30)cycloalkyl group; a 5- to 7-membered heterocycloalkyl group; a tri(C1-C30)alkylsilyl group; a tri(C6-C30)arylsilyl group; a di(C1-C30)alkyl(C6-C30)arylsilyl group; a (C1-C30)alkyldi(C6-C30)arylsilyl group; a (C2-C30)alkenyl group; a (C2-C30)alkynyl group; a cyano group; an N-carbazolyl group; a di(C1-C30)alkylamino group; a di(C6-C30)arylamino group; a (C1-C30)alkyl(C6-C30)arylamino group; a di(C6-C30)arylboronyl group; a di(C1-C30)alkylboronyl group; a (C1-C30)alkyl(C6-C30)arylboronyl group; a (C6-C30)aryl(C1-C30)alkyl group; a (C1-C30)alkyl(C6-C30)aryl group; a carboxyl group; a nitro group; and a hydroxyl group.

3. The organic electroluminescent compound according to claim 1, wherein
L₁ represents a single bond, a 3- to 30-membered heteroarylene group, or a (C6-C30)arylene group;
X₁ and X₂ each independently represent CR′ or N;
Y₁ represents —O—, —S—, —CR₁₁R₁₂—, —SiR₁₃R₁₄— or —NR₁₅—, provided that when Y₁ is —NR₁₅—, L₁ is not a single bond;
Ar represents hydrogen, a (C6-C30)aryl group, or a 3- to 30-membered heteroaryl group;
Ar₁, Ar₂, R′, R₁, R₂, R₃, and R₁₁ to R₁₅ each independently represent hydrogen, a (C1-C30)alkyl group, a (C6-C30)aryl group, a 3- to 30-membered heteroaryl group, a (C1-C30)alkylsilyl group, or a (C6-C30)arylsilyl group;
a represents an integer of 1 or 2; where a is an integer of 2, each of R₁ is the same or different;
b represents an integer of 1 to 4; where b is an integer of 2 or more, each of R₂ is the same or different;
c represents an integer of 1 to 3; where c is an integer of 2 or more, each of R₃ is the same or different; and
the heteroarylene and arylene groups in L₁, and the alkyl, aryl and heteroaryl groups in Ar, Ar₁, Ar₂, R′, R₁ to R₃, and R₁₁ to R₁₅ can be further substituted with at least one selected from the group consisting of deuterium, a halogen, a (C1-C30)alkyl group, a (C6-C30)aryl group, a 3- to 30-membered heteroaryl group, a (C3-C30)cycloalkyl group, and a (C6-C30)aryl(C1-C30)alkyl group.

4. The organic electroluminescent compound according to claim 1, wherein the compound represented by formula 1 is selected from the group consisting of:

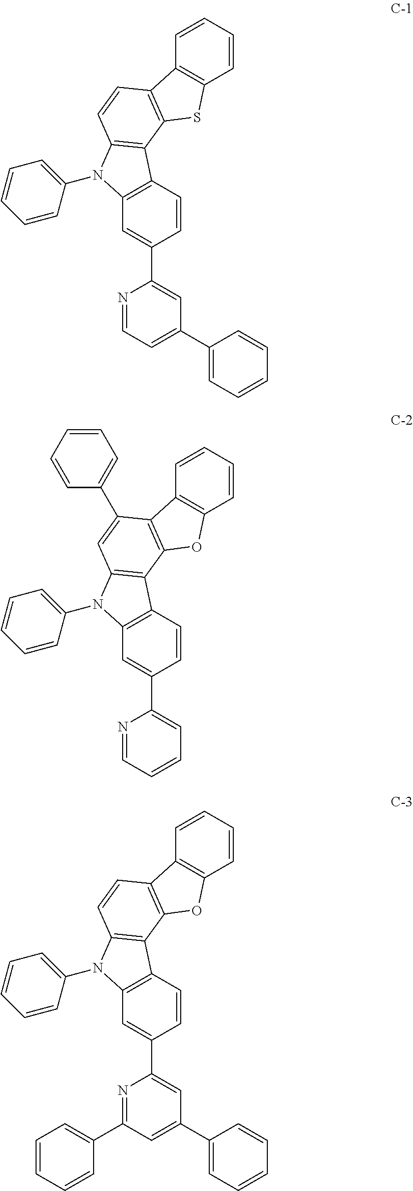 [SMILES: c1ccc(-c2ccnc(-c3ccc4c5c6sc7ccccc7c6ccc5n(-c5ccccc5)c4c3)c2)cc1 ; c1ccc(-c2cc3c(c4ccc(-c5ccccn5)cc4n3-c3ccccc3)c3oc4ccccc4c23)cc1 ; c1ccc(-c2cc(-c3ccccc3)nc(-c3ccc4c5c6oc7ccccc7c6ccc5n(-c5ccccc5)c4c3)c2)cc1]

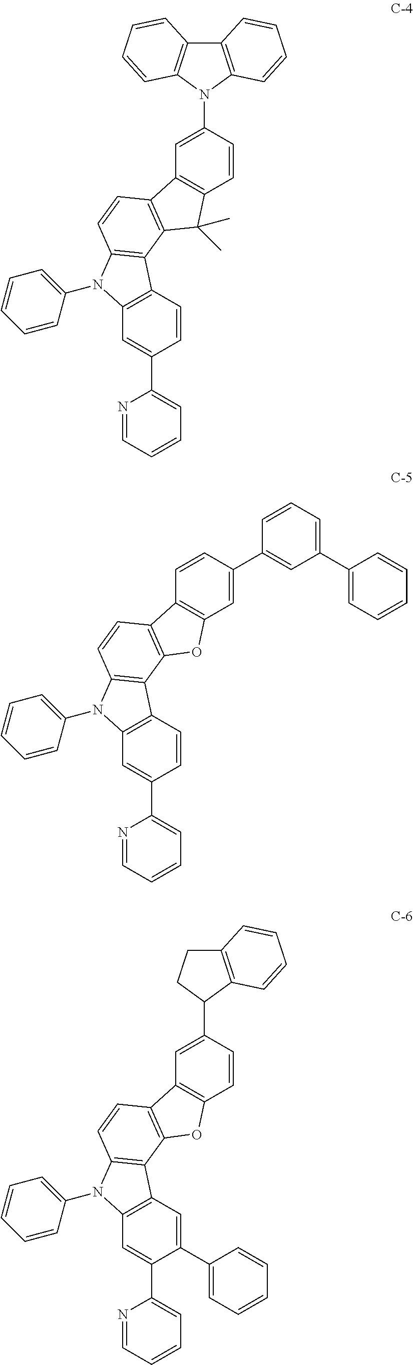 [SMILES: CC1(C)c2ccc(-n3c4ccccc4c4ccccc43)cc2-c2ccc3c(c21)c1ccc(-c2ccccn2)cc1n3-c1ccccc1 ; c1ccc(-c2cccc(-c3ccc4c(c3)oc3c4ccc4c3c3ccc(-c5ccccn5)cc3n4-c3ccccc3)c2)cc1 ; c1ccc(-c2cc3c4c5oc6ccc(C7CCc8ccccc87)cc6c5ccc4n(-c4ccccc4)c3cc2-c2ccccn2)cc1]

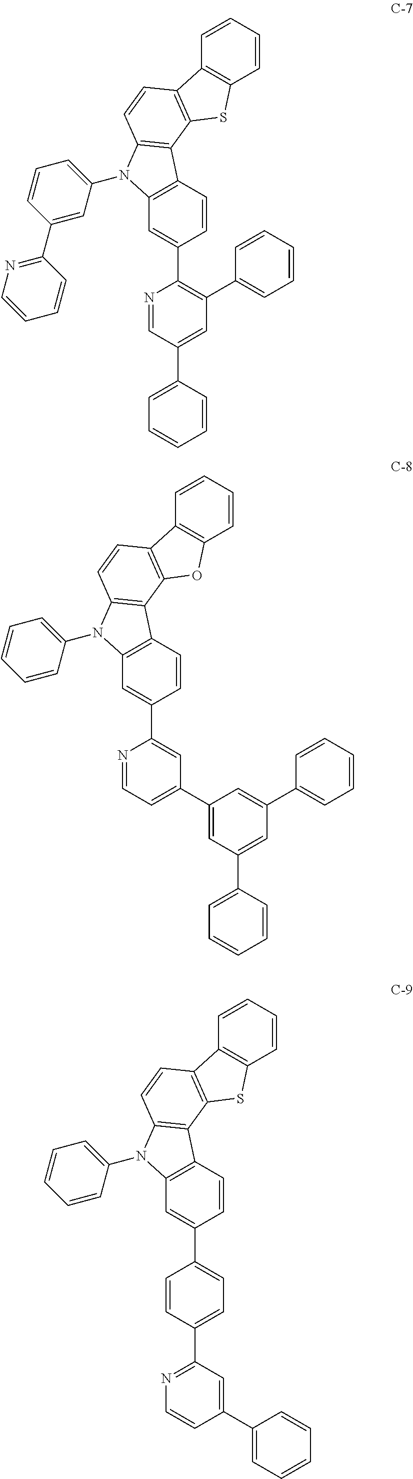

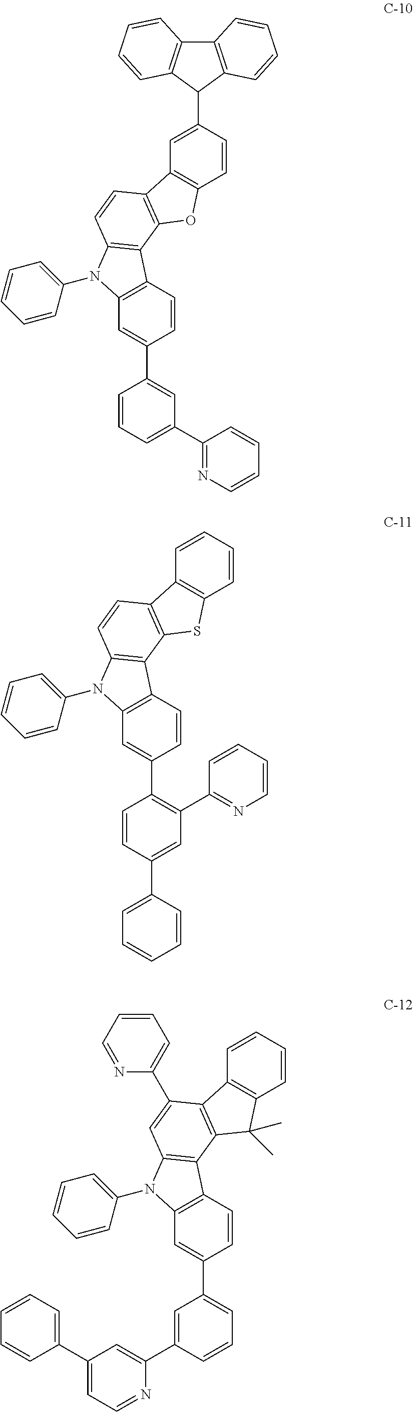 [SMILES: c1ccc(-n2c3cc(-c4cccc(-c5ccccn5)c4)ccc3c3c4oc5ccc(C6c7ccccc7-c7ccccc76)cc5c4ccc32)cc1 ; c1ccc(-c2ccc(-c3ccc4c5c6sc7ccccc7c6ccc5n(-c5ccccc5)c4c3)c(-c3ccccn3)c2)cc1 ; CC1(C)c2ccccc2-c2c(-c3ccccn3)cc3c(c21)c1ccc(-c2cccc(-c4cc(-c5ccccc5)ccn4)c2)cc1n3-c1ccccc1]

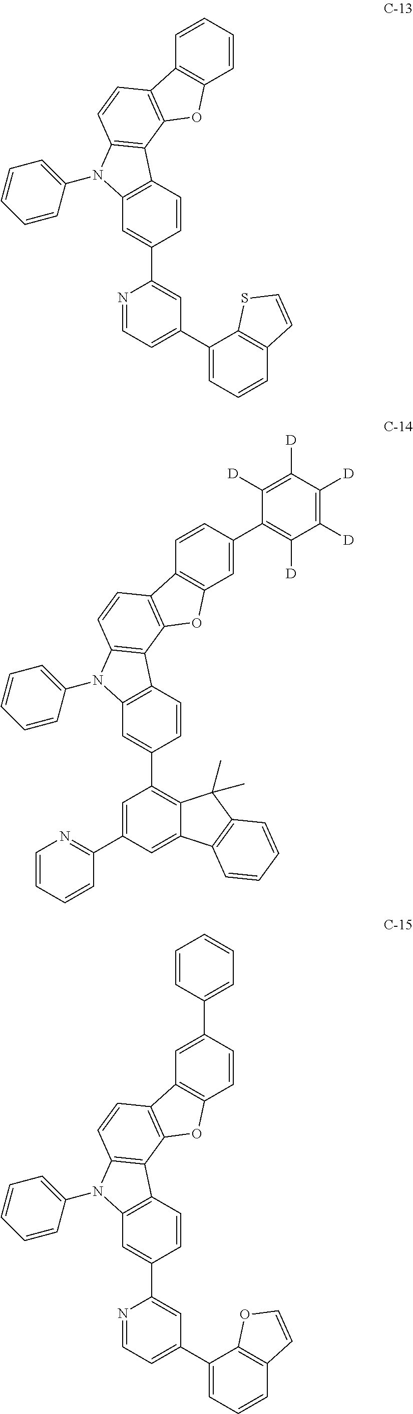 [SMILES: c1ccc(-n2c3cc(-c4cc(-c5cccc6ccsc56)ccn4)ccc3c3c4oc5ccccc5c4ccc32)cc1 ; [2H]c1c([2H])c([2H])c(-c2ccc3c(c2)oc2c3ccc3c2c2ccc(-c4cc(-c5ccccn5)cc5c4C(C)(C)c4ccccc4-5)cc2n3-c2ccccc2)c([2H])c1[2H] ; c1ccc(-c2ccc3oc4c(ccc5c4c4ccc(-c6cc(-c7cccc8ccoc78)ccn6)cc4n5-c4ccccc4)c3c2)cc1]

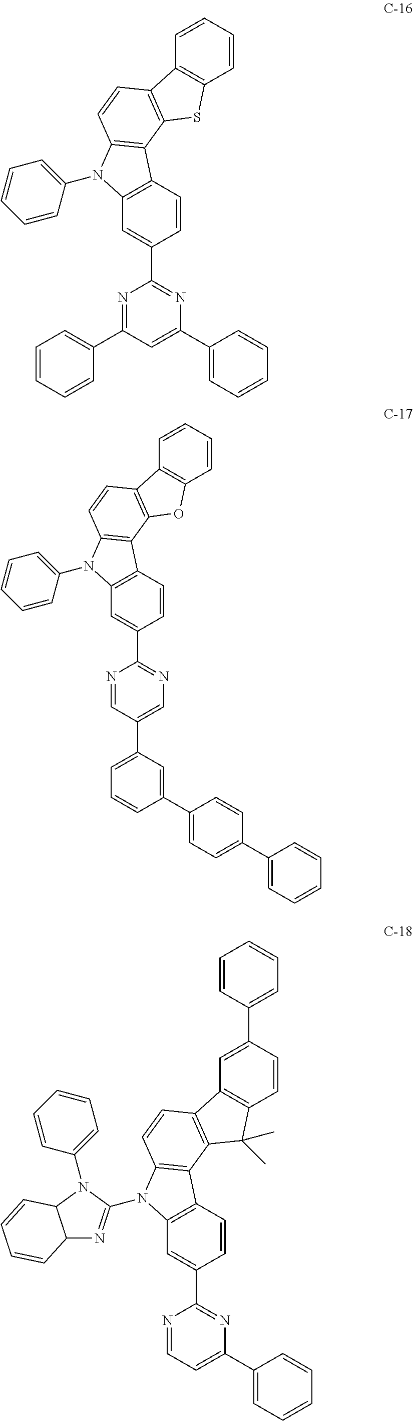 [SMILES: c1ccc(-c2cc(-c3ccccc3)nc(-c3ccc4c5c6sc7ccccc7c6ccc5n(-c5ccccc5)c4c3)n2)cc1 ; c1ccc(-c2ccc(-c3cccc(-c4cnc(-c5ccc6c7c8oc9ccccc9c8ccc7n(-c7ccccc7)c6c5)nc4)c3)cc2)cc1 ; CC1(C)c2ccc(-c3ccccc3)cc2-c2ccc3c(c21)c1ccc(-c2nccc(-c4ccccc4)n2)cc1n3C1=NC2C=CC=CC2N1c1ccccc1]

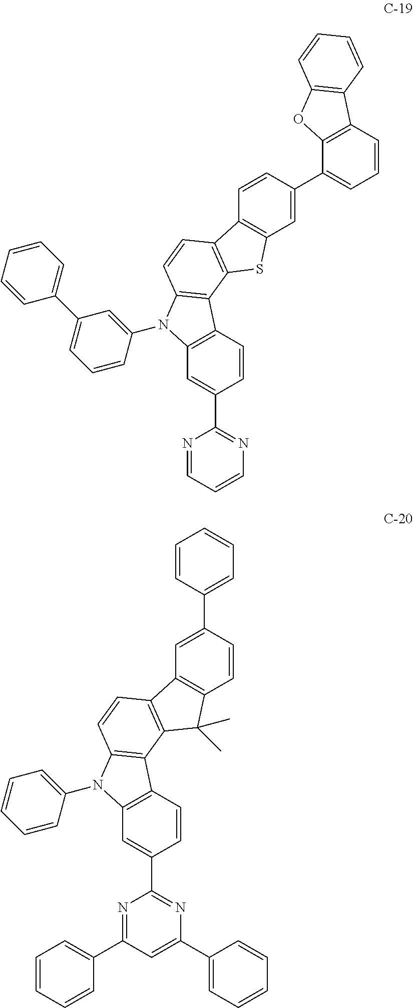

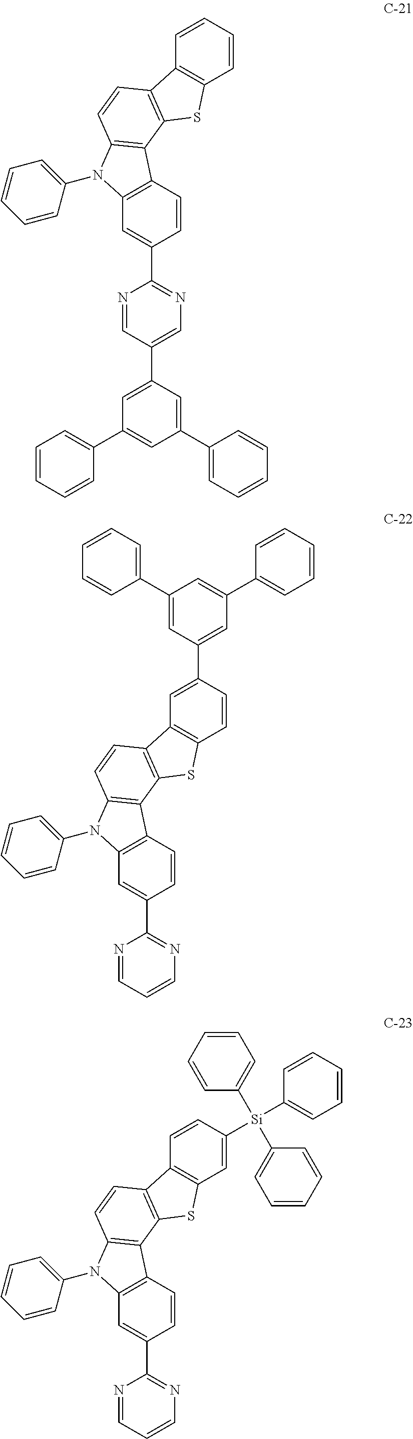 [SMILES: c1ccc(-c2cc(-c3ccccc3)cc(-c3cnc(-c4ccc5c6c7sc8ccccc8c7ccc6n(-c6ccccc6)c5c4)nc3)c2)cc1 ; c1ccc(-c2cc(-c3ccccc3)cc(-c3ccc4sc5c(ccc6c5c5ccc(-c7ncccn7)cc5n6-c5ccccc5)c4c3)c2)cc1 ; c1ccc(-n2c3cc(-c4ncccn4)ccc3c3c4sc5cc([Si](c6ccccc6)(c6ccccc6)c6ccccc6)ccc5c4ccc32)cc1]

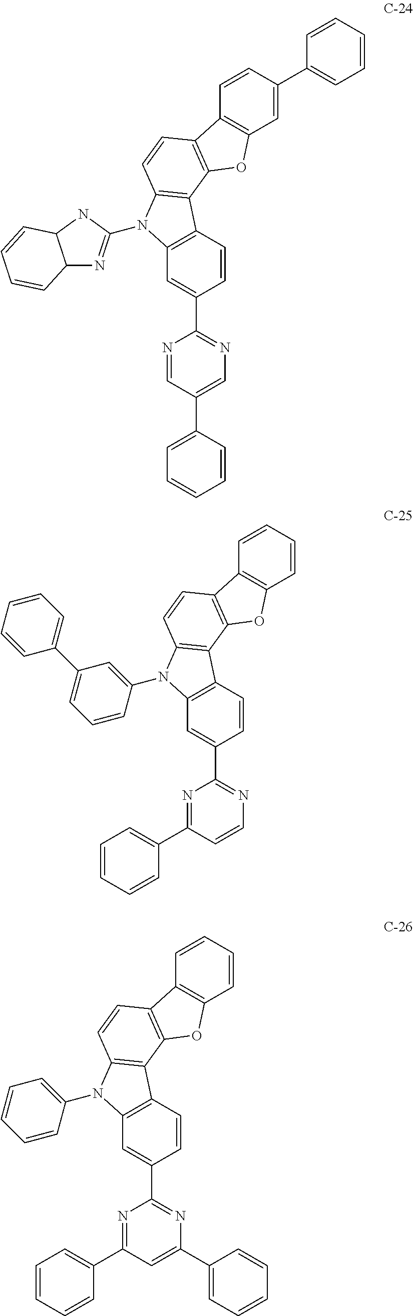 [SMILES: C1=CC2N=C(n3c4cc(-c5ncc(-c6ccccc6)cn5)ccc4c4c5oc6cc(-c7ccccc7)ccc6c5ccc43)NC2C=C1 ; c1ccc(-c2cccc(-n3c4cc(-c5nccc(-c6ccccc6)n5)ccc4c4c5oc6ccccc6c5ccc43)c2)cc1 ; c1ccc(-c2cc(-c3ccccc3)nc(-c3ccc4c5c6oc7ccccc7c6ccc5n(-c5ccccc5)c4c3)n2)cc1]

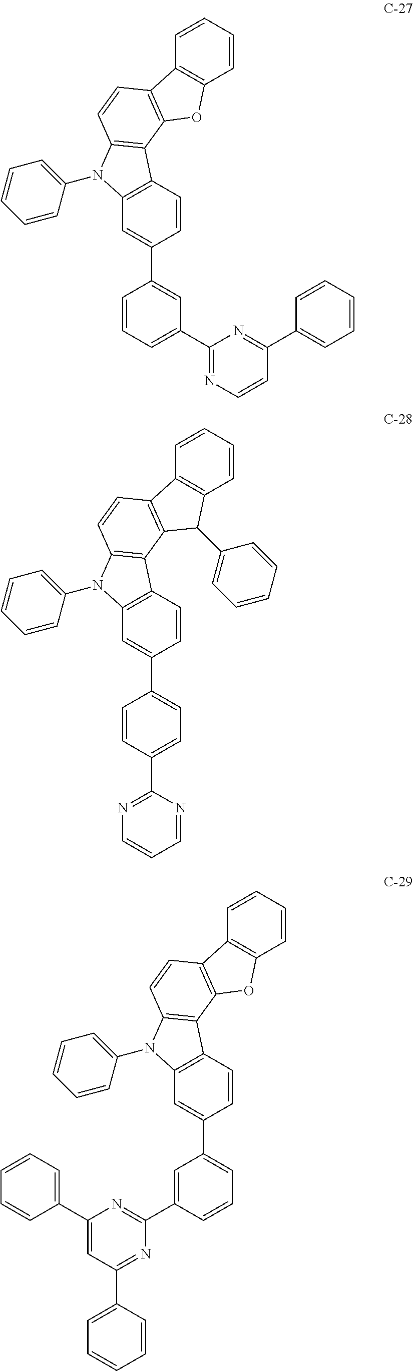

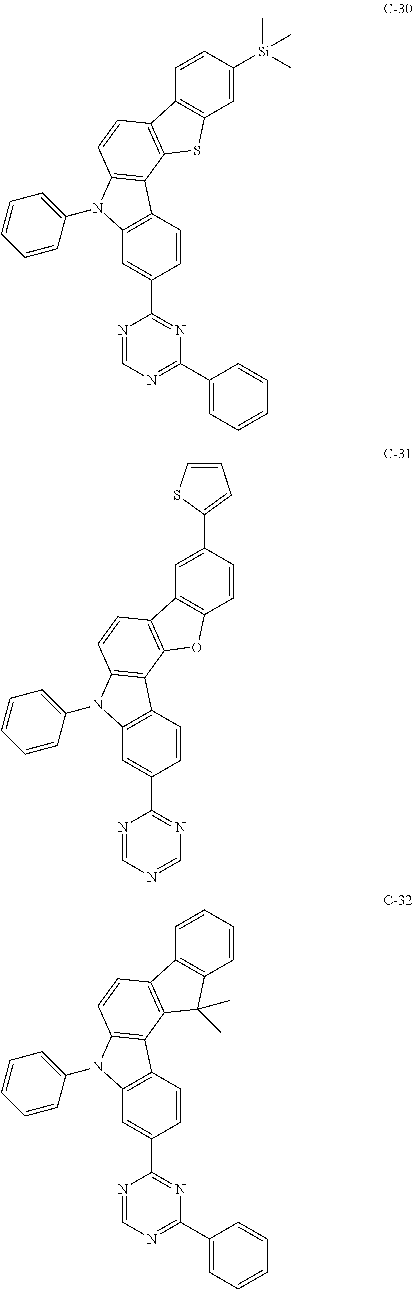

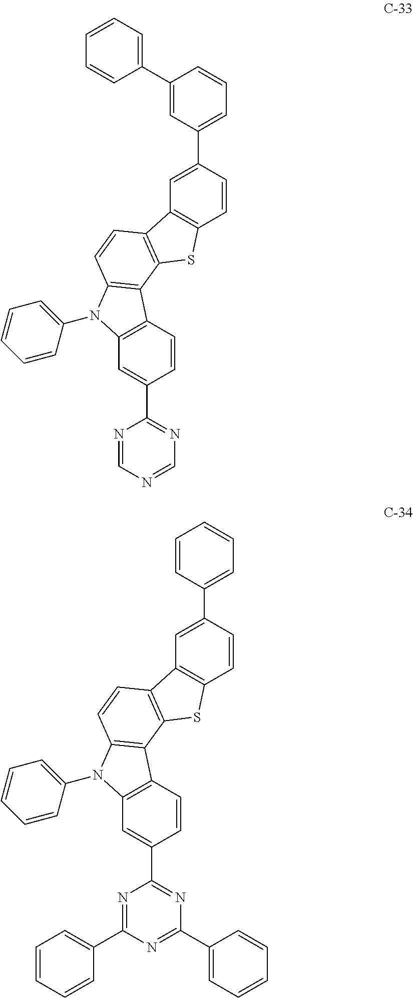 [SMILES: c1ccc(-c2cccc(-c3ccc4sc5c(ccc6c5c5ccc(-c7ncncn7)cc5n6-c5ccccc5)c4c3)c2)cc1 ; c1ccc(-c2ccc3sc4c(ccc5c4c4ccc(-c6nc(-c7ccccc7)nc(-c7ccccc7)n6)cc4n5-c4ccccc4)c3c2)cc1]

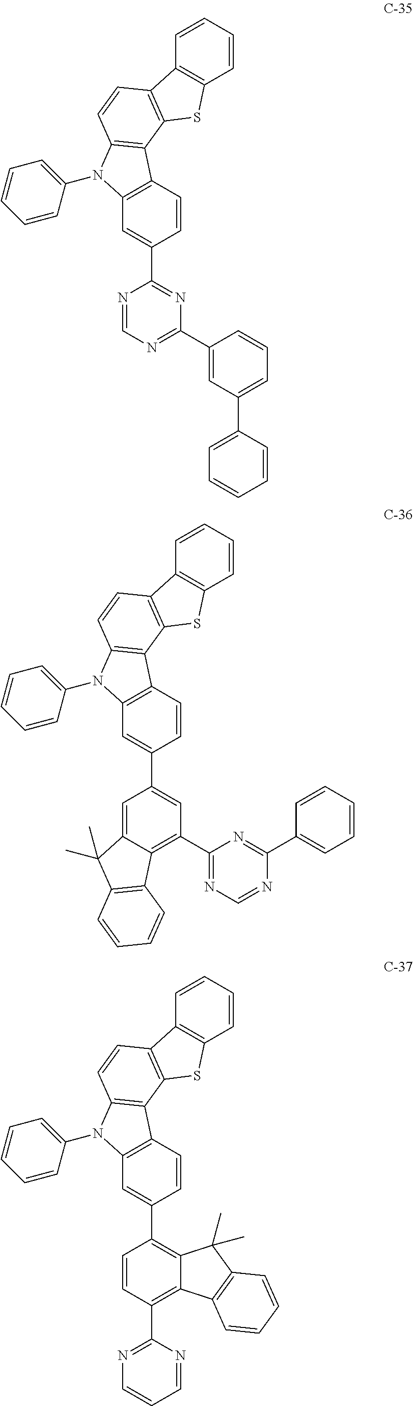

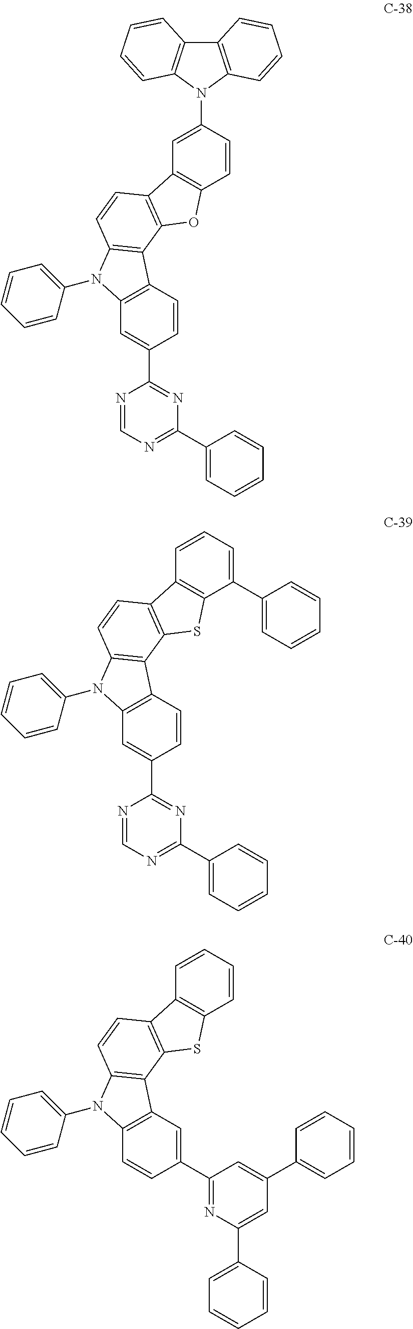

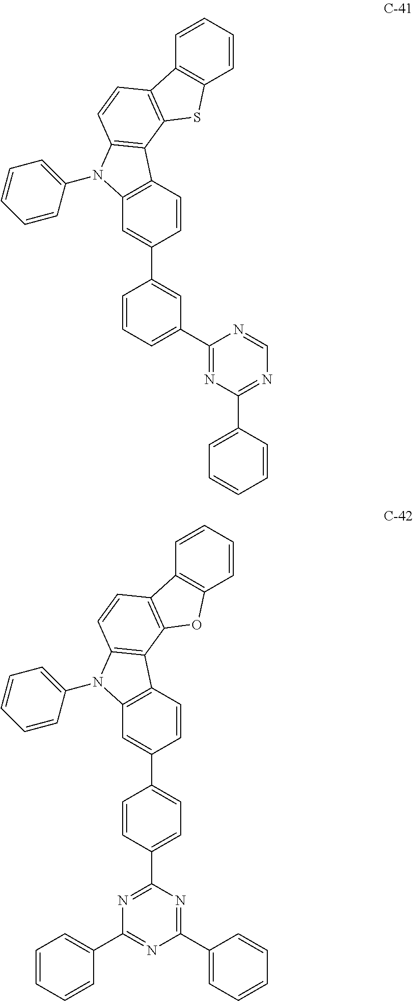

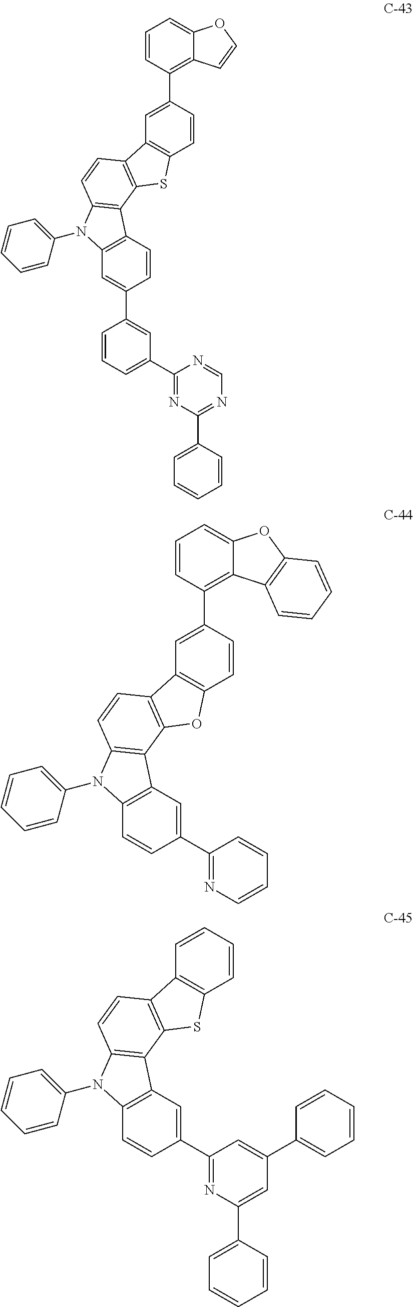

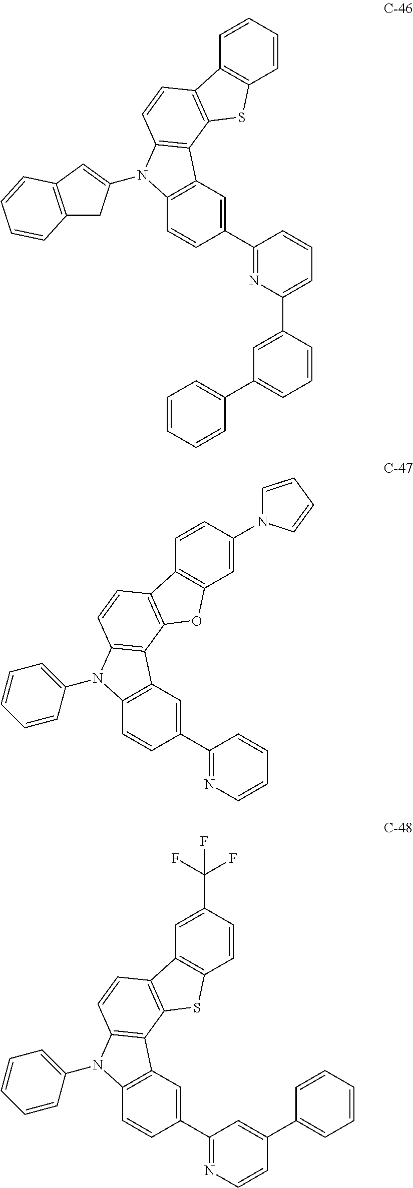 [SMILES: C1=C(n2c3ccc(-c4cccc(-c5cccc(-c6ccccc6)c5)n4)cc3c3c4sc5ccccc5c4ccc32)Cc2ccccc21 ; c1ccc(-n2c3ccc(-c4ccccn4)cc3c3c4oc5cc(-n6cccc6)ccc5c4ccc32)cc1 ; FC(F)(F)c1ccc2sc3c(ccc4c3c3cc(-c5cc(-c6ccccc6)ccn5)ccc3n4-c3ccccc3)c2c1]

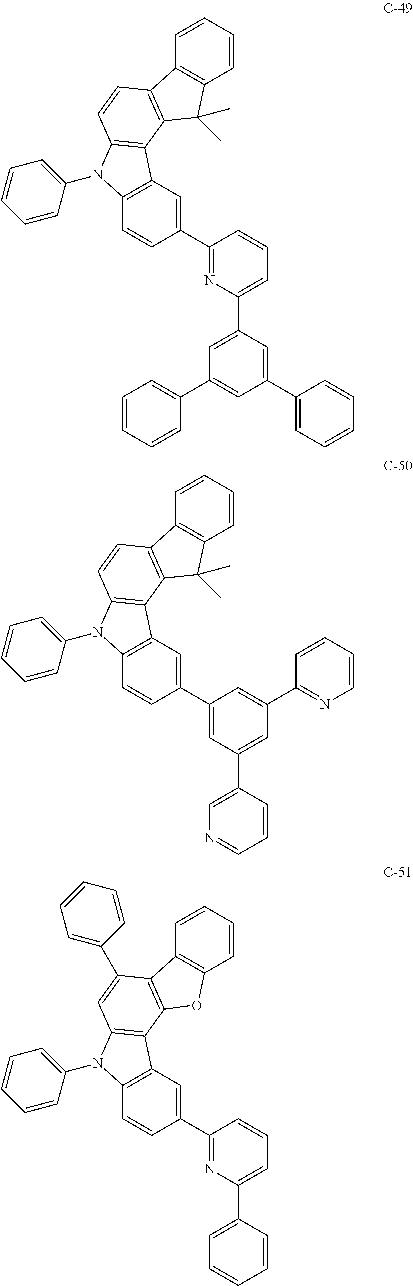 [SMILES: CC1(C)c2ccccc2-c2ccc3c(c21)c1cc(-c2cccc(-c4cc(-c5ccccc5)cc(-c5ccccc5)c4)n2)ccc1n3-c1ccccc1 ; CC1(C)c2ccccc2-c2ccc3c(c21)c1cc(-c2cc(-c4cccnc4)cc(-c4ccccn4)c2)ccc1n3-c1ccccc1 ; c1ccc(-c2cccc(-c3ccc4c(c3)c3c5oc6ccccc6c5c(-c5ccccc5)cc3n4-c3ccccc3)n2)cc1]

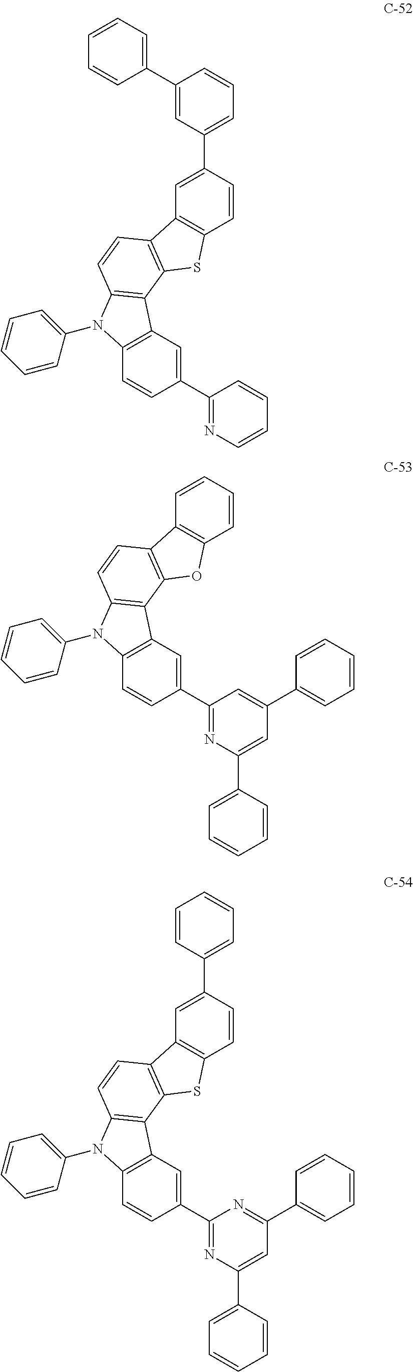

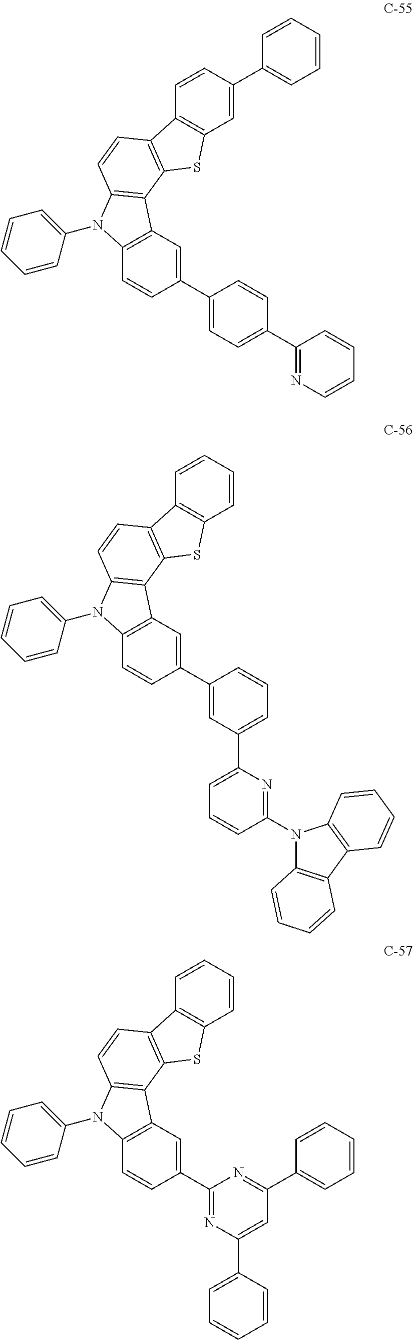 [SMILES: c1ccc(-c2ccc3c(c2)sc2c3ccc3c2c2cc(-c4ccc(-c5ccccn5)cc4)ccc2n3-c2ccccc2)cc1 ; c1ccc(-n2c3ccc(-c4cccc(-c5cccc(-n6c7ccccc7c7ccccc76)n5)c4)cc3c3c4sc5ccccc5c4ccc32)cc1 ; c1ccc(-c2cc(-c3ccccc3)nc(-c3ccc4c(c3)c3c5sc6ccccc6c5ccc3n4-c3ccccc3)n2)cc1]

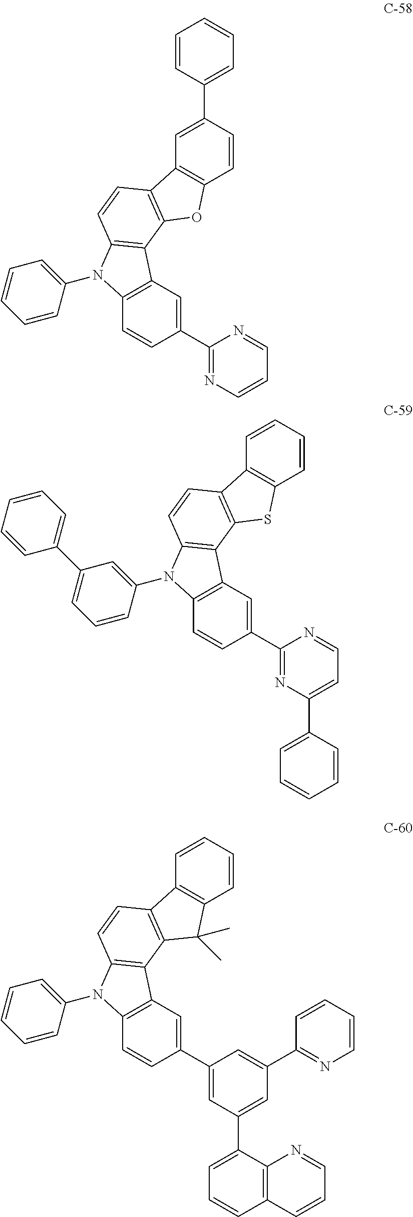

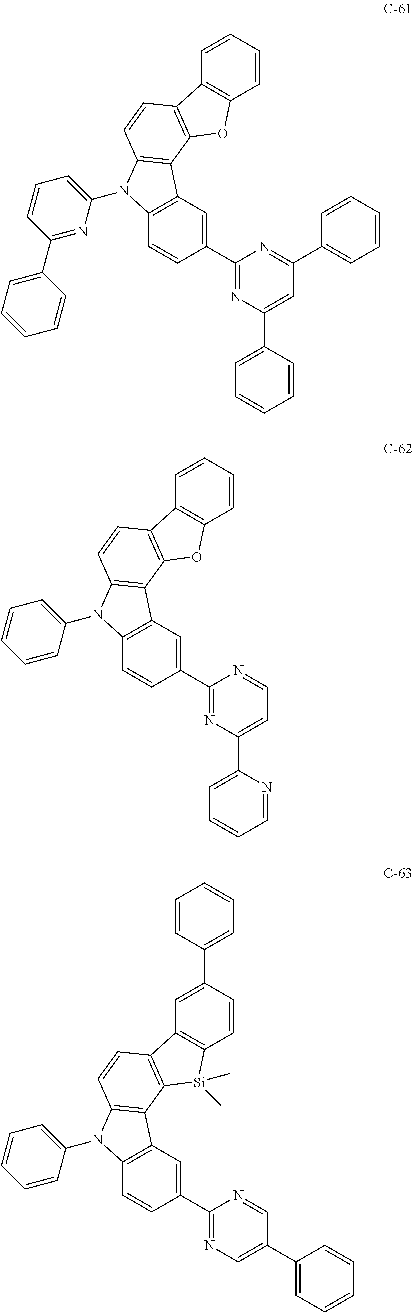 [SMILES: c1ccc(-c2cccc(-n3c4ccc(-c5nc(-c6ccccc6)cc(-c6ccccc6)n5)cc4c4c5oc6ccccc6c5ccc43)n2)cc1 ; c1ccc(-n2c3ccc(-c4nccc(-c5ccccn5)n4)cc3c3c4oc5ccccc5c4ccc32)cc1 ; C[Si]1(C)c2ccc(-c3ccccc3)cc2-c2ccc3c(c21)c1cc(-c2ncc(-c4ccccc4)cn2)ccc1n3-c1ccccc1]

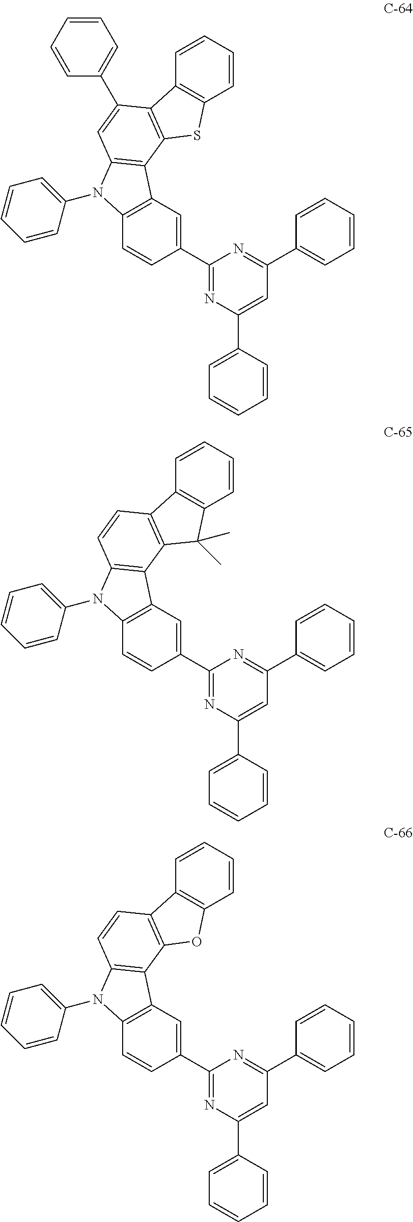

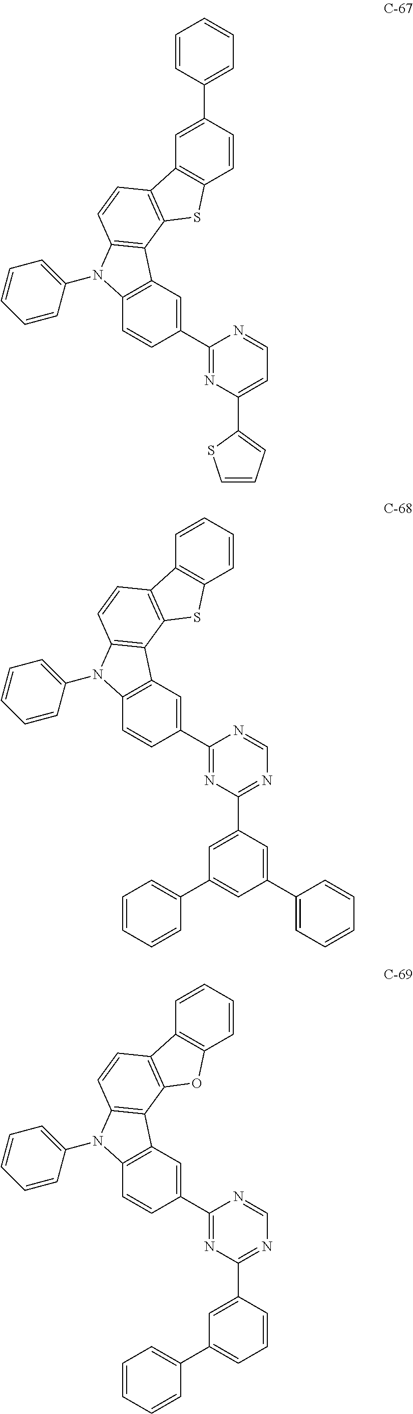

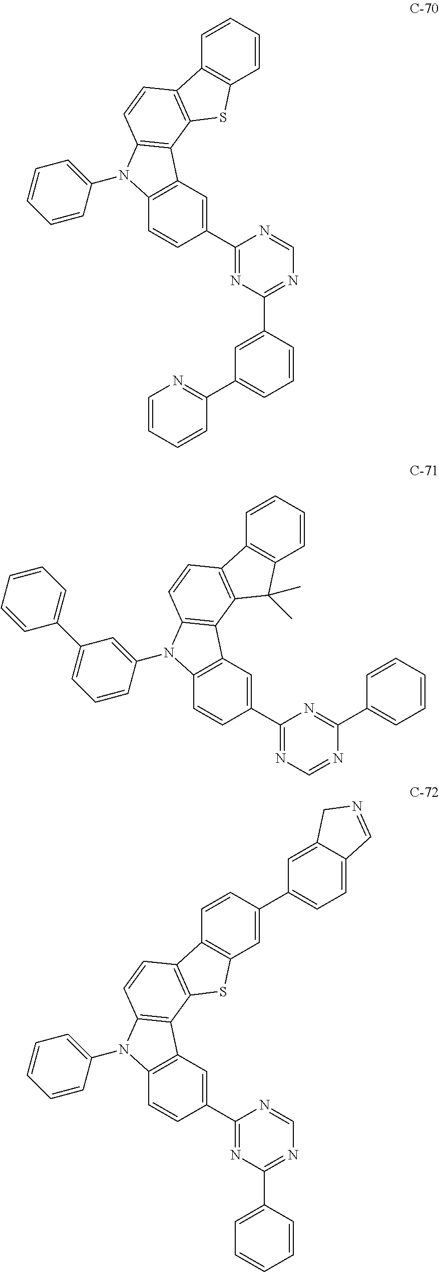

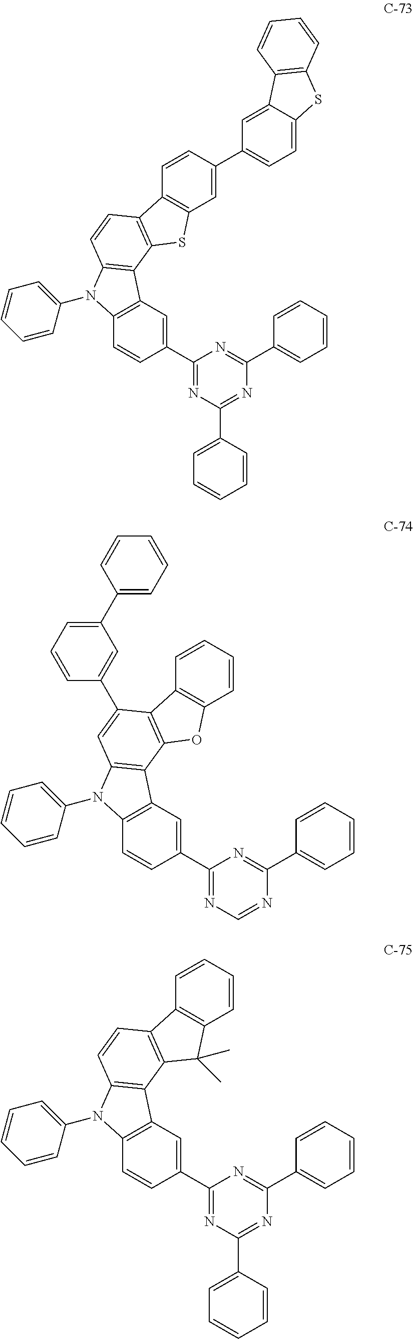 [SMILES: c1ccc(-c2nc(-c3ccccc3)nc(-c3ccc4c(c3)c3c5sc6cc(-c7ccc8sc9ccccc9c8c7)ccc6c5ccc3n4-c3ccccc3)n2)cc1 ; c1ccc(-c2cccc(-c3cc4c(c5cc(-c6ncnc(-c7ccccc7)n6)ccc5n4-c4ccccc4)c4oc5ccccc5c34)c2)cc1 ; CC1(C)c2ccccc2-c2ccc3c(c21)c1cc(-c2nc(-c4ccccc4)nc(-c4ccccc4)n2)ccc1n3-c1ccccc1]

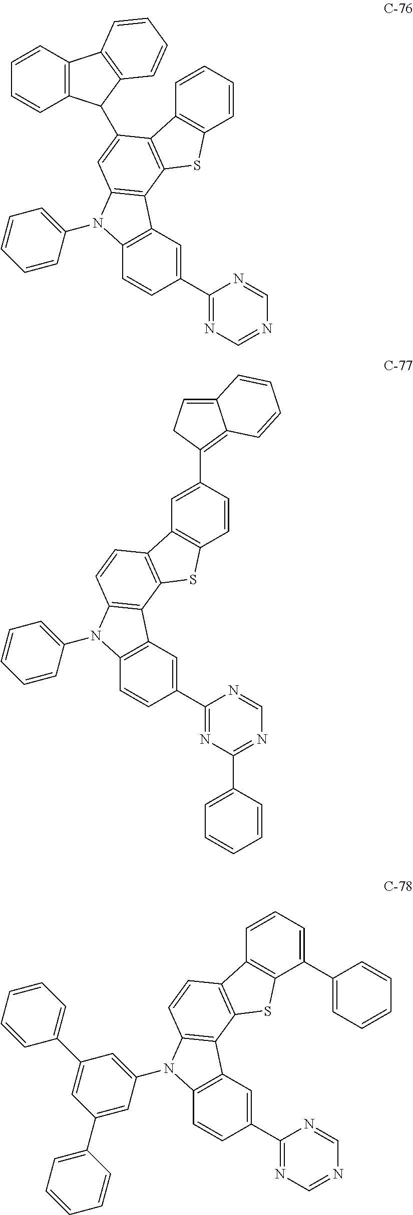

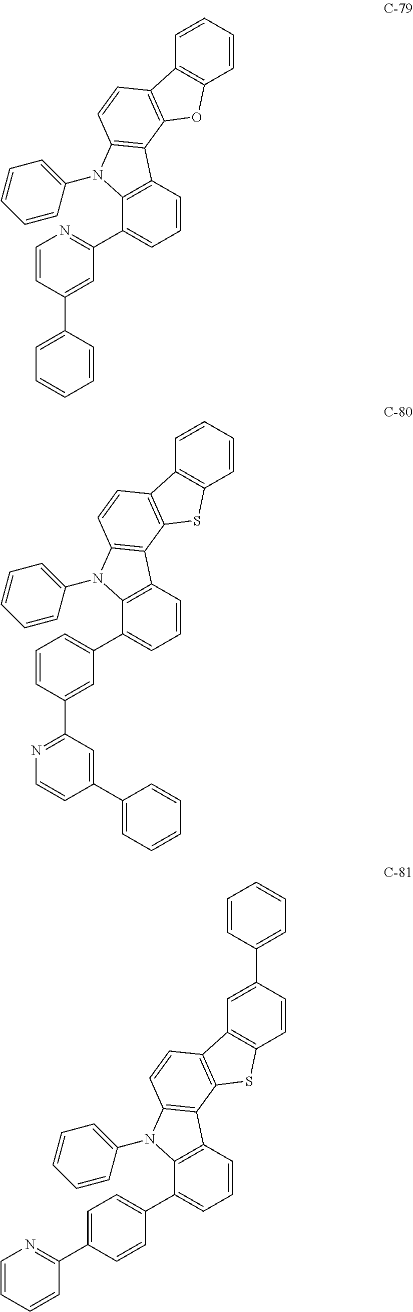 [SMILES: c1ccc(-c2ccnc(-c3cccc4c5c6oc7ccccc7c6ccc5n(-c5ccccc5)c34)c2)cc1 ; c1ccc(-c2ccnc(-c3cccc(-c4cccc5c6c7sc8ccccc8c7ccc6n(-c6ccccc6)c45)c3)c2)cc1 ; c1ccc(-c2ccc3sc4c(ccc5c4c4cccc(-c6ccc(-c7ccccn7)cc6)c4n5-c4ccccc4)c3c2)cc1]

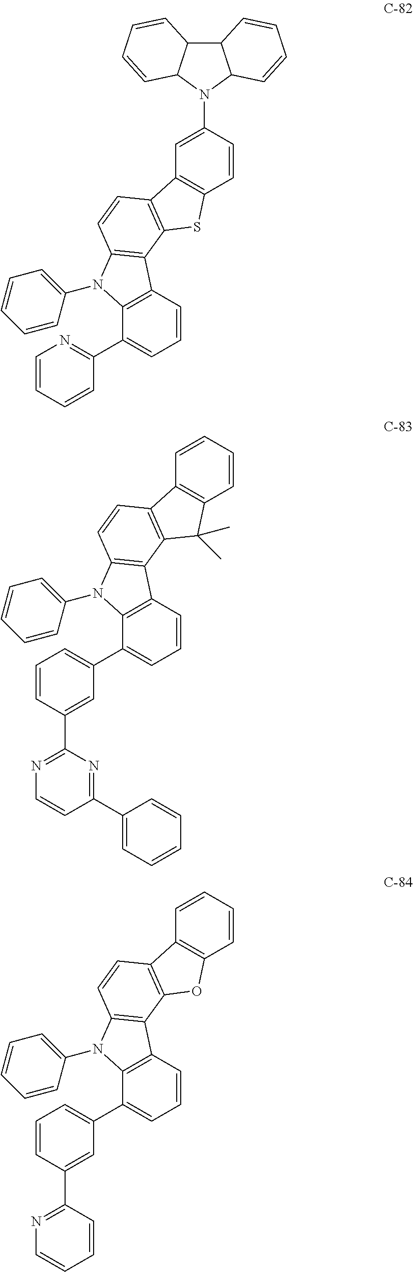 [SMILES: C1=CC2C3C=CC=CC3N(c3ccc4sc5c(ccc6c5c5cccc(-c7ccccn7)c5n6-c5ccccc5)c4c3)C2C=C1 ; CC1(C)c2ccccc2-c2ccc3c(c21)c1cccc(-c2cccc(-c4nccc(-c5ccccc5)n4)c2)c1n3-c1ccccc1 ; c1ccc(-n2c3ccc4c5ccccc5oc4c3c3cccc(-c4cccc(-c5ccccn5)c4)c32)cc1]

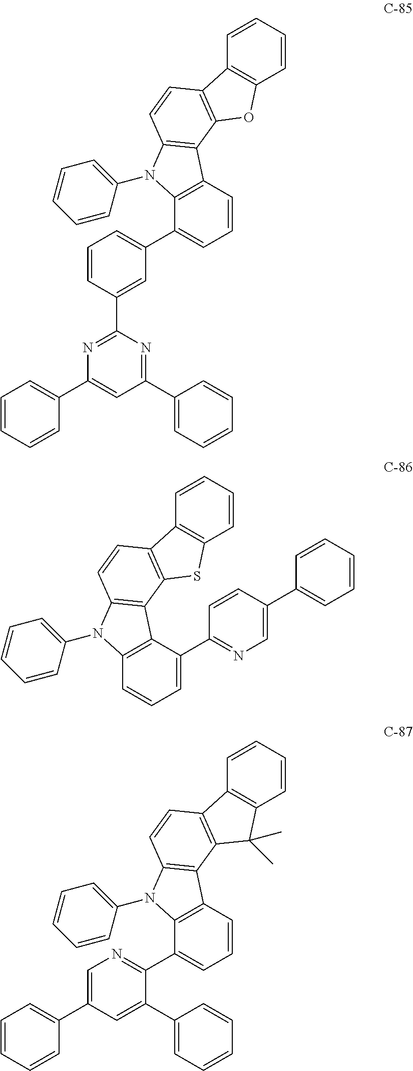

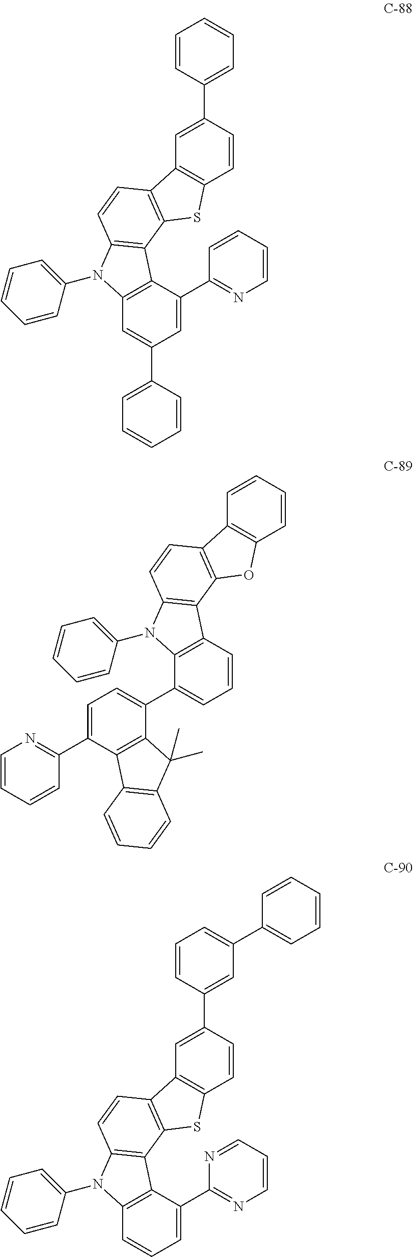 [SMILES: c1ccc(-c2ccc3sc4c(ccc5c4c4c(-c6ccccn6)cc(-c6ccccc6)cc4n5-c4ccccc4)c3c2)cc1 ; CC1(C)c2ccccc2-c2c(-c3ccccn3)ccc(-c3cccc4c5c6oc7ccccc7c6ccc5n(-c5ccccc5)c34)c21 ; c1ccc(-c2cccc(-c3ccc4sc5c(ccc6c5c5c(-c7ncccn7)cccc5n6-c5ccccc5)c4c3)c2)cc1]

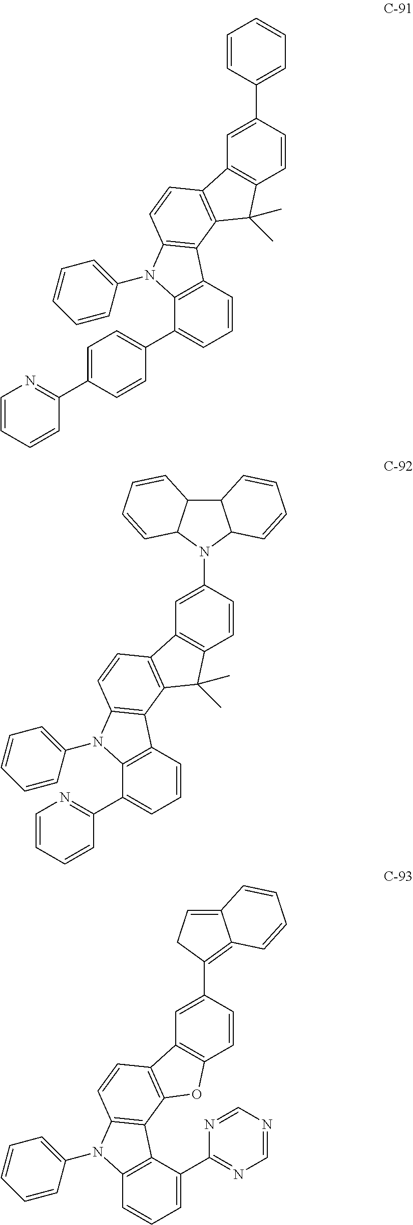 [SMILES: CC1(C)c2ccc(-c3ccccc3)cc2-c2ccc3c(c21)c1cccc(-c2ccc(-c4ccccn4)cc2)c1n3-c1ccccc1 ; CC1(C)c2ccc(N3C4C=CC=CC4C4C=CC=CC43)cc2-c2ccc3c(c21)c1cccc(-c2ccccn2)c1n3-c1ccccc1 ; C1=c2ccccc2=C(c2ccc3oc4c(ccc5c4c4c(-c6ncncn6)cccc4n5-c4ccccc4)c3c2)C1]

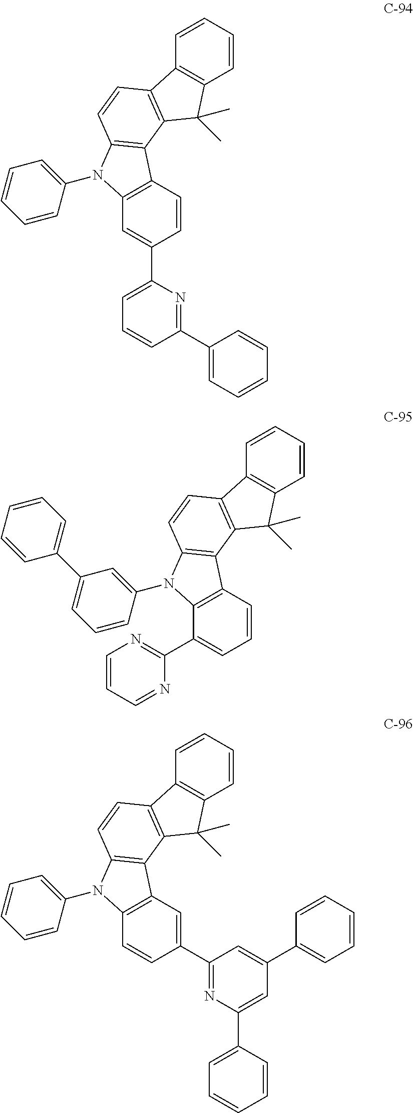

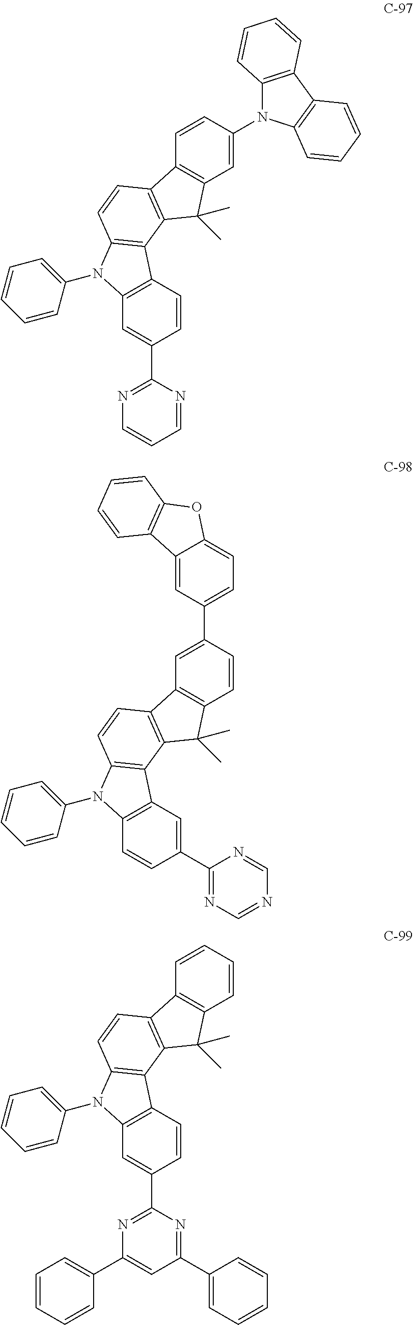

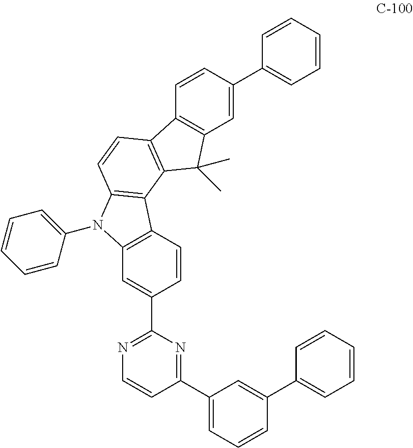 [SMILES: CC1(C)c2cc(-c3ccccc3)ccc2-c2ccc3c(c21)c1ccc(-c2nccc(-c4cccc(-c5ccccc5)c4)n2)cc1n3-c1ccccc1]

5. An organic electroluminescent device comprising the organic electroluminescent compound according to claim 1.
